(19) United States
(12) Patent Application Publication
(10) Pub. No.: US 2024/0164166 A1
(43) Pub. Date: May 16, 2024

(54) DISPLAY APPARATUS, DISPLAY MODULE, AND ELECTRONIC DEVICE

(71) Applicant: Semiconductor Energy Laboratory Co., Ltd., Atsugi-shi, Kanagawa-ken (JP)

(72) Inventors: Daisuke KUBOTA, Atsugi (JP); Taisuke KAMADA, Niiza (JP); Akio YAMASHITA, Atsugi (JP); Kenichi OKAZAKI, Atsugi (JP); Koji KUSUNOKI, Isehara (JP); Tomoaki ATSUMI, Hadano (JP)

(21) Appl. No.: 18/279,925

(22) PCT Filed: Feb. 28, 2022
(86) PCT No.: PCT/IB2022/051715

§ 371 Date: Sep. 1, 2023

(30) Foreign Application Priority Data
Mar. 11, 2021 (JP) 2021-039474
Mar. 25, 2021 (JP) 2021-051822
Dec. 22, 2021 (JP) 2021-207740

(51) Int. Cl. H10K 59/35; G09G 3/3225; H10K 39/34

(52) U.S. Cl. CPC H10K 59/353; G09G 3/3225; H10K 39/34; G09G 2300/0452; G09G 2300/0842; G09G 2310/08

(57) ABSTRACT

A semiconductor device having a light detection function and including a high-resolution display portion is provided. The semiconductor device is a display apparatus including a light-emitting device, a light-receiving device, and a substrate. The light-emitting device includes a first electrode, a light-emitting layer, a first electron-transport layer, an electron-injection layer, and a second electrode stacked in this order over the substrate. The light-receiving device includes a third electrode, an active layer, a first hole-transport layer, the electron-injection layer, and the second electrode stacked in this order over the substrate. The first electrode is supplied with a first potential. The second electrode is preferably supplied with a second potential lower than the first potential. The third electrode is preferably supplied with a third potential higher than the second potential.

### TECHNICAL FIELD

One embodiment of the present invention relates to a semiconductor device, a display apparatus, a display module, and an electronic device. One embodiment of the present invention relates to a method for fabricating a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### BACKGROUND ART

In recent years, information terminal devices, for example, mobile phones such as smartphones, tablet information terminals, and laptop PCs (personal computers) have been widely used. Such information terminal devices often include personal information or the like, and thus various authentication technologies for preventing unauthorized use have been developed. Information terminal devices have been required to have a variety of functions such as an image display function, a touch sensor function, and a function of fingerprint image capturing for authentication.

For example, Patent Document 1 discloses an electronic device including a fingerprint sensor in a push button switch portion.

For example, light-emitting apparatuses including light-emitting devices have been developed as display apparatuses. Light-emitting devices (also referred to as EL devices or EL elements) utilizing electroluminescence (hereinafter referred to as EL) have features such as ease of reduction in thickness and weight, high-speed response to input signals, and driving with a constant DC voltage power source, and have been used in display apparatuses.

### REFERENCE

### Patent Document

[Patent Document 1] United States Published Patent Application No. 2014/0056493

### SUMMARY OF THE INVENTION

### Problems to be Solved by the Invention

An object of one embodiment of the present invention is to provide a semiconductor device having a light detection function and including a high-resolution display portion. An object of one embodiment of the present invention is to provide a semiconductor device having a light detection function and including a high-definition display portion. An object of one embodiment of the present invention is to provide a semiconductor device having a light detection function and a large display portion. An object of one embodiment of the present invention is to provide a highly reliable semiconductor device having a light detection function.

An object of one embodiment of the present invention is to provide a method for fabricating a semiconductor device having a light detection function and including a high-resolution display portion. An object of one embodiment of the present invention is to provide a method for fabricating a semiconductor device having a light detection function and including a high-definition display portion. An object of one embodiment of the present invention is to provide a method for fabricating a semiconductor device having a light detection function and including a large display portion. An object of one embodiment of the present invention is to provide a method for fabricating a highly reliable semiconductor device having a light detection function. An object of one embodiment of the present invention is to provide a method for fabricating a semiconductor device having a light detection function with high yield.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display apparatus including a light-emitting device, a light-receiving device, and a substrate. The light-emitting device includes a first electrode, a light-emitting layer, a first electron-transport layer, an electron-injection layer, and a second electrode stacked in this order over the substrate. The light-receiving device includes a third electrode, an active layer, a first hole-transport layer, the electron-injection layer, and the second electrode stacked in this order over the substrate.

In the above-described display apparatus, the light-emitting device preferably includes a second hole-transport layer between the first electrode and the light-emitting layer.

In the above-described display apparatus, the light-receiving device preferably includes a second electron-transport layer between the third electrode and the active layer.

In the above-described display apparatus, it is preferable that the light-emitting device have a function of emitting visible light and the light-receiving device have a function of detecting visible light.

In the above-described display apparatus, it is preferable that the light-emitting device have a function of emitting infrared light and the light-receiving device have a function of detecting infrared light.

In the above-described display apparatus, the first electrode is supplied with a first potential. The second electrode is preferably supplied with a second potential lower than the first potential. The third electrode is preferably supplied with a third potential higher than the second potential.

In the above-described display apparatus, the first electrode and the third electrode are preferably provided on the same plane.

The above-described display apparatus includes a pixel portion including a plurality of first pixels, a plurality of second pixels, a plurality of third pixels, and a plurality of fourth pixels. The first pixels, the second pixels, the third pixels, and the fourth pixels each preferably include the light-emitting device or the light-receiving device. The pixel portion preferably includes a first arrangement where the second pixel, the first pixel, the second pixel, and the third pixel are repeatedly arranged in this order in a first direction, and a second arrangement where the fourth pixel, the first pixel, the fourth pixel, and the third pixel are repeatedly arranged in this order. The first arrangement and the second arrangement are alternately repeated in a second direction orthogonal to the first direction. The pixel portion preferably includes a third arrangement where the second pixel and the fourth pixel are alternately arranged repeatedly in the second direction, and a fourth arrangement where the first pixel and the third pixel are alternately arranged repeatedly. The third arrangement and the fourth arrangement are alternately repeated in the first direction.

In the above-described display apparatus, it is preferable that the first pixel, the second pixel, and the third pixel include the light-emitting devices emitting light in different wavelength ranges and the fourth pixel include the light-receiving device.

In the above-described display apparatus, the third pixel preferably includes a light-emitting device emitting green light. An area of the third pixel is preferably smaller than an area of the first pixel. The area of the third pixel is preferably smaller than an area of the second pixel.

One embodiment of the present invention is a display module including the above-described display apparatus and at least one of a connector and an integrated circuit.

One embodiment of the present invention is an electronic device including the above-described display module and at least one of a housing, a battery, a camera, a speaker, and a microphone.

### Effect of the Invention

One embodiment of the present invention can provide a semiconductor device having a light detection function and including a high-resolution display portion. One embodiment of the present invention can provide a semiconductor device having a light detection function and including a high-definition display portion. One embodiment of the present invention can provide a semiconductor device having a light detection function and including a large display portion. One embodiment of the present invention can provide a highly reliable semiconductor device having a light detection function.

One embodiment of the present invention can provide a method for fabricating a semiconductor device having a light detection function and including a high-resolution display portion. One embodiment of the present invention can provide a method for fabricating a semiconductor device having a light detection function and including a high-definition display portion. One embodiment of the present invention can provide a method for fabricating a semiconductor device having a light detection function and including a large display portion. One embodiment of the present invention can provide a method for fabricating a highly reliable semiconductor device having a light detection function. One embodiment of the present invention can provide a method for fabricating a semiconductor device having a light detection function with high yield.

Note that the description of these effects does not preclude the existence of other effects. One embodiment of the present invention does not need to have all of these effects. Other effects can be derived from the description of the specification, the drawings, and the claims.

### BRIEF DESCRIPTION OF THE DRAWINGS

FIG. 1A to FIG. 1C are diagrams illustrating structure examples of a display apparatus.

FIG. 2A to FIG. 2D are diagrams illustrating structure examples of display apparatuses.

FIG. 3A to FIG. 3C are diagrams illustrating structure examples of display apparatuses.

FIG. 4 is a diagram illustrating a structure example of a display apparatus.

FIG. 5A is a diagram illustrating a structure example of a display apparatus. FIG. 5B and FIG. 5C are circuit diagrams of pixel circuits.

FIG. 6A and FIG. 6B are timing charts showing driving methods of a display apparatus.

FIG. 7A and FIG. 7B are circuit diagrams of a pixel circuit.

FIG. 8A to FIG. 8C are circuit diagrams of a pixel circuit.

FIG. 9 is a circuit diagram of a pixel circuit.

FIG. 10A and FIG. 10B are diagrams illustrating structure examples of a display apparatus.

FIG. 11A and FIG. 11B are diagrams illustrating structure examples of a display apparatus.

FIG. 12A and FIG. 12B are diagrams illustrating structure examples of a display apparatus.

FIG. 13A and FIG. 13B are diagrams illustrating structure examples of a display apparatus.

FIG. 14A, FIG. 14B, and FIG. 14D are cross-sectional views illustrating examples of a display apparatus. FIG. 14C and FIG. 14E are diagrams illustrating examples of an image captured by the display apparatus.

FIG. 15 is a cross-sectional view illustrating an example of a display apparatus.

FIG. 16A to FIG. 16C are cross-sectional views illustrating an example of a display apparatus.

FIG. 17A to FIG. 17C are cross-sectional views illustrating an example of a display apparatus.

FIG. 18A to FIG. 18C are diagrams illustrating an example of a display apparatus.

FIG. 19A to FIG. 19C are diagrams illustrating an example of an electronic device.

FIG. 20A is a top view illustrating an example of a display apparatus. FIG. 20B is a cross-sectional view illustrating the example of the display apparatus.

FIG. 21A to FIG. 21I are top views illustrating examples of a pixel.

FIG. 22A to FIG. 22E are top views illustrating examples of a pixel.

FIG. 23A and FIG. 23B are top views illustrating examples of pixels.

FIG. 24A and FIG. 24B are top views illustrating examples of pixels.

FIG. 25A and FIG. 25B are top views illustrating examples of pixels.

FIG. 26A and FIG. 26B are top views illustrating examples of pixels.

FIG. 27A and FIG. 27B are top views illustrating examples of pixels.

FIG. 28A is a top view illustrating an example of a display apparatus. FIG. 28B is a cross-sectional view illustrating the example of the display apparatus.

FIG. 29A to FIG. 29F are top views illustrating an example of a method for fabricating a display apparatus.

FIG. 30A to FIG. 30C are cross-sectional views illustrating the example of a method for fabricating a display apparatus.

FIG. 31A to FIG. 31C are cross-sectional views illustrating the example of a method for fabricating a display apparatus.

FIG. 32A to FIG. 32C are cross-sectional views illustrating the example of a method for fabricating a display apparatus.

FIG. 33A and FIG. 33B are cross-sectional views illustrating the example of a method for fabricating a display apparatus.

FIG. 34A to FIG. 34C are cross-sectional views illustrating the example of a method for fabricating a display apparatus.

FIG. 35A to FIG. 35C are cross-sectional views illustrating the example of a method for fabricating a display apparatus.

FIG. 36A and FIG. 36B are cross-sectional views illustrating the example of a method for fabricating a display apparatus.

FIG. 37A to FIG. 37E are cross-sectional views illustrating the example of a method for fabricating a display apparatus.

FIG. 38A to FIG. 38F are cross-sectional views illustrating examples of a method for fabricating a display apparatus.

FIG. 39 is a perspective view illustrating an example of a display apparatus.

FIG. 40A is a cross-sectional view illustrating an example of a display apparatus. FIG. 40B and FIG. 40C are cross-sectional views illustrating examples of transistors.

FIG. 41 is a cross-sectional view illustrating an example of a display apparatus.

FIG. 42A and FIG. 42B are perspective views illustrating an example of a display module.

FIG. 43 is a cross-sectional view illustrating an example of a display apparatus.

FIG. 44 is a cross-sectional view illustrating an example of a display apparatus.

FIG. 45 is a cross-sectional view illustrating an example of a display apparatus.

FIG. 46 is a cross-sectional view illustrating an example of a display apparatus.

FIG. 47 is a cross-sectional view illustrating an example of a display apparatus.

FIG. 48A to FIG. 48D are diagrams illustrating examples of transistors.

FIG. 49A and FIG. 49B are diagrams illustrating an example of an electronic device.

FIG. 50A to FIG. 50D are diagrams illustrating examples of electronic devices.

FIG. 51A to FIG. 51F are diagrams illustrating examples of electronic devices.

FIG. 52 is a diagram illustrating an example of a vehicle.

FIG. 53A and FIG. 53B are diagrams showing the current density-voltage characteristics of light-receiving devices.

FIG. 54 is a diagram showing the current density-voltage characteristics of a light-receiving device.

FIG. 55A is a diagram showing the current density-voltage characteristics of a light-receiving device. FIG. 55B is a diagram showing the external quantum efficiency of the light-receiving device.

FIG. 56A is a diagram showing the current density-voltage characteristics of a light-receiving device. FIG. 56B is a diagram showing the external quantum efficiency of the light-receiving device.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. Moreover, similar functions are denoted by the same hatching pattern and are not denoted by specific reference numerals in some cases.

In addition, the position, size, range, or the like of each structure illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be interchanged with each other depending on the case or circumstances. For example, the term “conductive layer” can be changed into the term “conductive film”. As another example, the term “insulating film” can be changed into the term “insulating layer”.

### Embodiment 1

In this embodiment, a display apparatus of one embodiment of the present invention will be described.

The display apparatus of one embodiment of the present invention includes a display portion, and the display portion includes a plurality of pixels arranged in a matrix. The pixel includes a light-emitting device (also referred to as a light-emitting element) and a light-receiving device (also referred to as a light-receiving element).

The light-emitting device functions as a display device (also referred to as a display element). In the display apparatus of one embodiment of the present invention, the light-emitting devices are arranged in a matrix in the display portion, and an image can be displayed on the display portion. In addition, the display apparatus of one embodiment of the present invention has a function of detecting light with the use of the light-receiving devices.

As the light-emitting device, an EL device such as an OLED (Organic Light Emitting Diode) or a QLED (Quantum-dot Light Emitting Diode) is preferably used. Examples of a light-emitting substance contained in the EL device include a substance exhibiting fluorescence (a fluorescent material), a substance exhibiting phosphorescence (a phosphorescent material), an inorganic compound (e.g., a quantum dot material), and a substance exhibiting thermally activated delayed fluorescence (a thermally activated delayed fluorescence (TADF) material). In addition, an LED (Light Emitting Diode) such as a micro-LED can be used as the light-emitting device. Note that as a TADF material, a material that is in a thermal equilibrium state between a singlet excited state and a triplet excited state may be used. Since such a TADF material enables a short emission lifetime (excitation lifetime), an efficiency decrease of a light-emitting device in a high-luminance region can be inhibited.

The light-receiving devices are arranged in a matrix in the display portion of the display apparatus of one embodiment of the present invention, and the display portion has one or both of an image capturing function and a sensing function in addition to an image displaying function. The display portion can be used as an image sensor or a touch sensor. That is, by detecting light with the display portion, an image can be captured or an approach or touch of an object (e.g., a finger, a hand, or a pen) can be detected. Furthermore, in the display apparatus of one embodiment of the present invention, the light-emitting devices can be used as a light source of the sensor. Accordingly, a light-receiving portion and a light source do not need to be provided separately from the display apparatus; hence, the number of components of an electronic device can be reduced.

In the case where the light-receiving devices are used as the image sensor, the display apparatus can capture an image using the light-receiving devices. For example, the display apparatus of this embodiment can be used as a scanner.

For example, data on biological information such as a fingerprint or a palm print can be obtained with the use of the image sensor. That is, a biometric authentication sensor can be incorporated in the display apparatus. When the display apparatus incorporates a biometric authentication sensor, the number of components of an electronic device can be reduced as compared with the case where a biometric authentication sensor is provided separately from the display apparatus; thus, the size and weight of the electronic device can be reduced.

In the case where the light-receiving devices are used as the touch sensor, the display apparatus can detect an approach or touch of an object with the use of the light-receiving devices.

More specific examples are described below with reference to drawings.

### <Structure Example 1>

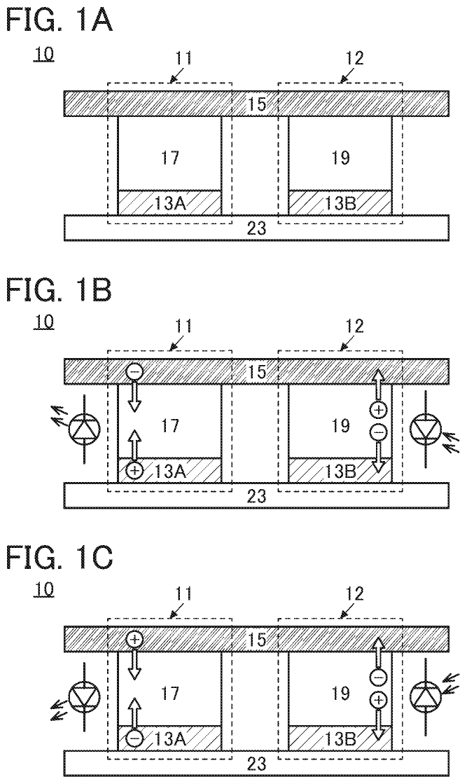

In this embodiment, a light-emitting device and a light-receiving device that can be used for the display apparatus of one embodiment of the present invention are described. FIG. 1A is a schematic cross-sectional view illustrating a light-emitting device 11 and a light-receiving device 12 included in a display apparatus 10 of one embodiment of the present invention.

The light-emitting device 11 has a function of emitting light (hereinafter, also referred to as a light-emitting function). The light-emitting device 11 includes an electrode 13A, an EL layer 17, and an electrode 15. The light-emitting device 11 is preferably an organic EL device (organic electroluminescent device). The EL layer 17 interposed between the electrode 13A and the electrode 15 at least includes a light-emitting layer. The light-emitting layer contains a light-emitting substance that emits light. The EL layer 17 emits light when a voltage is applied between the electrode 13A and the electrode 15. The EL layer 17 can further include any of a variety of layers such as a hole-injection layer, a hole-transport layer, an electron-transport layer, an electron-injection layer, a carrier-blocking layer, an exciton-blocking layer, and a charge generation layer.

The emission color of the light-emitting device can be red, green, blue, cyan, magenta, yellow, white, or the like depending on the material contained in the EL layer 17. Furthermore, the color purity can be further increased when the light-emitting device has a microcavity structure.

The light-receiving device 12 has a function of detecting light (hereinafter, also referred to as a light-receiving function). For example, a pn or pin photodiode can be used as the light-receiving device 12. The light-receiving device 12 includes an electrode 13B, a light-receiving layer 19, and the electrode 15. Thus, the light-receiving layer 19 interposed between the electrode 13B and the electrode 15 includes at least an active layer. The light-receiving device 12 functions as a photoelectric conversion device; charge can be generated by light incident on the light-receiving layer 19 and extracted as a current. At this time, a voltage may be applied between the electrode 13B and the electrode 15. The amount of generated charge is determined depending on the amount of light incident on the light-receiving layer 19.

The light-receiving device 12 has a function of detecting visible light. The light-receiving device 12 has sensitivity to visible light. The light-receiving device 12 further preferably has a function of detecting visible light and infrared light. The light-receiving device 12 preferably has sensitivity to visible light and infrared light.

In this specification and the like, a blue (B) wavelength range is greater than or equal to 400 nm and less than 490 nm, and blue (B) light has at least one emission spectrum peak in the wavelength range. A green (G) wavelength range is greater than or equal to 490 nm and less than 580 nm, and green (G) light has at least one emission spectrum peak in the wavelength range. A red (R) wavelength range is greater than or equal to 580 nm and less than 700 nm, and red (R) light has at least one emission spectrum peak in the wavelength range. In this specification and the like, a wavelength range of visible light is greater than or equal to 400 nm and less than 700 nm, and visible light has at least one emission spectrum peak in the wavelength range. An infrared (IR) wavelength range is greater than or equal to 700 nm and less than 900 nm, and infrared (IR) light has at least one emission spectrum peak in the wavelength range.

The active layer includes a semiconductor. Examples of the semiconductor include an inorganic semiconductor such as silicon and an organic semiconductor including an organic compound. It is particularly preferable to use an organic photodiode including a layer containing an organic semiconductor, as the light-receiving device 12. An organic photodiode, which is easily made thin, lightweight, and large in area and has a high degree of freedom for shape and design, can be used in a variety of display apparatuses. An organic semiconductor is preferably used, in which case the EL layer included in the light-emitting device 11 and the light-receiving layer included in the light-receiving device 12 can be formed by the same method (e.g., a vacuum evaporation method) with the same manufacturing apparatus.

In the display apparatus of one embodiment of the present invention, an organic EL device can be used as the light-emitting device 11 and an organic photodiode can be suitably used as the light-receiving device 12. The organic EL device and the organic photodiode can be formed over the same substrate. Thus, the organic photodiode can be incorporated in the display apparatus including the organic EL device. The display apparatus of one embodiment of the present invention has one or both of an image capturing function and a sensing function in addition to an image displaying function.

The electrode 13A and the electrode 13B are provided on the same plane. FIG. 1A illustrates a structure where the electrode 13A and the electrode 13B are provided over a substrate 23. The electrode 13A and the electrode 13B can be formed by processing a conductive film formed over the substrate 23 into island-like shapes, for example. In other words, the electrode 13A and the electrode 13B can be formed through the same process.

As the substrate 23, a substrate having heat resistance high enough to withstand the formation of the light-emitting device 11 and the light-receiving device 12 can be used. In the case where an insulating substrate is used as the substrate 23, a glass substrate, a quartz substrate, a sapphire substrate, a ceramic substrate, an organic resin substrate, or the like can be used. Alternatively, a single crystal semiconductor substrate or a polycrystalline semiconductor substrate using silicon or silicon carbide as a material, a compound semiconductor substrate of silicon germanium or the like, or a semiconductor substrate such as an SOI substrate can be used.

As the substrate 23, it is particularly preferable to use the insulating substrate or the semiconductor substrate over which a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

The electrode 13A and the electrode 13B can each be referred to as a pixel electrode. The electrode 15 is a layer shared by the light-emitting device 11 and the light-receiving device 12, and can be referred to as a common electrode. A conductive film transmitting visible light and infrared light is used as the pixel electrode or the common electrode through which light exits or enters. A conductive film reflecting visible light and infrared light is preferably used as the electrode through which light neither exits nor enters.

The display apparatus of one embodiment of the present invention has a structure where the electrode 15 functioning as the common electrode functions as one of an anode and a cathode in the light-emitting device 11 and functions as the other of the anode and the cathode in the light-receiving device 12.

FIG. 1B schematically illustrates a structure where the electrode 13A functions as the anode and the electrode 15 functions as the cathode in the light-emitting device 11, and the electrode 13B functions as the cathode and the electrode 15 functions as the anode in the light-receiving device 12. For easy understanding of the direction of the anode and the cathode, FIG. 1B illustrates a circuit symbol of a light-emitting diode on the left of the light-emitting device 11 and a circuit symbol of a photodiode on the right of the light-receiving device 12. In addition, an electron is indicated by a circle with a sign of − (minus), a hole is indicated by a circle with a sign of + (plus), and flow directions of the electron and the hole are schematically indicated by arrows.

In the light-emitting device 11, the electrode 13A functions as the anode and is electrically connected to a first wiring that supplies a first potential. In the light-emitting device 11, the electrode 15 functions as the cathode and is electrically connected to a second wiring that supplies a second potential. The second potential is a potential lower than the first potential.

In the light-receiving device 12, the electrode 13B functions as the cathode and is electrically connected to a third wiring that supplies a third potential. In the light-receiving device 12, the electrode 15 functions as the anode and is electrically connected to the second wiring that supplies the second potential. Here, a reverse bias voltage is applied to the light-receiving device 12. That is, the third potential is a potential higher than the second potential.

With a structure where the electrode 13A functions as the anode and the electrode 15 functions as the cathode in the light-emitting device 11 and the electrode 13B functions as the cathode and the electrode 15 functions as the anode in the light-receiving device 12, a potential difference between the electrode 13A and the electrode 13B can be small, whereby leakage (hereinafter, also referred to as side leakage) between the electrode 13A and the electrode 13B can be inhibited. Thus, the light-receiving device can have a high SN ratio (Signal to Noise Ratio).

For example, the first potential (a potential supplied to the electrode 13A) can be 12 V, the second potential (a potential supplied to the electrode 15) can be 0 V, and the third potential (a potential supplied to the electrode 13B) can be 4 V. With such a structure, a potential difference between the electrode 13A and the electrode 13B can be small, whereby side leakage between the light-emitting device 11 and the light-receiving device 12 can be inhibited.

Furthermore, a difference between the highest potential and the lowest potential among the first potential (a potential supplied to the electrode 13A), the second potential (a potential supplied to the electrode 15), and the third potential (a potential supplied to the electrode 13B) can be small, whereby a display apparatus with low power consumption can be achieved.

In the display apparatus of one embodiment of the present invention, the side leakage between the light-emitting device 11 and the light-receiving device 12 can be inhibited, which allows a short distance between the light-emitting device 11 and the light-receiving device 12. That is, the proportions of the light-emitting device 11 and the light-receiving device 12 in a pixel (hereinafter, also referred to as an aperture ratio) can be increased. In addition, the size of a pixel can be reduced, so that the resolution of the display apparatus can be increased. Thus, a display apparatus having a light detection function and a high aperture ratio can be achieved. In addition, a display apparatus having a light detection function and a high resolution can be achieved.

Note that the light-receiving devices 12 can be arranged at a resolution higher than or equal to 100 ppi, preferably higher than or equal to 200 ppi, more preferably higher than or equal to 300 ppi, further preferably higher than or equal to 400 ppi, still further preferably higher than or equal to 500 ppi and lower than or equal to 2000 ppi, lower than or equal to 1000 ppi, or lower than or equal to 600 ppi, for example. In particular, when the light-receiving devices 12 are provided at a resolution higher than or equal to 200 ppi and lower than or equal to 600 ppi, preferably higher than or equal to 300 ppi and lower than or equal to 600 ppi, the display apparatus can be suitably used for fingerprint image capturing. In the case where fingerprint authentication is performed with the display apparatus of one embodiment of the present invention, the increased resolution of the light-receiving device 12 enables, for example, highly accurate extraction of the minutiae of fingerprints; thus, the accuracy of the fingerprint authentication can be increased. The resolution is preferably higher than or equal to 500 ppi, in which case the authentication conforms to the standard by the National Institute of Standards and Technology (NIST) or the like. On the assumption that the light-receiving devices are arranged at a resolution of 500 ppi, the size of a pixel is 50.8 μm, which is a resolution adequate for image capturing of a fingerprint ridge distance (typically, greater than or equal to 300 μm and less than or equal to 500 μm).

As illustrated in FIG. 1C, the display apparatus 10 of one embodiment of the present invention may have a structure where the electrode 13A functions as the cathode and the electrode 15 functions as the anode in the light-emitting device 11, and the electrode 13B functions as the anode and the electrode 15 functions as the cathode in the light-receiving device 12.

In the light-emitting device 11, the electrode 13A functions as the cathode and is electrically connected to the first wiring that supplies the first potential. In the light-emitting device 11, the electrode 15 functions as the anode and is electrically connected to the second wiring that supplies the second potential. The second potential is a potential higher than the first potential.

In the light-receiving device 12, the electrode 13B functions as the anode and is electrically connected to the third wiring that supplies the third potential. In the light-receiving device 12, the electrode 15 functions as the cathode and is electrically connected to the second wiring that supplies the second potential. Here, a reverse bias potential is applied to the light-receiving device 12. That is, the third potential is a potential lower than the second potential. With such a structure, a potential difference between the electrode 13A and the electrode 13B can be small, whereby leakage between the electrode 13A and the electrode 13B can be inhibited.

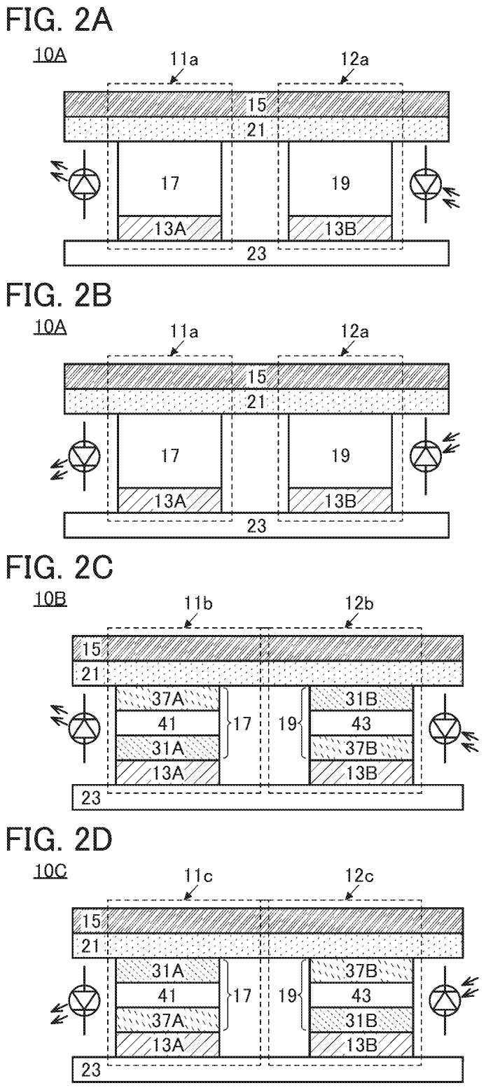

FIG. 2A illustrates an example different from that of the above-described display apparatus 10. A display apparatus 10A illustrated in FIG. 2A includes a light-emitting device 11a and a light-receiving device 12a. The display apparatus 10A is different from the above-described display apparatus 10 mainly in that the light-emitting device 11a includes a layer 21 between the EL layer 17 and the electrode 15, and the light-receiving device 12a includes the layer 21 between the light-receiving layer 19 and the electrode 15. The layer 21 is a layer shared by the light-emitting device 11a and the light-receiving device 12a, and can be referred to as a common layer. For example, at least one of a hole-injection layer, a hole-transport layer, an electron-transport layer, and an electron-injection layer is preferably a layer shared by the light-receiving device and the light-emitting device.

In the case where the electrode 13A functions as an anode and the electrode 15 functions as a cathode in the light-emitting device 11a and the electrode 13B functions as a cathode and the electrode 15 functions as an anode in the light-receiving device 12a, as illustrated in FIG. 2A, the layer 21 includes a layer containing a substance with a high electron-injection property (an electron-injection layer), for example. In the light-emitting device 11a, the layer 21 can function as an electron-injection layer that injects electrons from the electrode 15 functioning as the cathode to the EL layer 17.

Note that in the light-receiving device 12a, the layer 21 including the layer with a high electron-injection property (the electron-injection layer), for example, does not have a specific function. As described above, the layer 21 is configured to function as the electron-injection layer in the light-emitting device 11a.

In some cases, a layer shared by the light-receiving device and the light-emitting device have different functions in the light-emitting device and the light-receiving device. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. In other cases, a layer shared by the light-receiving device and the light-emitting device have the same function in both the light-emitting device and the light-receiving device. The hole-transport layer functions as a hole-transport layer in both the light-emitting device and the light-receiving device, and the electron-transport layer functions as an electron-transport layer in both the light-emitting device and the light-receiving device.

In the case where the electrode 13A functions as the cathode and the electrode 15 functions as the anode in the light-emitting device 11a and the electrode 13B functions as the anode and the electrode 15 functions as the cathode in the light-receiving device 12a, as illustrated in FIG. 2B, the layer 21 includes a layer containing a substance with a high hole-injection property (a hole-injection layer), for example. In the light-emitting device 11a, the layer 21 can function as a hole-injection layer that injects holes from the electrode 15 functioning as the anode to the EL layer 17.

Note that in the light-receiving device 12a, the layer 21 including the layer with a high hole-injection property (the hole-injection layer), for example, does not have a specific function. As described above, the layer 21 is configured to function as the hole-injection layer in the light-emitting device 11a.

FIG. 2C illustrates a display apparatus of one embodiment of the present invention. A display apparatus 10B illustrated in FIG. 2C includes a light-emitting device 11b and a light-receiving device 12b. The EL layer 17 included in the light-emitting device 11b has a stacked-layer structure where a layer 31A, a light-emitting layer 41, and a layer 37A are stacked in this order. The light-receiving layer 19 included in the light-receiving device 12b has a stacked-layer structure where a layer 37B, an active layer 43, and a layer 31B are stacked in this order.

In the light-emitting device 11b, the electrode 13A functions as an anode and the electrode 15 functions as a cathode. In the light-receiving device 12, the electrode 13B functions as a cathode and the electrode 15 functions as an anode. The layer 21 includes, for example, a layer containing a substance with a high electron-injection property (an electron-injection layer).

The layer 31A and the layer 31B each include, for example, a layer containing a substance with a high hole-transport property (a hole-transport layer). Furthermore, the layer 31A and the layer 31B may each include a layer containing a substance with a high hole-injection property (a hole-injection layer). Note that in the case where the layer 31A and the layer 31B each contain a substance with a high hole-transport property, the substance with a high hole-transport property contained in the layer 31A and the substance with a high hole-transport property contained in the layer 31B may be the same or different from each other. Similarly, in the case where the layer 31A and the layer 31B each contain a substance with a high hole-injection property, the substance with a high hole-injection property contained in the layer 31A and the substance with a high hole-injection property contained in the layer 31B may be the same or different from each other. In addition, the layer 31A and the layer 31B may each have a stacked-layer structure.

The layer 37A and the layer 37B each include, for example, a layer containing a substance with a high electron-transport property (an electron-transport layer). Furthermore, the layer 37A and the layer 37B may each include a layer containing a substance with a high electron-injection property (an electron-injection layer). In the case where the layer 37A and the layer 37B each contain a substance with a high electron-transport property, the substance with a high electron-transport property contained in the layer 37A and the substance with a high electron-transport property contained in the layer 37B may be the same or different from each other. Similarly, in the case where the layer 37A and the layer 37B each contain a substance with a high electron-injection property, the substance with a high electron-injection property contained in the layer 37A and the substance with a high electron-injection property contained in the layer 37B may be the same or different from each other. In addition, the layer 37A and the layer 37B may each have a stacked-layer structure.

The active layer 43 includes a semiconductor. In particular, the active layer 43 preferably includes an organic semiconductor.

The light-emitting layer 41 contains a light-emitting substance that emits light. In the light-emitting device 11, a structure including the layer 31A, the light-emitting layer 41, and the layer 37A provided between a pair of electrodes (the electrode 13A and the electrode 15) can function as a single light-emitting unit; in this specification and the like, the structure of the light-emitting device 11b is referred to as a single structure in some cases.

The light-emitting device 11b includes the layer 31A including the layer containing a substance with a high hole-transport property (the hole-transport layer), the light-emitting layer 41, and the layer 37A including the layer containing a substance with a high electron-transport property (the electron-transport layer) in this order from the electrode 13A side. The light-receiving device 12b includes the layer 37B including the layer containing a substance with a high electron-transport property (the electron-transport layer), the active layer 43, and the layer 31B including the layer containing a substance with a high hole-transport property (the hole-transport layer) in this order from the electrode 13B side. In the display apparatus of one embodiment of the present invention, the layer containing a substance with a high electron-transport property (the electron-transport layer) and the layer containing a substance with a high hole-transport property (the hole-transport layer), between which the light-emitting layer or the active layer is interposed, is stacked in the opposite order in the light-emitting device and the light-receiving device. With such a structure, side leakage between the light-emitting device and the light-receiving device can be inhibited.

FIG. 2D illustrates a structure different from that of the above-described display apparatus 10B. A display apparatus 10C illustrated in FIG. 2D includes a light-emitting device 11c and a light-receiving device 12c. The light-emitting device 11c is different from the light-emitting device 11b mainly in that the stacking order of the layers included in the EL layer 17 is reversed. The light-receiving device 12c is different from the light-receiving device 12b mainly in that the stacking order of the layers included in the light-receiving layer 19 is reversed.

The EL layer 17 included in the light-emitting device 11c has a stacked-layer structure where the layer 37A, the light-emitting layer 41, and the layer 31A are stacked in this order. The light-receiving layer 19 included in the light-receiving device 12c has a stacked-layer structure where the layer 31B, the active layer 43, and the layer 37B are stacked in this order.

In the light-emitting device 11b, the electrode 13A functions as the cathode and the electrode 15 functions as the anode. In the light-receiving device 12, the electrode 13B functions as the anode and the electrode 15 functions as the cathode. The layer 21 includes, for example, a layer containing a substance with a high hole-injection property (a hole-injection layer).

A structure different from that of the above-described display apparatus will be described. Described below as an example is a structure where the electrode 13A functions as the anode and the electrode 15 functions as the cathode in the light-emitting device, and the electrode 13B functions as the cathode and the electrode 15 functions as the anode in the light-receiving device.

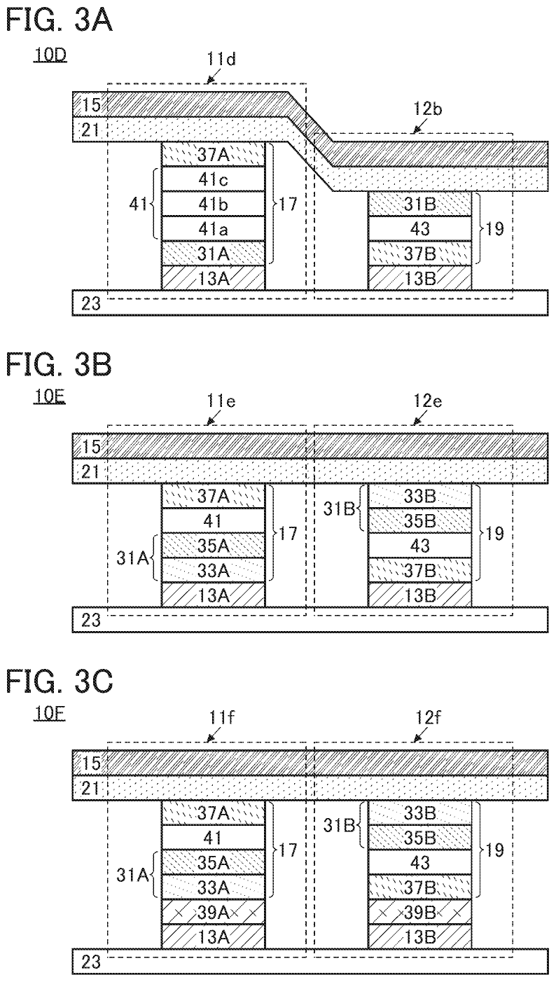

FIG. 3A illustrates a display apparatus of one embodiment of the present invention. A display apparatus 10D illustrated in FIG. 3A includes a light-emitting device 11d and the light-receiving device 12b. The light-emitting layer 41 included in the light-emitting device 11d has a stacked-layer structure where a light-emitting layer 41a, a light-emitting layer 41b, and a light-emitting layer 41c are stacked in this order. A structure where a plurality of light-emitting layers (e.g., the light-emitting layer 41a, the light-emitting layer 41b, and the light-emitting layer 41c) between the layer 31A and the layer 37A can also be referred to as a single structure.

FIG. 3B illustrates a display apparatus of one embodiment of the present invention. A display apparatus 10E illustrated in FIG. 3B includes a light-emitting device 11e and a light-receiving device 12e.

The light-emitting device 11e is different from the above-described light-emitting device 11b mainly in that the layer 31A has a stacked-layer structure of a layer 33A and a layer 35A over the layer 33A. The light-receiving device 12e is different from the above-described light-receiving device 12b mainly in that the layer 31B has a stacked-layer structure of a layer 35B and a layer 33B over the layer 35B.

The layer 33A and the layer 33B each include, for example, a layer containing a substance with a high hole-injection property (a hole-injection layer). The substance with a high hole-injection property contained in the layer 33A and the substance with a high hole-injection property contained in the layer 33B may be the same or different from each other.

The layer 35A and the layer 35B each include, for example, a layer containing a substance with a high hole-transport property (a hole-transport layer). The substance with a high hole-transport property contained in the layer 35A and the substance with a high hole-transport property contained in the layer 35B may be the same or different from each other.

With such a layer structure, the light-emitting device 11e can efficiently inject carriers to the light-emitting layer 41, and the efficiency of the recombination of carriers in the light-emitting layer 41 can be enhanced. Note that as described above, the layer 33B functions as a hole-transport layer in the light-receiving device 12e.

FIG. 3C illustrates a display apparatus of one embodiment of the present invention. A display apparatus 10F illustrated in FIG. 3C includes a light-emitting device 11f and a light-receiving device 12f.

The light-emitting device 11f is different from the above-described light-emitting device 11e mainly in that an optical adjustment layer 39A is included between the electrode 13A and the EL layer 17. The light-receiving device 12f is different from the above-described light-receiving device 12e mainly in that an optical adjustment layer 39B is included between the electrode 13B and the light-receiving layer 19.

The optical adjustment layer 39A and the optical adjustment layer 39B are each preferably formed using a conductive material having a high transmitting property with respect to visible light. It is further preferable that the optical adjustment layer 39A and the optical adjustment layer 39B be each formed using a conductive material having a high transmitting property with respect to visible light and infrared light. For example, the optical adjustment layer 39A and the optical adjustment layer 39B can each be formed using a conductive oxide such as indium oxide, indium tin oxide, indium zinc oxide, zinc oxide, zinc oxide containing gallium, indium tin oxide containing silicon, or indium zinc oxide containing silicon.

Here, a conductive film having a reflecting property with respect to visible light is used for the electrode 13A and the electrode 13B, and a conductive film having a reflecting property and a transmitting property with respect to visible light is used for the common electrode 15. Thus, the light-emitting device 11f and the light-receiving device 12f each achieve what is called a microcavity structure. The light-emitting device 11f intensifies light with a specific wavelength, and thus can be a light-emitting device with high color purity. The light-receiving device 12f intensifies light with a specific wavelength to be detected, and thus can be a light-receiving device with high sensitivity.

Note that by making the thicknesses of the optical adjustment layer 39A included in the light-emitting device 11f and the optical adjustment layer 39B included in the light-receiving device 12f different, the optical path lengths can be different. The optical adjustment layers may be formed using conductive films with different thicknesses, or may have different structures by employing a single-layer structure and a multi-layer structure.

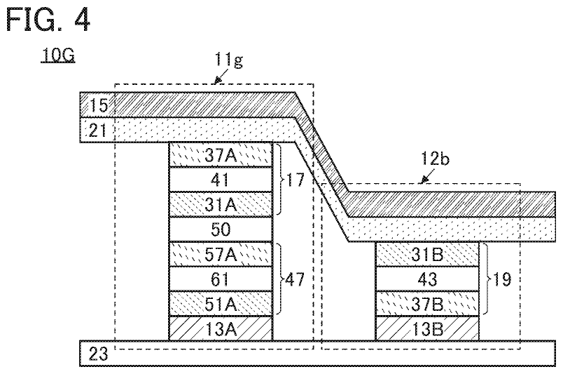

FIG. 4 illustrates a display apparatus of one embodiment of the present invention. A display apparatus 10G illustrated in FIG. 4 includes a light-emitting device 11g and the light-receiving device 12b.

The light-emitting device 11g has a stacked-layer structure where an EL layer 47, an intermediate layer 50, and the EL layer 17 are stacked in this order, between the electrode 13A and the electrode 15. The EL layer 47 has a stacked-layer structure where a layer 51A, a light-emitting layer 61, and a layer 57A are stacked in this order.

Note that the layer 51A, the light-emitting layer 61, and the layer 57A may each have a stacked-layer structure. Since the description of the layer 31A can be referred to for the layer 51A, the detailed description thereof is omitted. Since the description of the light-emitting layer 41 can be referred to for the light-emitting layer 61, the detailed description thereof is omitted. Since the description of the layer 37A can be referred to for the layer 57A, the detailed description thereof is omitted.

A structure where a plurality of light-emitting units (the EL layer 17 and the EL layer 47) are connected in series with the intermediate layer 50 (also referred to as a charge generation layer) therebetween, as in the light-emitting device 11g, is sometimes referred to as a tandem structure in this specification and the like. Note that the tandem structure may be referred to as a stack structure. The tandem structure enables a light-emitting device capable of high-luminance light emission.

The emission color of the light-emitting device can be red, green, blue, cyan, magenta, yellow, white, or the like depending on the combination of the material contained in the EL layer 17 and the material contained in the EL layer 47. Furthermore, the color purity can be further increased when the light-emitting device has a microcavity structure.

The light-emitting device that emits white light preferably contains two or more kinds of light-emitting substances in the light-emitting layer 41. In the case of a structure containing two light-emitting substances, the light-emitting substances are selected such that their emission colors are complementary. For example, when an emission color of a first light-emitting substance and an emission color of a second light-emitting substance are complementary, the light-emitting device can be configured to emit white light as a whole. In the case of a structure containing three or more light-emitting substances, white light emission can be obtained by mixing emission colors of the light-emitting substances. Similarly, in the case of a light-emitting device including two or more light-emitting layers, white light emission can be obtained by mixing emission colors of the light-emitting layers. For example, in the light-emitting device 11d illustrated in FIG. 3A, the emission colors of the light-emitting layer 41a, the light-emitting layer 41b, and the light-emitting layer 41c are mixed, so that a white-light-emitting device with a single structure can be achieved.

The light-emitting layer preferably contains two or more of light-emitting substances that emit light of red (R), green (G), blue (B), yellow (Y), orange (0), and the like.

Alternatively, the light-emitting layer preferably contains two or more light-emitting substances that emit light containing two or more of spectral components of R, G, and B.

Note that there is no particular limitation on the combination of the light-emitting device and the light-receiving device. The display apparatus can include one or more of the above-described light-emitting devices and one or more of the above-described light-receiving devices. For example, the display apparatus may include the light-emitting device 11e and the light-receiving device 12c.

### <Structure Example 2>

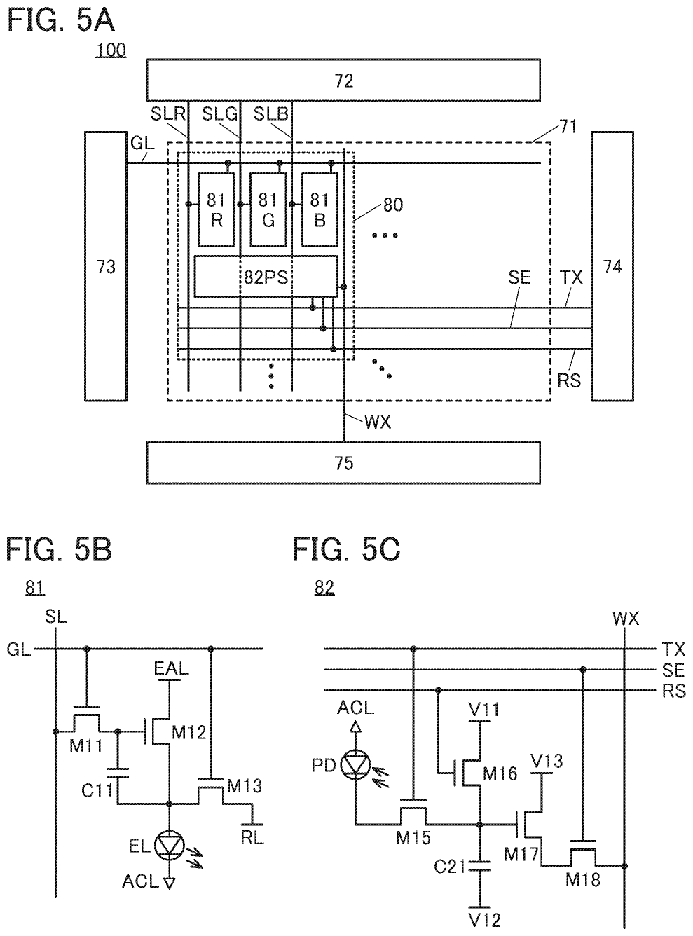

FIG. 5A is a block diagram of a display apparatus 100. The display apparatus 100 includes a display portion 71, a driver circuit portion 72, a driver circuit portion 73, a driver circuit portion 74, a circuit portion 75, and the like.

The display portion 71 includes a plurality of pixels 80 arranged in a matrix. The pixel 80 includes a subpixel 81R, a subpixel 81G, a subpixel 81B, and a subpixel 82PS. The subpixel 81R, the subpixel 81G, and the subpixel 81B each include a light-emitting device functioning as a display device. As the light-emitting device, any of the above-described light-emitting devices can be used, for example. The subpixel 82PS includes a light-receiving device functioning as a photoelectric conversion element. As the light-receiving device, any of the above-described light-receiving devices can be used, for example.

Note that in this specification and the like, although a minimum unit in which independent operation is performed in one “pixel” is defined as a “subpixel” in the description for convenience, a “pixel” may be replaced with a “region” and a “subpixel” may be replaced with a “pixel”.

The pixel 80 is electrically connected to a wiring GL, a wiring SLR, a wiring SLG, a wiring SLB, a wiring TX, a wiring SE, a wiring RS, a wiring WX, and the like. The wiring SLR, the wiring SLG, and the wiring SLB are electrically connected to the driver circuit portion 72. The wiring GL is electrically connected to the driver circuit portion 73. The driver circuit portion 72 functions as a source line driver circuit (also referred to as a source driver). The driver circuit portion 73 functions as a gate line driver circuit (also referred to as a gate driver).

The pixel 80 includes the subpixel 81R, the subpixel 81G, and the subpixel 81B as the subpixels each including a light-emitting device. For example, the subpixel 81R is a subpixel exhibiting a red color, the subpixel 81G is a subpixel exhibiting a green color, and the subpixel 81B is a subpixel exhibiting a blue color. Thus, the display apparatus 100 can perform full-color display. Note that although the example where the pixel 80 includes subpixels of three colors is shown here, subpixels of four or more colors may be included.

The subpixel 81R includes a light-emitting device that emits red light. The subpixel 81G includes a light-emitting device that emits green light. The subpixel 81B includes a light-emitting device that emits blue light. Note that the pixel 80 may include a subpixel including a light-emitting device that emits light of another color. For example, the pixel 80 may include, in addition to the three subpixels, a subpixel including a light-emitting device that emits white light, a subpixel including a light-emitting device that emits yellow light, or the like. The wiring GL is electrically connected to the subpixel 81R, the subpixel 81G, and the subpixel 81B arranged in a row direction (an extending direction of the wiring GL). The wiring SLR, the wiring SLG, and the wiring SLB are electrically connected to the subpixels 81R, the subpixels 81G, and the subpixels 81B arranged in a column direction (extending directions of the wiring SLR and the like), respectively.

The subpixel 82PS included in the pixel 80 is electrically connected to the wiring TX, the wiring SE, the wiring RS, and the wiring WX. The wiring TX, the wiring SE, and the wiring RS are electrically connected to the driver circuit portion 74, and the wiring WX is electrically connected to the circuit portion 75.

The driver circuit portion 74 has a function of generating a signal for driving the subpixel 82PS and outputting the signal to the subpixel 82PS through the wiring SE, the wiring TX, and the wiring RS. The circuit portion 75 has a function of receiving a signal output from the subpixel 82PS through the wiring WX and outputting the signal to the outside as image data. The circuit portion 75 functions as a reading circuit.

### <Structure Example of Pixel Circuit>

FIG. 5B illustrates an example of a circuit diagram of a pixel 81 that can be used as the subpixel 81R, the subpixel 81G, and the subpixel 81B. The pixel 81 includes a transistor M11, a transistor M12, a transistor M13, a capacitor C11, and a light-emitting device EL. The wiring GL and a wiring SL are electrically connected to the pixel 81. The wiring SL corresponds to any of the wiring SLR, the wiring SLG, and the wiring SLB illustrated in FIG. 5A. Any of the above-described light-emitting devices can be used as the light-emitting device EL.

A gate of the transistor M11 is electrically connected to the wiring GL, one of a source and a drain of the transistor M11 is electrically connected to the wiring SL, and the other thereof is electrically connected to one electrode of the capacitor C11 and a gate of the transistor M12. One of a source and a drain of the transistor M12 is electrically connected to a wiring EAL, and the other of the source and the drain of the transistor M12 is electrically connected to one electrode of the light-emitting device EL, the other electrode of the capacitor C11, and one of a source and a drain of the transistor M13. A gate of the transistor M13 is electrically connected to the wiring GL, and the other of the source and the drain of the transistor M13 is electrically connected to a wiring RL. The other electrode of the light-emitting device EL is electrically connected to a wiring ACL.

The transistor M11 and the transistor M13 each function as a switch. The transistor M12 functions as a transistor that controls current flowing through the light-emitting device EL.

Here, transistors containing silicon in the channel formation regions (hereinafter referred to as Si transistors) are preferably used as all of the transistor M11 to the transistor M13. Alternatively, it is preferable that a transistor including a metal oxide (hereinafter also referred to as an oxide semiconductor) in its channel formation region (hereinafter such a transistor is also referred to as an OS transistor) be used as each of the transistor M11 and the transistor M13 and a Si transistor be used as the transistor M12.

As silicon, single crystal silicon, polycrystalline silicon, amorphous silicon, and the like can be given. A Si transistor has high field-effect mobility and favorable frequency characteristics. For example, a transistor containing low-temperature polysilicon (LTPS) in its channel formation region (hereinafter such a transistor is also referred to as an LTPS transistor) can be used.

With the use of Si transistors such as LTPS transistors, a circuit required to be driven at a high frequency (e.g., a source driver circuit) can be formed on the same substrate as the display portion. Thus, external circuits mounted on the display apparatus can be simplified, and the component cost and the mounting cost can be reduced.

The oxide semiconductor preferably contains indium, a metal M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Further alternatively, it is preferable to use an oxide containing indium, gallium, tin, and zinc.

An OS transistor using an oxide semiconductor having a wider band gap and a lower carrier density than silicon can achieve an extremely low off-state current. Thus, such a low off-state current enables long-term retention of charge accumulated in a capacitor that is connected in series with the OS transistor. Therefore, it is particularly preferable to use an OS transistor as the transistor M11 and the transistor M13 each of which is connected in series with the capacitor C11. The use of the OS transistor as each of the transistor M11 and the transistor M13 can prevent leakage of charge retained in the capacitor C11 through the transistor M11 or the transistor M13. Furthermore, since charge retained in the capacitor C11 can be retained for a long period, a still image can be displayed for a long period without rewriting data in the pixel 81.

A data potential is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. A first potential is supplied to the wiring EAL. A second potential is supplied to the wiring ACL. The wiring EAL is electrically connected to an anode of the light-emitting device EL and has a function of supplying the first potential to the anode of the light-emitting device EL. The wiring ACL is electrically connected to a cathode of the light-emitting device EL and has a function of supplying the second potential to the cathode of the light-emitting device EL. The second potential is a potential lower than the first potential. In the pixel 81, the first potential can be referred to as an anode potential, and the second potential can be referred to as a cathode potential. The reset potential supplied to the wiring RL can be set such that a potential difference between the reset potential and the cathode potential is lower than the threshold voltage of the light-emitting device EL. The reset potential can be a potential higher than the cathode potential, a potential equal to the cathode potential, or a potential lower than the cathode potential.

FIG. 5C illustrates an example of a circuit diagram that can be employed for the subpixel 82PS. A pixel 82 includes a transistor M15, a transistor M16, a transistor M17, a transistor M18, a capacitor C21, a light-receiving device PD, and the like. Any of the above-described light-receiving devices can be used as the light-receiving device PD.

A gate of the transistor M15 is electrically connected to the wiring TX, one of a source and a drain of the transistor M15 is electrically connected to a cathode of the light-receiving device PD, and the other of the source and the drain thereof is electrically connected to one of a source and a drain of the transistor M16, a first electrode of the capacitor C21, and a gate of the transistor M17. A gate of the transistor M16 is electrically connected to the wiring RS, and the other of the source and the drain of the transistor M16 is electrically connected to a wiring V11. One of a source and a drain of the transistor M17 is electrically connected to a wiring V13, and the other of the source and the drain of the transistor M17 is electrically connected to one of a source and a drain of the transistor M18. A gate of the transistor M18 is electrically connected to the wiring SE, and the other of the source and the drain of the transistor M18 is electrically connected to the wiring WX. An anode of the light-receiving device PD is electrically connected to the wiring ACL. A second electrode of the capacitor C21 is electrically connected to a wiring V12.

The wiring ACL electrically connected to the anode of the light-receiving device PD in the pixel 82 can serve as the wiring ACL also in the pixel 81, and is supplied with the second potential. In the pixel 82, the wiring ACL has a function of supplying the second potential to the anode of the light-receiving device PD. A third potential is supplied to the wiring V11. The wiring V11 is electrically connected to the cathode of the light-receiving device PD and has a function of supplying the third potential to the cathode of the light-receiving device PD. The third potential is a potential higher than the second potential. Thus, a reverse bias voltage can be applied to the light-receiving device PD.

The transistor M15, the transistor M16, and the transistor M18 each function as a switch. The transistor M17 functions as an amplifier element (amplifier).

It is preferable to use Si transistors as all of the transistor M15 to the transistor M18. Alternatively, it is preferable to use OS transistors as the transistor M15 and the transistor M16 and to use a Si transistor as the transistor M17. In this case, the transistor M18 may be either an OS transistor or a Si transistor.

By using OS transistors as the transistor M15 and the transistor M16, a potential retained in the gate of the transistor M17 on the basis of charge generated in the light-receiving device PD can be prevented from leaking through the transistor M15 or the transistor M16.

For example, in the case where image capturing is performed using a global shutter system, a period from the end of charge transfer operation to the start of reading operation (charge retention period) varies among pixels. When an image having the same gray level in all the pixels is captured, output signals in all the pixels ideally have potentials of the same level. However, in the case where the length of the charge retention period varies row by row, if charge accumulated at nodes in the pixels in each row leaks out over time, the potential of an output signal in a pixel varies row by row, and image data varies in gray level row by row. Thus, when OS transistors are used as the transistor M15 and the transistor M16, such a potential change at the node of the pixel can be extremely small. That is, even when image capturing is performed using the global shutter system, it is possible to inhibit variation in gray level of image data due to a difference in the length of the charge retention period, and it is possible to enhance the quality of captured images.

In contrast, as the transistor M17, a Si transistor is preferably used. A Si transistor can have a higher field-effect mobility than an OS transistor, and has excellent drive capability and current capability. Thus, the transistor M17 can operate at higher speed than the transistor M15 and the transistor M16. The use of Si transistor as the transistor M17 enables a quick output operation to the transistor M18 in accordance with an extremely low potential based on the amount of light received by the light-receiving device PD.

In other words, in the subpixel 82, the transistor M15 and the transistor M16 each have a low leakage current and the transistor M17 has high drive capability, whereby, when the light-receiving device PD receives light, the charge transferred through the transistor M15 can be retained without leakage and high-speed reading can be performed.

A low off-state current, a high-speed operation, and the like, which are required for the transistor M15 to the transistor M17, are not necessarily required for the transistor M18, which functions as a switch for supplying the output from the transistor M17 to the wiring WX. Thus, a Si transistor or an OS transistor may be used as the transistor M18.

Although n-channel transistors are shown as the transistors in FIG. 5B and FIG. 5C, p-channel transistors can also be used.

The transistors included in the pixel 81 and the subpixel 82 are preferably formed to be arranged over the same substrate.

### <Driving Method Example>

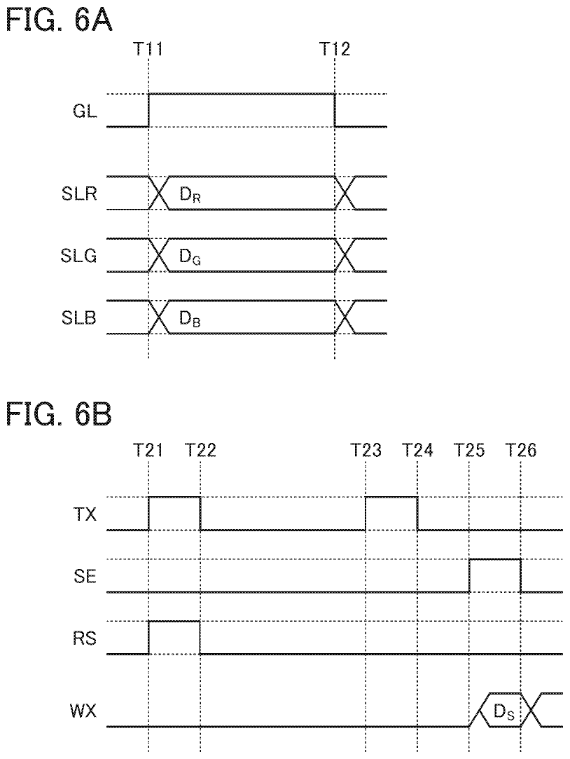

An example of a driving method of the case where the structure of the pixel 81 is employed for each of the subpixel 81R, the subpixel 81G, and the subpixel 81B illustrated in FIG. 5A is described with reference to a timing chart shown in FIG. 6A. FIG. 6A shows examples of signals input to the wiring GL, the wiring SLR, the wiring SLG, and the wiring SLB.

### <Before Time T11>

Before Time T11, the subpixel 81R, the subpixel 81G, and the subpixel 81B are in a non-selected state. Before Time T11, a potential for bringing the transistor M11 and the transistor M13 into a non-conducting state (here, a low-level potential) is supplied to the wiring GL.

### <Period T11-T12>

A period from Time T11 to Time T12 corresponds to a period in which data is written to a pixel. At Time T11, a potential for bringing the transistor M11 and the transistor M13 into a conducting state (here, a high-level potential) is supplied to the wiring GL, and a data potential DR, a data potential DG, and a data potential DB are supplied to the wiring SLR, the wiring SLG, and the wiring SLB, respectively. At this time, the transistor M11 is brought into a conducting state, and the data potential is supplied to the gate of the transistor M12 from the wiring SLR, the wiring SLG, or the wiring SLB. In addition, the transistor M13 is brought into a conducting state, and the reset potential is supplied from the wiring RL to the one electrode of the light-emitting device EL. Thus, light emission from the light-emitting device EL can be prevented during the writing period.

### <After Time T12>

A period after Time T12 corresponds to a period in which data is written to the next row. At Time T12, a potential for bringing the transistor M11 and the transistor M13 into a non-conducting state is supplied to the wiring GL, so that the transistor M11 and the transistor M13 are brought into a non-conducting state. Thus, a current corresponding to the gate potential of the transistor M12 flows through the light-emitting device EL, so that the light-emitting device EL emits light with desired luminance.

The above is the description of the example of the driving method of the pixel 81.

An example of a driving method of the pixel 82 illustrated in FIG. 5C is described with reference to a timing chart shown in FIG. 6B. FIG. 6B shows signals input to the wiring TX, the wiring SE, the wiring RS, and the wiring WX.

### <Before Time T21>

Before Time T21, a low-level potential is supplied to the wiring TX, the wiring SE, and the wiring RS. Data is not output to the wiring WX, and the wiring WX is regarded as being set to a low-level potential here. Note that a predetermined potential may be supplied to the wiring WX.

### <Period T21-T22>

At Time T21, a potential for bringing a transistor into a conducting state (here, a high-level potential) is supplied to the wiring TX and the wiring RS. In addition, a potential for bringing a transistor into a non-conducting state (here, a low-level potential) is supplied to the wiring SE.

At this time, the transistor M15 and the transistor M16 are brought into a conducting state, so that a potential lower than the potential of the cathode of the light-receiving device PD is supplied to the anode of the light-receiving device PD from the wiring V11 through the transistor M16 and the transistor M15. That is, a reverse bias voltage is applied to the light-receiving device PD.

The potential of the wiring V11 is also supplied to the first electrode of the capacitor C21, so that charge is stored in the capacitor C21.

Period T21-T22 can also be referred to as a reset (initialization) period.

### <Period T22-T23>

At Time T22, a low-level potential is supplied to the wiring TX and the wiring RS. Accordingly, the transistor M15 and the transistor M16 are each brought into a non-conducting state.

Since the transistor M15 is brought into a non-conducting state, the applied reverse bias voltage is retained in the light-receiving device PD. Here, photoelectric conversion is caused by light incident on the light-receiving device PD, and charge is accumulated in the light-receiving device PD.

Period T22-T23 can also be referred to as a light exposure period. The light exposure period is set in accordance with the sensitivity of the light-receiving device PD, the amount of incident light, or the like and is preferably set to be much longer than at least the reset period.

Since the transistor M15 and the transistor M16 are brought into a non-conducting state in Period T22-T23, the potential of the first electrode of the capacitor C21 is retained at a low-level potential supplied from the wiring V11.

### <Period T23-T24>

At Time T23, a high-level potential is supplied to the wiring TX. Accordingly, the transistor M15 is brought into a conducting state, and the charge accumulated in the light-receiving device PD is transferred to the first electrode of the capacitor C21 through the transistor M15. Accordingly, the potential of a node to which the first electrode of the capacitor C21 is connected increases in accordance with the amount of the charge accumulated in the light-receiving device PD. Consequently, a potential corresponding to the amount of light to which the light-receiving device PD is exposed is supplied to the gate of the transistor M17.

### <Period T24-T25>

At Time T24, a low-level potential is supplied to the wiring TX. Thus, the transistor M15 is brought into an off state, and the node to which the gate of the transistor M17 is connected is brought into a floating state. Since the light-receiving device PD is continuously exposed to light, a change in the potential of the node to which the gate of the transistor M17 is connected can be prevented by bringing the transistor M15 into a non-conducting state after the transfer operation in Period T23-T24 is completed.

### <Period T25-T26>

At Time T25, a high-level potential is supplied to the wiring SE. Accordingly, the transistor M18 is brought into a conducting state. Period T25-T26 can also be referred to as a reading period.

For example, data can be read when a source follower circuit is formed using the transistor M17 and a transistor included in the circuit portion 75. In this case, a data potential DS output to the wiring WX is determined in accordance with a gate potential of the transistor M17. Specifically, a potential obtained by subtracting the threshold voltage of the transistor M17 from the gate potential of the transistor M17 is output to the wiring WX as the data potential DS, and the potential is read by the reading circuit included in the circuit portion 75.

Note that a source ground circuit can also be formed using the transistor M17 and the transistor included in the circuit portion 75, in which case data can be read by the reading circuit included in the circuit portion 75.

### <After Time T26>

At Time T26, a low-level potential is supplied to the wiring SE. Accordingly, the transistor M18 is brought into a non-conducting state. Thus, data reading in the pixel 82 is completed. After Time T26, data reading operation is sequentially performed in the subsequent rows.

When the driving method shown as an example in FIG. 6B is used, the light exposure period and the reading period can be set independently; therefore, light exposure can be concurrently performed on all the pixels 82 in the display portion 71, and then data can be sequentially read. Accordingly, what is called global shutter driving can be achieved. In the case of performing global shutter driving, a transistor including an oxide semiconductor, which has an extremely low leakage current in an off-state, is preferably used as a transistor functioning as a switch in the pixel 82 (in particular, each of the transistor M15 and the transistor M16).

The above is the description of the example of a driving method of the pixel 82.

### <Variation Example of Pixel Circuit>

Structure examples of the pixel 81 and the pixel 82, which are different from the above, are described below.

Transistors each including a pair of gates overlapping with each other with a semiconductor layer therebetween can be used as the transistors included in the pixel 81 and the pixel 82. Specific examples of an LTPS transistor and an OS transistor each including a pair of gates are described in detail below.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

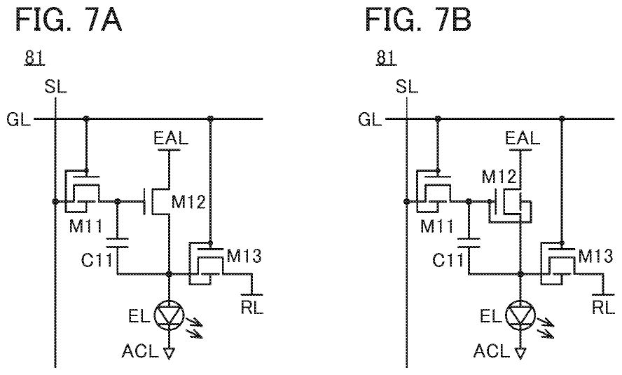

The pixel 81 illustrated in FIG. 7A is an example where a transistor including a pair of gates is used as each of the transistor M11 and the transistor M13. In each of the transistor M11 and the transistor M13, the pair of gates are electrically connected each other. Such a structure can shorten the period in which data is written to the pixel 81.

The pixel 81 illustrated in FIG. 7B is an example where a transistor including a pair of gates is used as the transistor M12 in addition to the transistor M11 and the transistor M13. A pair of gates of the transistor M12 are electrically connected to each other. When such a transistor is used as the transistor M12, the saturation characteristics are improved, whereby emission luminance of the light-emitting device EL can be controlled easily and the display quality can be increased.

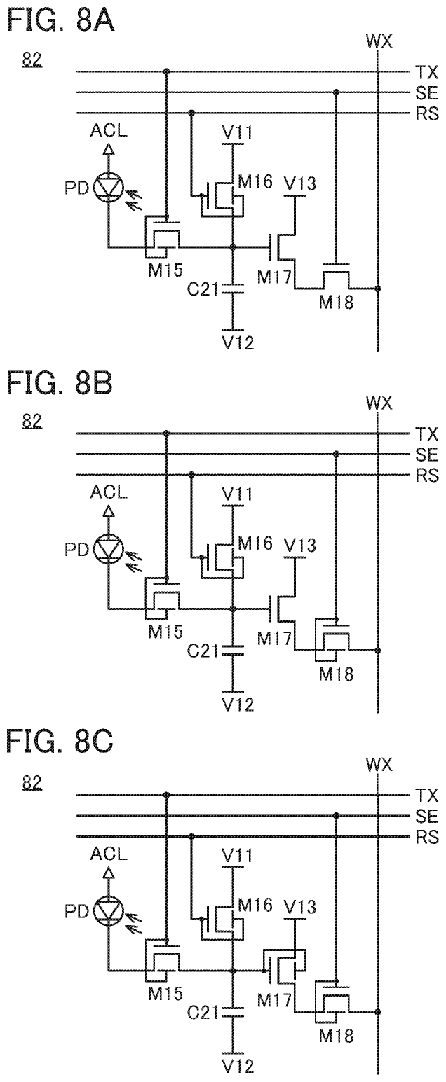

The pixel 82 illustrated in FIG. 8A is an example where a transistor including a pair of gates connected to each other is used as each of the transistor M15 and the transistor M16. Such a structure can shorten the time required for the reset operation and the transfer operation.

The pixel 82 illustrated in FIG. 8B is an example where a transistor including a pair of gates connected to each other is used as the transistor M18 in the structure illustrated in FIG. 8A. Such a structure can shorten the time required for reading.

The pixel 82 illustrated in FIG. 8C is an example where a transistor including a pair of gates connected to each other is used as the transistor M17 in the structure illustrated in FIG. 8B. Such a structure can further shorten the time required for reading.

### <Structure Example 3>

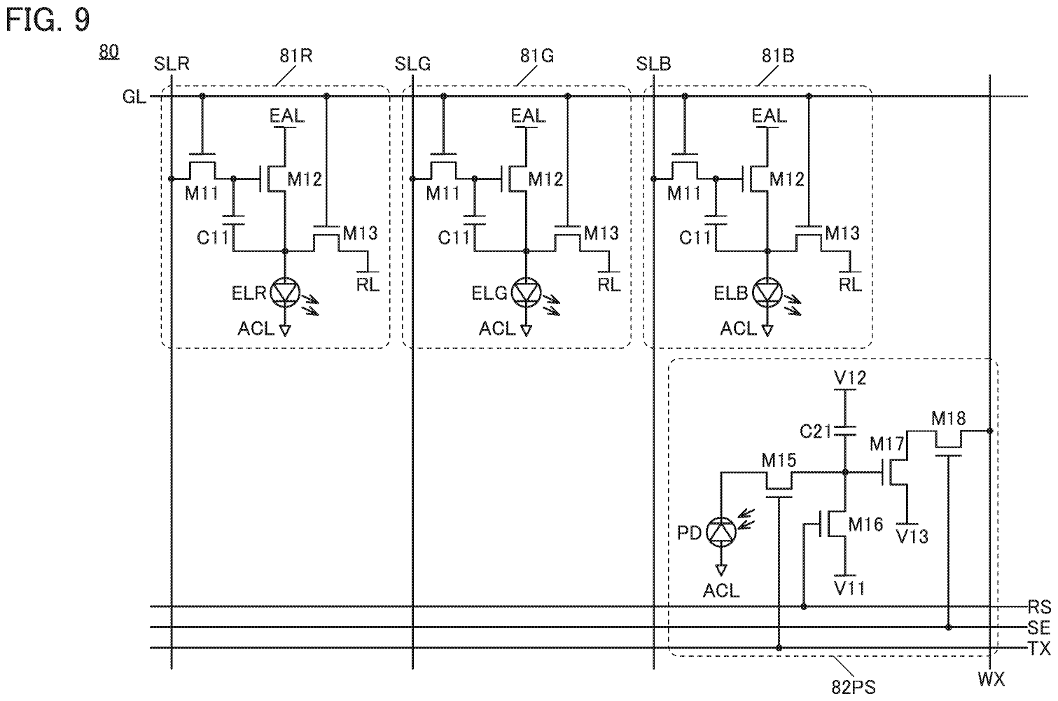

FIG. 9 illustrates an example of a circuit diagram of the pixel 80 including the subpixel 81R, the subpixel 81G, the subpixel 81B, and the subpixel 82PS.

The subpixel 81R includes a light-emitting device ELR that emits red light. The subpixel 81G includes a light-emitting device ELG that emits green light. The subpixel 81B includes a light-emitting device ELB that emits blue light. The subpixel 81R, the subpixel 81G, and the subpixel 81B have similar structures except for the light-emitting devices.

FIG. 9 illustrates a structure where the anode of the light-receiving device PD, a cathode of the light-emitting device ELR, a cathode of the light-emitting device ELG, and a cathode of the light-emitting device ELB are each electrically connected to the wiring ACL. Such a structure can reduce the number of wirings included in the pixel 80 and accordingly can reduce the size of the pixel 80, so that the display apparatus can have a high resolution. Note that a structure may be employed where the anode of the light-receiving device PD, the cathode of the light-emitting device ELR, the cathode of the light-emitting device ELG, and the cathode of the light-emitting device ELB are connected to different wirings.

Note that the structures of the subpixel 81R, the subpixel 81G, the subpixel 81B, and the subpixel 82PS are not limited to the structures illustrated in FIG. 9.

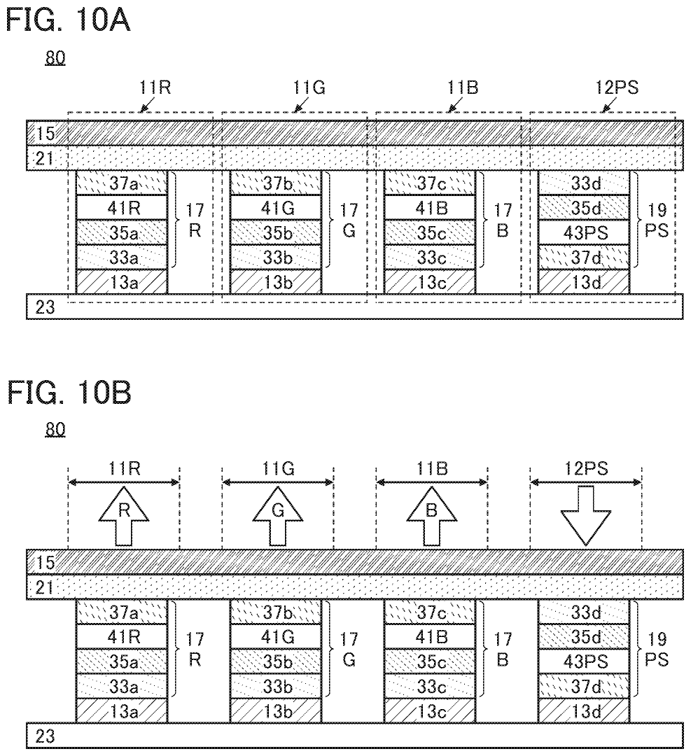

FIG. 10A illustrates structure examples of the light-emitting device and the light-receiving device included in the pixel 80. FIG. 10A is a schematic cross-sectional view illustrating the structures of a light-emitting device 11R, a light-emitting device 11G, a light-emitting device 11B, and a light-receiving device 12PS.

Note that FIG. 10A illustrates an example where the structure of the light-emitting device 11e illustrated in FIG. 3B is employed for the light-emitting device 11R, the light-emitting device 11G, and the light-emitting device 11B and the structure of the light-receiving device 12e illustrated in FIG. 3B is employed for the light-receiving device 12PS.

The light-emitting device 11R can be used as the light-emitting device ELR included in the subpixel 81R and has a function of emitting red light. The light-emitting device 11R has a stacked-layer structure where an electrode 13a, an EL layer 17R, the layer 21, and the electrode are stacked in this order over the substrate 23. The EL layer 17R has a stacked-layer structure where a layer 33a, a layer 35a, a light-emitting layer 41R, and a layer 37a are stacked in this order.

The layer 33a includes a layer containing a substance with a high hole-injection property (a hole-injection layer). The layer 35a includes a layer containing a substance with a high hole-transport property (a hole-transport layer). The light-emitting layer 41R contains a light-emitting substance that emits red light. The layer 37a includes a layer containing a substance with a high electron-transport property (an electron-transport layer). The layer 21 includes a layer containing a substance with a high electron-injection property (an electron-injection layer).

In the light-emitting device 11R, the electrode 13a functions as an anode and the electrode 15 functions as a cathode. That is, a potential supplied to the electrode 13a is higher than a potential supplied to the electrode 15.

The light-emitting device 11G can be used as the light-emitting device ELG included in the subpixel 81G and has a function of emitting green light. The light-emitting device 11G has a stacked-layer structure where an electrode 13b, an EL layer 17G, the layer 21, and the electrode 15 are stacked in this order over the substrate 23. The EL layer 17G has a stacked-layer structure where a layer 33b, a layer 35b, a light-emitting layer 41G, and a layer 37b are stacked in this order.

The layer 33b includes a layer containing a substance with a high hole-injection property (a hole-injection layer). The layer 35b includes a layer containing a substance with a high hole-transport property (a hole-transport layer). The light-emitting layer 41G contains a light-emitting substance that emits green light. The layer 37b includes a layer containing a substance with a high electron-transport property (an electron-transport layer).

In the light-emitting device 11G, the electrode 13b functions as an anode and the electrode 15 functions as a cathode. That is, a potential supplied to the electrode 13b is higher than a potential supplied to the electrode 15.

The light-emitting device 11B can be used as the light-emitting device ELB included in the subpixel 81B and has a function of emitting blue light. The light-emitting device 11B has a stacked-layer structure where an electrode 13c, an EL layer 17B, the layer 21, and the electrode are stacked in this order over the substrate 23. The EL layer 17B has a stacked-layer structure where a layer 33c, a layer 35c, a light-emitting layer 41B, and a layer 37c are stacked in this order.

The layer 33c includes a layer containing a substance with a high hole-injection property (a hole-injection layer). The layer 35c includes a layer containing a substance with a high hole-transport property (a hole-transport layer). The light-emitting layer 41B contains a light-emitting substance that emits blue light. The layer 37c includes a layer containing a substance with a high electron-transport property (an electron-transport layer).

In the light-emitting device 11B, the electrode 13c functions as an anode and the electrode 15 functions as a cathode. That is, a potential supplied to the electrode 13c is higher than a potential supplied to the electrode 15.

The light-receiving device 12PS can be used as the light-receiving device PD included in the subpixel 82PS, and has a function of detecting visible light and infrared light. The light-receiving device 12PS has a stacked-layer structure where an electrode 13d, a light-receiving layer 19PS, the layer 21, and the electrode 15 are stacked in this order over the substrate 23. The light-receiving layer 19PS has a stacked-layer structure where a layer 37d, the active layer 43, a layer 35d, and a layer 33d are stacked in this order.

The layer 37d includes a layer containing a substance with a high electron-transport property (an electron-transport layer). An active layer 43PS includes a semiconductor. In particular, the active layer 43PS preferably includes an organic semiconductor. The layer 35d includes a layer containing a substance with a high hole-transport property (a hole-transport layer). The layer 33d includes a layer containing a substance with a high hole-injection property (a hole-injection layer). Note that in the light-receiving device 12PS, the layer 33d functions as a hole-transport layer.

In the light-receiving device 12PS, the electrode 13d functions as a cathode and the electrode 15 functions as an anode. That is, a potential supplied to the electrode 13d is higher than a potential supplied to the electrode 15. In the light-receiving device 12PS, a reverse bias is applied between the electrode 13d and the electrode 15.

The electrode 13a, the electrode 13b, the electrode 13c, and the electrode 13d are provided over the substrate 23. The electrode 13a, the electrode 13b, the electrode 13c, and the electrode 13d can be formed by processing a conductive film formed over the substrate 23 into island-like shapes, for example. The electrode 13a, the electrode 13b, the electrode 13c, and the electrode 13d each function as a pixel electrode. Since the above description of the electrode 13A and the electrode 13B can be referred to for the electrode 13a, the electrode 13b, the electrode 13c, and the electrode 13d, the detailed description thereof is omitted. The electrode 15 functions as a common electrode. Since the above description can be referred to for the electrode 15, the detailed description thereof is omitted.

Since the above description of the layer 33A and the layer 33B can be referred to for the layer 33a, the layer 33b, the layer 33c, and the layer 33d, the detailed description thereof is omitted. Since the above description of the layer 35A and the layer 35B can be referred to for the layer 35a, the layer 35b, the layer 35c, and the layer 35d, the detailed description thereof is omitted. Since the above description of the layer 37A and the layer 37B can be referred to for the layer 37a, the layer 37b, the layer 37c, and the layer 37d, the detailed description thereof is omitted. Since the above description can be referred to for the layer 21 that is a common layer, the detailed description thereof is omitted.

In FIG. 10B, red (R) light emitted from the light-emitting device 11R, green (G) light emitted from the light-emitting device 11G, blue (B) light emitted from the light-emitting device 11B, and light incident on the light-receiving device 12PS are schematically indicated by arrows.

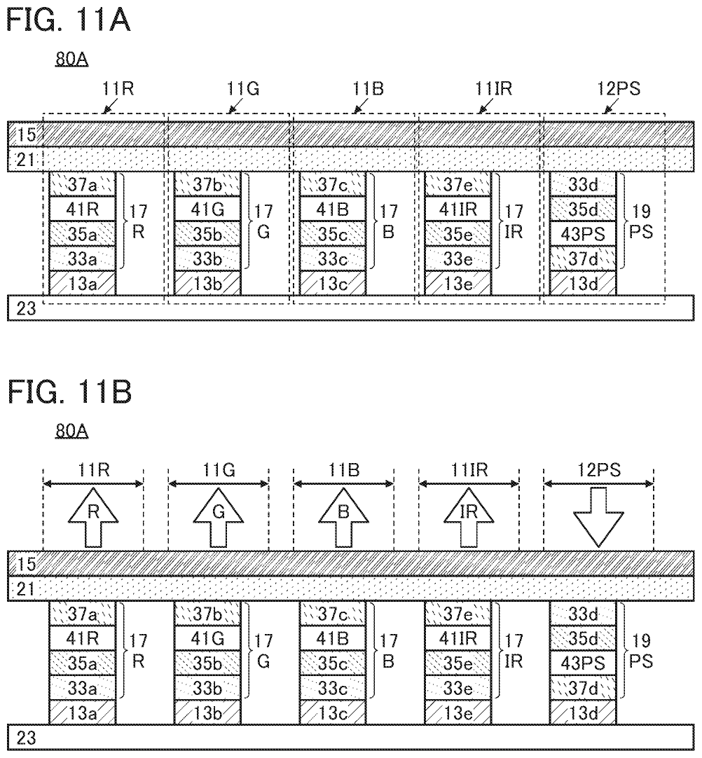

FIG. 11A illustrates a structure example different from that of the above-described pixel 80. A pixel 80A illustrated in FIG. 11A includes the light-emitting device 11R, the light-emitting device 11G, the light-emitting device 11B, a light-emitting device 11IR, and the light-receiving device 12PS. FIG. 11A is a schematic cross-sectional view illustrating the structures of the light-emitting device 11R, the light-emitting device 11G, the light-emitting device 11B, the light-emitting device 11IR, and the light-receiving device 12PS. The pixel 80A is different from the pixel 80 illustrated in FIG. 10A and the like mainly in including the light-emitting device 1118.

The light-emitting device 11IR has a function of emitting infrared light. The light-emitting device 11IR has a stacked-layer structure where an electrode 13e, an EL layer 171R, the layer 21, and the electrode 15 are stacked in this order over the substrate 23. The EL layer 171R has a stacked-layer structure where a layer 33e, a layer 35e, a light-emitting layer 411R, and a layer 37e are stacked in this order.

The layer 33e includes a layer containing a substance with a high hole-injection property (a hole-injection layer). The layer 35e includes a layer containing a substance with a high hole-transport property (a hole-transport layer). The light-emitting layer 411R contains a light-emitting substance that emits light in an infrared wavelength range. The layer 37e includes a layer containing a substance with a high electron-transport property (an electron-transport layer).

In the light-emitting device 11IR, the electrode 13e functions as an anode and the electrode 15 functions as a cathode. That is, a potential supplied to the electrode 13e is higher than a potential supplied to the electrode 15.

The electrode 13e is provided over the substrate 23. The electrode 13e can be formed in the same step as the electrode 13a, the electrode 13b, the electrode 13c, and the electrode 13d. The electrode 13e functions as a pixel electrode. Since the above description of the electrode 13A and the electrode 13B can be referred to for the electrode 13e, the detailed description thereof is omitted.

Since the above description of the layer 33A and the layer 33B can be referred to for the layer 33e, the detailed description thereof is omitted. Since the above description of the layer 35A and the layer 35B can be referred to for the layer 35e, the detailed description thereof is omitted. Since the above description of the layer 37A and the layer 37B can be referred to for the layer 37e, the detailed description thereof is omitted.

In FIG. 11B, red (R) light emitted from the light-emitting device 11R, green (G) light emitted from the light-emitting device 11G, blue (B) light emitted from the light-emitting device 11B, infrared (IR) light emitted from the light-emitting device 11IR, and light incident on the light-receiving device 12PS are schematically indicated by arrows.

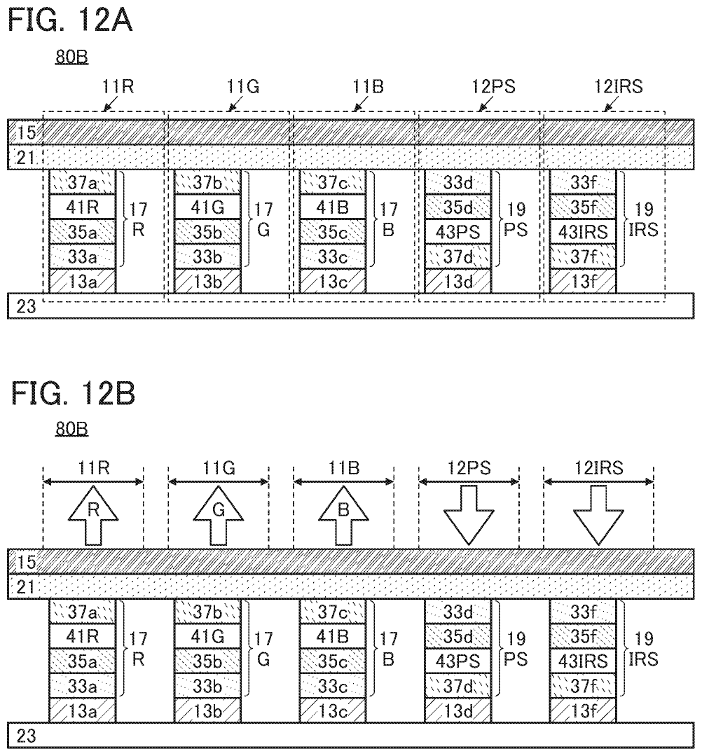

FIG. 12A illustrates a structure example different from that of the above-described pixel 80. A pixel 80B illustrated in FIG. 12A includes the light-emitting device 11R, the light-emitting device 11G, the light-emitting device 11B, the light-receiving device 12PS, and a light-receiving device 12IRS. FIG. 12A is a schematic cross-sectional view illustrating the structures of the light-emitting device 11R, the light-emitting device 11G, the light-emitting device 11B, the light-receiving device 12PS, and the light-receiving device 12IRS. The pixel 80B is different from the pixel 80 illustrated in FIG. 10A and the like mainly in the structure of the light-receiving device.

The light-receiving device 12PS included in the pixel 80 has a function of receiving visible light, and the light-receiving device 12IRS has a function of receiving infrared light.

The light-receiving device 12IRS has a stacked-layer structure where an electrode 13f, a light-receiving layer 19IRS, the layer 21, and the electrode 15 are stacked in this order over the substrate 23. The light-receiving layer 19IRS has a stacked-layer structure where a layer 37f, an active layer 43IRS, a layer 35f, and a layer 33f are stacked in this order.

The layer 37f includes a layer containing a substance with a high electron-transport property (an electron-transport layer). The active layer 43IRS includes a semiconductor. In particular, the active layer 43IRS preferably includes an organic semiconductor. The layer 35f includes a layer containing a substance with a high hole-transport property (a hole-transport layer). The layer 33f includes a layer containing a substance with a high hole-injection property (a hole-injection layer). Note that in the light-receiving device 12IRS, the layer 33f functions as a hole-transport layer.

In the light-receiving device 12IRS, the electrode 13f functions as a cathode and the electrode 15 functions as an anode. That is, a potential supplied to the electrode 13f is higher than a potential supplied to the electrode 15.

The electrode 13f is provided over the substrate 23. The electrode 13f can be formed in the same step as the electrode 13a, the electrode 13b, the electrode 13c, the electrode 13d, and the electrode 13e. The electrode 13e functions as a pixel electrode. Since the above description of the electrode 13A and the electrode 13B can be referred to for the electrode 13f, the detailed description thereof is omitted.

Since the above description of the layer 33A and the layer 33B can be referred to for the layer 33f, the detailed description thereof is omitted. Since the above description of the layer 35A and the layer 35B can be referred to for the layer 35f, the detailed description thereof is omitted. Since the above description of the layer 37A and the layer 37B can be referred to for the layer 37f, the detailed description thereof is omitted.

In FIG. 12B, red (R) light emitted from the light-emitting device 11R, green (G) light emitted from the light-emitting device 11G, blue (B) light emitted from the light-emitting device 11B, light incident on the light-receiving device 12PS, and light incident on the light-receiving device 12IRS are schematically indicated by arrows.

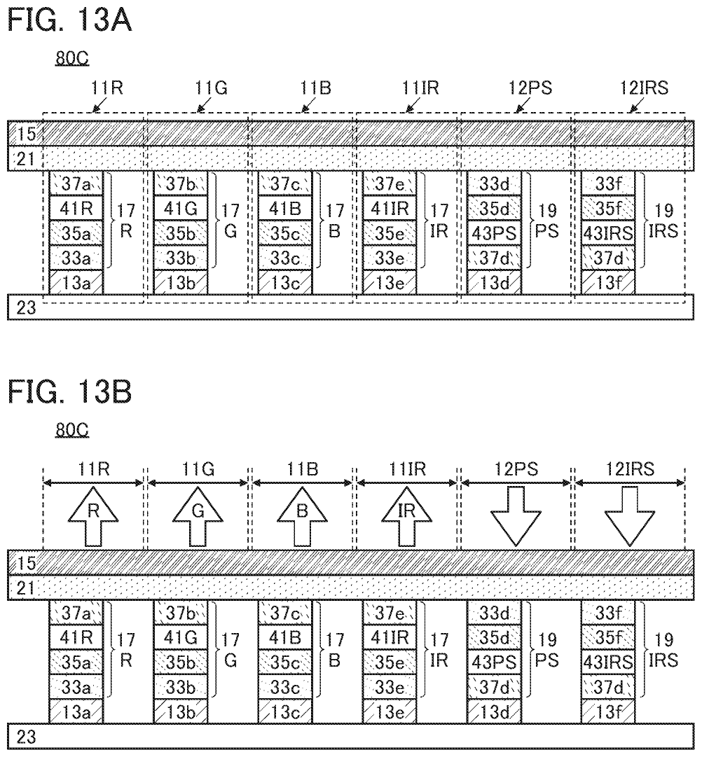

FIG. 13A illustrates a structure example different from that of the above-described pixel 80B. The pixel 80B illustrated in FIG. 13A includes the light-emitting device 11R, the light-emitting device 11G, the light-emitting device 11B, the light-emitting device 11IR, the light-receiving device 12PS, and the light-receiving device 12IRS. FIG. 13A is a schematic cross-sectional view illustrating the structures of the light-emitting device 11R, the light-emitting device 11G, the light-emitting device 11B, the light-emitting device 11IR, the light-receiving device 12PS, and the light-receiving device 12IRS. A pixel 80C is different from the pixel 80B illustrated in FIG. 12A and the like mainly in including the light-emitting device 11IR.

In FIG. 13B, red (R) light emitted from the light-emitting device 11R, green (G) light emitted from the light-emitting device 11G, blue (B) light emitted from the light-emitting device 11B, infrared (IR) light emitted from the light-emitting device 11IR, light incident on the light-receiving device 12PS, and light incident on the light-receiving device 12IRS are schematically indicated by arrows.

### <Structure Example 4>

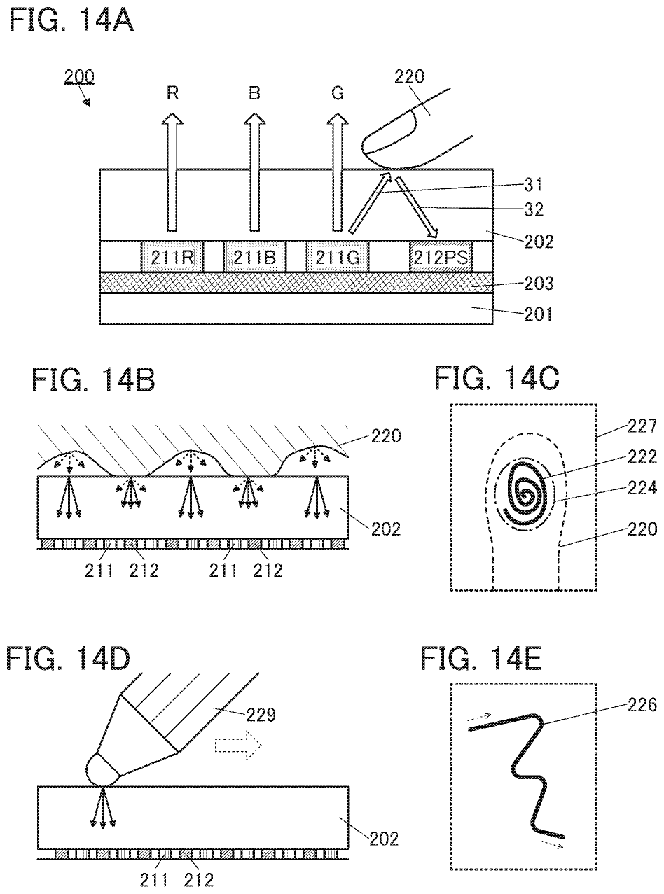

FIG. 14A shows a schematic view illustrating a display apparatus of one embodiment of the present invention. A display apparatus 200 illustrated in FIG. 14A includes a substrate 201, a substrate 202, a light-emitting device 211R, a light-emitting device 211G, a light-emitting device 211B, a light-receiving device 212PS, a functional layer 203, and the like.

The light-emitting device 211R, the light-emitting device 211G, the light-emitting device 211B, and the light-receiving device 212PS are provided between the substrate 201 and the substrate 202. The light-emitting device 211R, the light-emitting device 211G, and the light-emitting device 211B emit red (R) light, green (G) light, and blue (B) light, respectively. Any of the above-described light-emitting devices can be used as the light-emitting device 211R, the light-emitting device 211G, and the light-emitting device 211B. Any of the light-receiving devices can be used as the light-receiving device 212PS. Note that in the following description, the term “light-emitting device 211” is sometimes used when the light-emitting device 211R, the light-emitting device 211G, and the light-emitting device 211B are not particularly distinguished from each other.

FIG. 14A illustrates a state where a finger 220 is in contact with a surface of the substrate 202. Part of light emitted by the light-emitting device (e.g., the light-emitting device 211G) is reflected at a contact portion of the substrate 202 and the finger 220. In the case where part of the reflected light is incident on the light-receiving device 212PS, the contact of the finger 220 with the substrate 202 can be detected. That is, the display apparatus 200 can function as a touch panel.

The functional layer 203 includes a circuit for driving the light-emitting device 211R, the light-emitting device 211G, and the light-emitting device 211B and a circuit for driving the light-receiving device 212PS. The functional layer 203 is provided with a switch, a transistor, a capacitor, a wiring, and the like. Note that in the case where the light-emitting device 211R, the light-emitting device 211G, the light-emitting device 211B, and the light-receiving device 212PS are driven by a passive matrix method, the switch and the transistor are not necessarily provided.

The display apparatus 200 can detect a fingerprint of the finger 220, for example. FIG. 14B schematically shows an enlarged view of the contact portion of the substrate 202 and the finger 220. FIG. 14B illustrates the light-emitting devices 211 and the light-receiving devices 212 that are alternately arranged.

The fingerprint of the finger 220 is formed of depressions and projections. Accordingly, as illustrated in FIG. 14B, the projections of the fingerprint touch the substrate 202.

Reflection of light from a surface or an interface is categorized into regular reflection and diffuse reflection. Regularly reflected light is highly directional light with an angle of reflection equal to the angle of incidence. Diffusely reflected light has low directionality and low angular dependence of intensity. As for regular reflection and diffuse reflection, diffuse reflection components are dominant in the light reflected from the surface of the finger 220. Meanwhile, regular reflection components are dominant in the light reflected from the interface between the substrate 202 and the air.

The intensity of light that is reflected from contact surfaces or non-contact surfaces between the finger 220 and the substrate 202 and is incident on the light-receiving devices 212 positioned directly below the contact surfaces or the non-contact surfaces is the sum of intensities of regularly reflected light and diffusely reflected light. As described above, regularly reflected light (indicated by solid arrows) is dominant near the depressions of the finger 220, where the finger 220 is not in contact with the substrate 202; whereas diffusely reflected light (indicated by dashed arrows) from the finger 220 is dominant near the projections of the finger 220, where the finger 220 is in contact with the substrate 202. Thus, the intensity of light received by the light-receiving device 212 positioned directly below the depression is higher than the intensity of light received by the light-receiving device 212 positioned directly below the projection. Accordingly, a fingerprint image of the finger 220 can be captured.

In the case where an arrangement interval between the light-receiving devices 212 is smaller than a distance between two projections of a fingerprint, preferably a distance between a depression and a projection adjacent to each other, a clear fingerprint image can be obtained. The distance between a depression and a projection of a human's fingerprint is approximately 200 μm; thus, the arrangement interval between the light-receiving devices 212 is, for example, less than or equal to 400 μm, preferably less than or equal to 200 μm, further preferably less than or equal to 150 μm, still further preferably less than or equal to 100 μm, yet still further preferably less than or equal to 50 μm and greater than or equal to 1 μm, preferably greater than or equal to 10 μm, further preferably greater than or equal to 20 μm.

FIG. 14C illustrates an example of a fingerprint image captured by the display apparatus 200. In FIG. 14C, in an imaging range 227, the outline of the finger 220 is indicated by a dashed line and the outline of a contact portion 224 is indicated by a dashed-dotted line. In the contact portion 224, a high-contrast image of a fingerprint 222 can be captured owing to a difference in the amount of light incident on the light-receiving devices 212.

The display apparatus 200 can also function as a touch panel or a pen tablet. FIG. 14D illustrates a state where a tip of a stylus 229 slides in a direction indicated by a dashed arrow while the tip of the stylus 229 is in contact with the substrate 202.

As illustrated in FIG. 14D, when diffusely reflected light that is diffused at the contact surface of the tip of the stylus 229 and the substrate 202 is incident on the light-receiving device 212 positioned in a portion overlapping with the contact surface, the position of the tip of the stylus 229 can be detected with high accuracy.

FIG. 14E illustrates an example of a path 226 of the stylus 229 that is detected by the display apparatus 200. The display apparatus 200 can detect the position of an object to be detected, such as the stylus 229, with high position accuracy, so that high-resolution drawing can be performed using a drawing application or the like. Unlike the case of using a capacitive touch sensor, an electromagnetic induction touch pen, or the like, the display apparatus 200 can detect even the position of a highly insulating object to be detected, the material of a tip portion of the stylus 229 is not limited, and a variety of writing materials (e.g., a brush, a glass pen, and a quill pen) can be used.

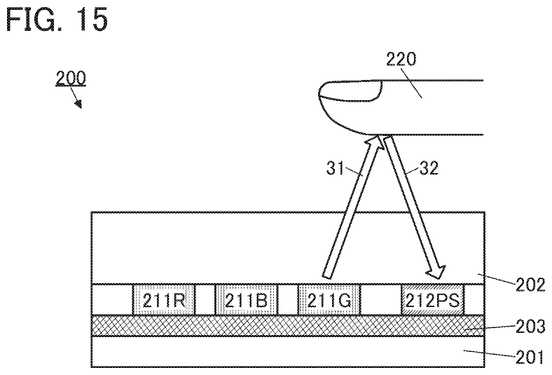

The light-receiving device 212PS can be used in a touch sensor (also referred to as a direct touch sensor), a near touch sensor (also referred to as a hover sensor, a hover touch sensor, a contactless sensor, or a touchless sensor), or the like. FIG. 15 illustrates a state where light 31 emitted from the light-emitting device (e.g., the light-emitting device 211G) is reflected by an object (e.g., the finger 220), and light 32 that is reflected light is incident on the light-receiving device 212PS. The object is not in contact with the display apparatus 200; however, the object can be detected with the use of the light-receiving device 212PS. Note that the wavelength of light detected by the light-receiving device 212PS may be determined as appropriate depending on the intended use.

The touch sensor or the near touch sensor can detect an approach or contact of an object (e.g., a finger, a hand, or a pen). The touch sensor can detect the object when the display apparatus and the object come in direct contact with each other. Furthermore, even when an object is not in contact with the display apparatus, the near touch sensor can detect the object. For example, the display apparatus is preferably capable of detecting an object positioned in the range of 0.1 mm to 300 mm inclusive, further preferably 3 mm to 50 mm inclusive from the display apparatus. This structure enables the display apparatus to be operated without direct contact of an object; in other words, the display apparatus can be operated in a contactless (touchless) manner. With the above structure, the display apparatus can have a reduced risk of being dirty or damaged, or can be operated without the object directly touching a dirt (e.g., dust or a virus) attached to the display apparatus.

The refresh rate of the display apparatus of one embodiment of the present invention can be variable. For example, the refresh rate is adjusted (adjusted in the range from 1 Hz to 240 Hz inclusive, for example) in accordance with contents displayed on the display apparatus, whereby power consumption can be reduced. The driving frequency of the touch sensor or the near touch sensor may be changed in accordance with the refresh rate. In the case where the refresh rate of the display apparatus is 120 Hz, for example, the driving frequency of the touch sensor or the near touch sensor can be higher than 120 Hz (typically 240 Hz). With this structure, low power consumption can be achieved, and the response speed of the touch sensor or the near touch sensor can be increased.

The light-receiving device 212PS is preferably provided in all of the pixels included in the display apparatus. Providing the light-receiving device 212PS in all of the pixels enables highly accurate touch detection. Note that the light-receiving device 212PS may be provided in some of the pixels. For example, the display apparatus may include a pixel provided with the light-emitting device and the light-receiving device and a pixel provided with the light-receiving device (not provided with only the light-emitting device).

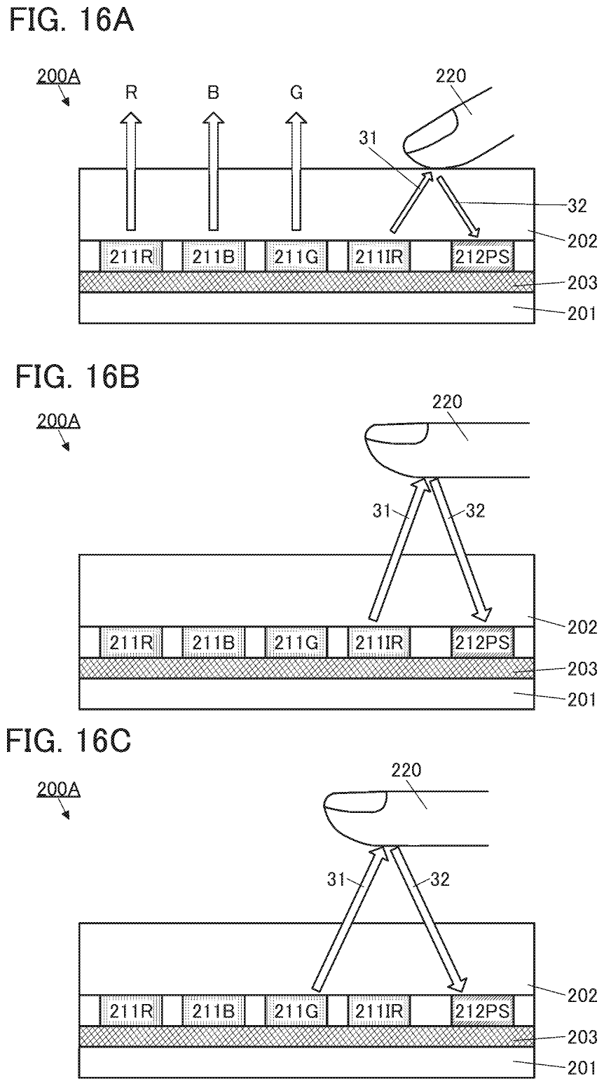

FIG. 16A illustrates a structure example different from that of the above-described display apparatus 200. A display apparatus 200A illustrated in FIG. 16A includes the substrate 201, the substrate 202, the light-emitting device 211R, the light-emitting device 211G, the light-emitting device 211B, a light-emitting device 211IR, the light-receiving device 212PS, the functional layer 203, and the like. The display apparatus 200A is different from the display apparatus 200 mainly in including the light-emitting device 211IR.

The light-emitting device 211R, the light-emitting device 211G, the light-emitting device 211B, and the light-receiving element 212PS are provided between the substrate 201 and the substrate 202. The light-emitting device 211IR emits infrared light. Any of the above-described light-emitting devices can be used as the light-emitting device 21118.

FIG. 16A illustrates a state where the finger 220 touches a surface of the substrate 202. Part of light emitted from the light-emitting device (e.g., the light-emitting device 211IR) is reflected at a contact portion of the substrate 202 and the finger 220. In the case where part of the reflected light is incident on the light-receiving device 212PS, the contact of the finger 220 with the substrate 202 can be detected. For example, infrared rays are emitted from the light-emitting device 211IR and infrared light is detected by the light-receiving device 212PS, so that a touch can be detected even in a dark place.

The display apparatus 200A can perform touch detection in a display portion with the use of the light-emitting device 2111R and the light-receiving device 212PS while displaying an image on the display portion with the use of the light-emitting device 211R, the light-emitting device 211G, and the light-emitting device 211B. In addition, the display apparatus 200A can perform image capturing in the display portion while displaying an image on the display portion.

FIG. 16B illustrates a state where the light 31 emitted from the light-emitting device 211G is reflected by an object (e.g., the finger 220), and the light 32 that is reflected light is incident on the light-receiving device 212PS. FIG. 16C illustrates a state where the light 31 emitted from the light-emitting device 211IR is reflected by an object (e.g., the finger 220), and the light 32 that is reflected light is incident on the light-receiving device 212PS. The object is not in contact with the display apparatus 200A; however, the object can be detected with the use of the light-receiving device 212PS.

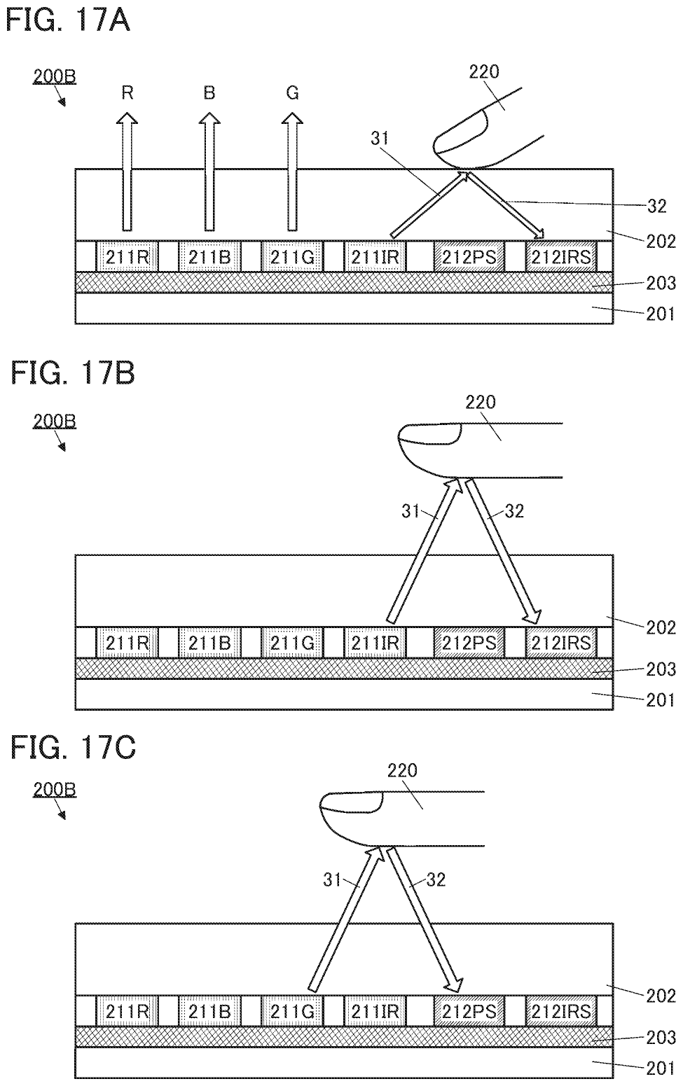

FIG. 17A illustrates a structure example different from that of the above-described display apparatus 200A. A display apparatus 200B illustrated in FIG. 17A includes the substrate 201, the substrate 202, the light-emitting device 211R, the light-emitting device 211G, the light-emitting device 211B, the light-emitting device 21118, the light-receiving device 212PS, a light-receiving device 212IRS, the functional layer 203, and the like. The display apparatus 200B is different from the above-described display apparatus 200A mainly in the structure of the light-receiving device.

The light-emitting device 211R, the light-emitting device 211G, the light-emitting device 211B, the light-receiving device 212PS, and the light-receiving device 212IRS are provided between the substrate 201 and the substrate 202. The light-receiving device 212PS receives visible light. The light-receiving device 212IRS receives infrared light. Any of the above-described light-receiving devices can be used as the light-receiving device 212PS and the light-receiving device 212IRS.

FIG. 17A illustrates a state where the finger 220 touches a surface of the substrate 202. Part of light emitted from the light-emitting device (e.g., the light-emitting device 211IR) is reflected at a contact portion of the substrate 202 and the finger 220. In the case where part of the reflected light is incident on the light-receiving device 212IRS, the contact of the finger 220 with the substrate 202 can be detected.

FIG. 17B illustrates a state where the light 31 emitted from the light-emitting device 211IR is reflected by an object (e.g., the finger 220), and the light 32 that is reflected light is incident on the light-receiving device 212IRS. FIG. 17C illustrates a state where the light 31 emitted from the light-emitting device 211G is reflected by an object (e.g., the finger 220), and the light 32 that is reflected light is incident on the light-receiving device 212PS. The object is not in contact with the display apparatus 200B; however, the object can be detected with the use of the light-receiving device 212PS or the light-receiving device 212IRS.

The area of a light-receiving region (hereinafter, also referred to as a light-receiving area) of the light-receiving device 212PS is preferably smaller than the light-receiving area of the light-receiving device 212IRS. When the light-receiving area of the light-receiving device 212PS is made small, that is, the image capturing range is made small, the light-receiving device 212PS can perform higher-resolution image capturing than the light-receiving device 212IRS. In this case, the light-receiving device 212PS can be used to capture an image for personal authentication using a fingerprint, a palm print, the iris, the shape of a blood vessel (including the shape of a vein and the shape of an artery), a face, or the like. Note that the wavelength of light detected by the light-receiving device 212PS may be determined as appropriate depending on the intended use.

Since the light-receiving device 212PS and the light-receiving device 212IRS have difference in the detection accuracy, methods for detecting an object may be selected depending on the functions. For example, a function of scrolling a display screen may be achieved by a near touch sensor function using the light-receiving device 212IRS, and an input function with a keyboard displayed on a screen may be achieved by a high-resolution touch sensor function using the light-receiving device 212PS.

When one pixel includes two kinds of light-receiving devices, the display apparatus can have two additional functions as well as a display function, enabling a multifunctional display apparatus.

For high-resolution image capturing, the light-receiving device 212PS is preferably provided in all of the pixels included in the display apparatus. Meanwhile, the light-receiving device 212IRS used for a touch sensor, a near touch sensor, or the like may be provided in some of the pixels included in the display apparatus because detection with the light-receiving device 212IRS is not required to have high accuracy as compared to detection with the light-receiving device 212PS. When the number of the light-receiving devices 212IRS included in the display apparatus is smaller than the number of the light-receiving devices 212PS, the detection speed can be increased.

As described above, the display apparatus of this embodiment can be a multifunctional display apparatus by including a light-emitting device and a light-receiving device in one pixel. For example, a display apparatus with a high-resolution image capturing function and a sensing function of a touch sensor, a near touch sensor, or the like can be achieved.

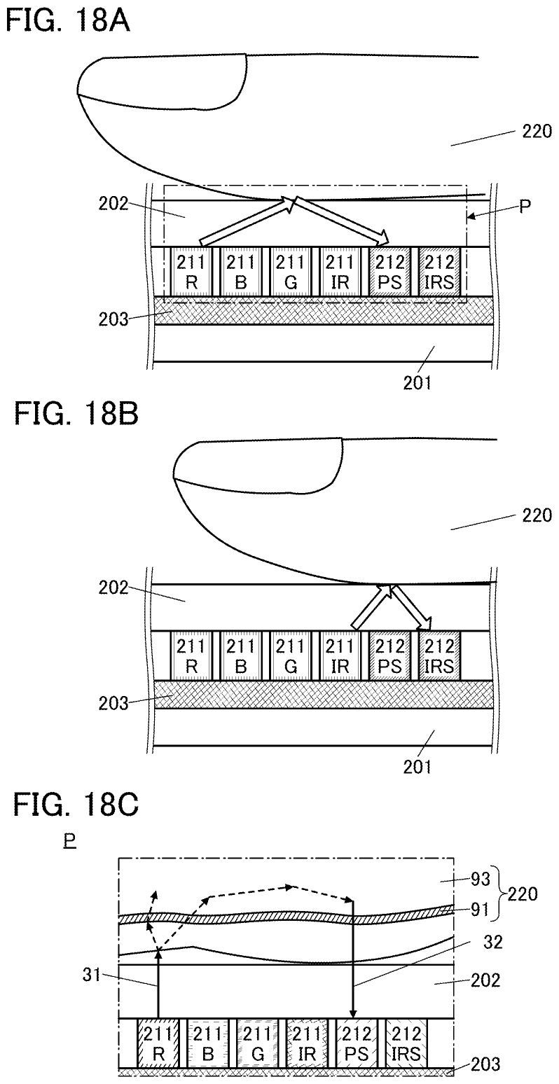

The display apparatus of one embodiment of the present invention may emit light of a particular color and receive reflected light that has been reflected by an object. In FIG. 18A, red light emitted from the display apparatus and the red light incident on the display apparatus after being reflected by an object (here, the finger 220) are schematically indicated by arrows. In FIG. 18B, infrared light emitted from the display apparatus and the infrared light incident on the display apparatus after being reflected by an object (here, the finger 220) are schematically indicated by arrows.

Red light is emitted with an object being in contact with or approaching the display apparatus, and light reflected by the object is incident on the display apparatus, so that the red light transmittance of the object can be measured. Similarly, infrared light is emitted with an object being in contact with or approaching the display apparatus, and light reflected by the object is incident on the display apparatus, so that the infrared light transmittance of the object can be measured.

FIG. 18C shows an enlarged view of a region P indicated by the dashed-dotted line in FIG. 18A. The light 31 emitted from the light-emitting device 211R is scattered by biological tissue on the surface or at the inside of the finger 220, and part of the scattered light advances from the inside of the living body toward the light-receiving device 212PS. The scattered light passes through a blood vessel 91, and the light 32 having passed through the blood vessel 91 is incident on the light-receiving device 212PS.

Similarly, infrared light emitted from the light-emitting device 211IR is scattered by biological tissue on the surface or at the inside of the finger 220, and part of the scattered infrared light advances from the inside of the living body toward the light-receiving device 212IRS. The scattered infrared light passes through the blood vessel 91, and the infrared light having passed through the blood vessel 91 is incident on the light-receiving device 212IRS.

Here, the light 32 is light having passed through biological tissue 93 and the blood vessel 91 (an artery and a vein). Since an arterial blood pulses by heartbeat, light absorption by the artery fluctuates in accordance with the heartbeat. In contrast, the biological tissue 93 and the vein are not influenced by the heartbeat, and thus light absorption by the biological tissue 93 and light absorption by the vein are constant. Therefore, light transmittance of the artery can be calculated by subtracting the components that are constant over time from the light 32 that is incident on the display apparatus. The red light transmittance of oxygen-unbound hemoglobin (also referred to as reduced hemoglobin) is lower than that of oxygen-bound hemoglobin (also referred to as oxyhemoglobin). Oxyhemoglobin and reduced hemoglobin have substantially the same infrared light transmittance. Measuring the red light transmittance of the artery and the infrared light transmittance of the artery enables the ratio of oxyhemoglobin to the total amount of oxyhemoglobin and reduced hemoglobin, that is, the oxygen saturation (hereinafter, also referred to as percutaneous oxygen saturation (SpO₂: Peripheral Oxygen Saturation)), to be calculated. In this way, the display apparatus of one embodiment of the present invention can have a function of a reflective pulse oximeter.

For example, when a finger is in contact with a display portion of a display apparatus, positional information of a region that the finger is in contact with is obtained. Then, red light is emitted from pixels in and around the region that the finger is in contact with to measure the red light transmittance of the artery. After that, infrared light is emitted to measure the infrared light transmittance of the artery, whereby the oxygen saturation can be calculated. Note that the order of measuring the red light transmittance and the infrared light transmittance is not particularly limited. After the infrared light transmittance is measured, the red light transmittance may be measured. Furthermore, although an example of calculating the oxygen saturation using the finger is described here, one embodiment of the present invention is not limited thereto. The oxygen saturation can be calculated using a part other than the finger. For example, the oxygen saturation can be calculated by measuring the red light transmittance of an artery and the infrared light transmittance of the artery while a palm is in contact with the display portion of the display apparatus.

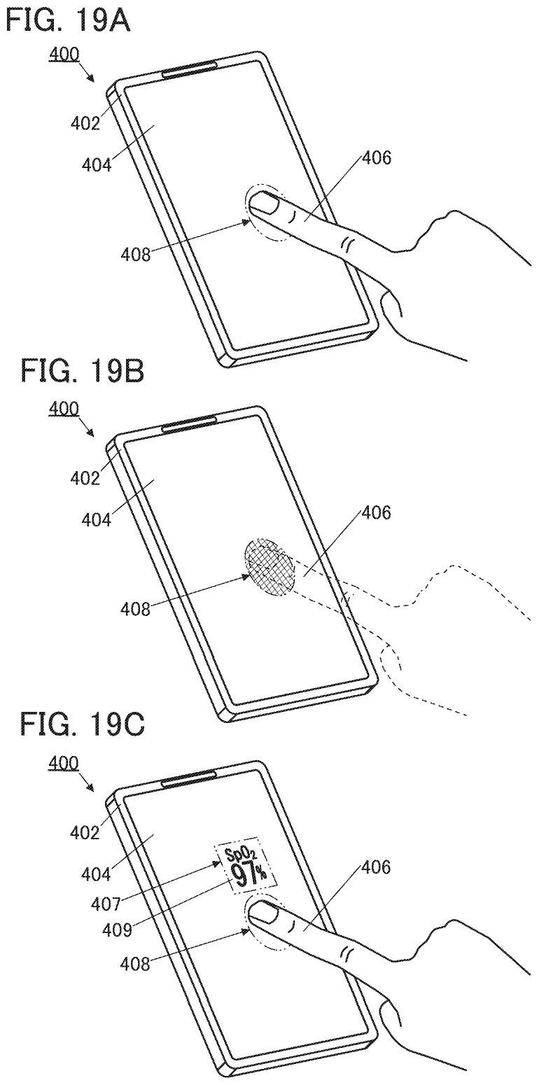

FIG. 19A illustrates an example of an electronic device including the display apparatus of one embodiment of the present invention. A portable information terminal 400 illustrated in FIG. 19A can be used as a smartphone, for example. The portable information terminal 400 includes a housing 402 and a display portion 404. Any of the above-described display apparatuses can be used for the display portion 404. For example, the above-described display apparatus 200B can be suitably used for the display portion 404.

FIG. 19A illustrates a state where a finger 406 is in contact with the display portion 404 of the portable information terminal 400. In FIG. 19A, a region 408 including a region where a touch is detected and the vicinity thereof is indicated by a dashed double-dotted line.

The portable information terminal 400 emits red light from pixels in the region 408 and detects red light incident on the display portion 404. Similarly, the portable information terminal 400 can measure the oxygen saturation of the finger 406 by emitting infrared light from pixels in the region 408 and detecting infrared light incident on the display portion 404. FIG. 19B illustrates a state where the pixels in the region 408 are in a lighting state. In FIG. 19B, the finger 406 is illustrated to be transparent with only the outline indicated by a dashed line, and the region 408 is hatched. As illustrated in FIG. 19B, the region 408 in a lighting state is hidden by the finger 406 and thus is less likely to be recognized by a user. Therefore, the oxygen saturation can be measured without causing stress to the user. In addition, the portable information terminal 400 can measure the oxygen saturation at any position in the display portion 404.

The obtained oxygen saturation may be displayed on the display portion 404. FIG. 19C illustrates a state where an image 409 showing the oxygen saturation is displayed in a region 407. FIG. 19C illustrates characters of “SpO₂ 97%” as an example of the image 409. Note that the image 409 may be an image or may include an image and a character. The region 407 is provided at a given position in the display portion 404.

This embodiment can be combined with the other embodiments as appropriate. In the case where a plurality of structure examples are described in one embodiment in this specification, the structure examples can be combined as appropriate.

### Embodiment 2

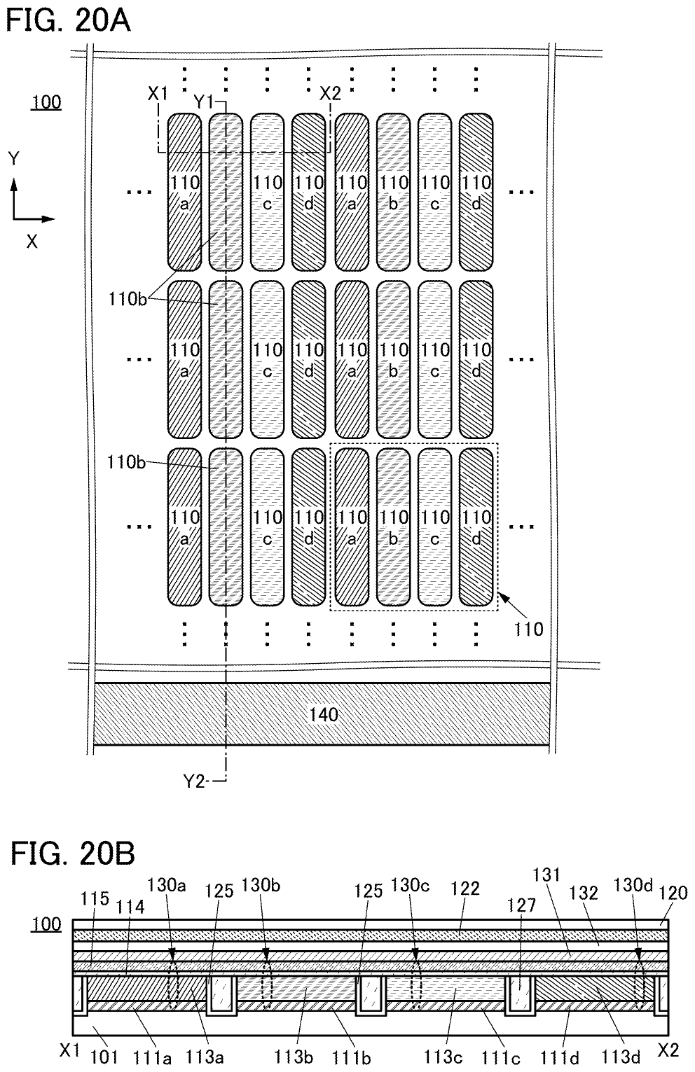

In this embodiment, a display apparatus of one embodiment of the present invention and a fabrication method thereof are described with reference to FIG. 20 to FIG. 38.

In the case of fabricating a display apparatus including light-emitting devices emitting light of different colors and a light-receiving device, a plurality of light-emitting layers and an active layer each need to be formed into an island-like shape.

For example, an island-shaped light-emitting layer and active layer can be formed by a vacuum evaporation method using a metal mask (also referred to as a shadow mask). However, this method causes a deviation from the designed shape and position of an island-shaped light-emitting layer and active layer due to various influences such as the low accuracy of the metal mask position, the positional deviation between the metal mask and a substrate, a warp of the metal mask, and the vapor-scattering-induced expansion of outline of the formed film; accordingly, it is difficult to achieve a high resolution and a high aperture ratio of the display apparatus.

In a fabrication method of a display apparatus of one embodiment of the present invention, an island-shaped pixel electrode (also can be referred to as a lower electrode) is formed, a first layer to be an EL layer is formed over the entire surface, and then a first sacrificial layer is formed over the first layer. After that, a first resist mask is formed over the first sacrificial layer and the first layer and the first sacrificial layer are processed using the first resist mask, whereby an island-shaped EL layer is formed. Similarly, a second layer to be a light-receiving layer is formed into an island-shaped light-receiving layer using a second sacrificial layer and a second resist mask. Note that in this specification and the like, a sacrificial layer may be referred to as a mask layer.

As described above, in the fabrication method of the display apparatus of one embodiment of the present invention, the island-shaped EL layer is formed by processing the layer to be the EL layer formed over the entire surface, not by using a fine metal mask (high-resolution metal mask). Similarly, the island-shaped light-receiving layer is formed by processing the layer to be the light-receiving layer formed over the entire surface, not by using a fine metal mask. Accordingly, a display apparatus with a high resolution or a display apparatus with a high aperture ratio, which has been difficult to achieve so far, can be obtained. Moreover, EL layers can be formed separately for the respective colors, enabling the display apparatus to perform extremely clear display with high contrast and high display quality. Furthermore, a light-receiving device can be provided in the pixel, enabling the display apparatus to have a high-resolution image capturing function and a sensing function of a touch sensor, a near touch sensor, or the like. In addition, a sacrificial layer provided over an EL layer and a light-receiving layer can reduce damage to the EL layer and the light-receiving layer in the fabrication process of the display apparatus, increasing the reliability of the light-emitting device and the light-receiving device.

It is difficult to set the distance between adjacent devices among the light-emitting devices and the light-receiving device to be less than 10 μm with a formation method using a metal mask, for example; however, with the above method, the distance can be decreased to less than or equal to 3 μm, less than or equal to 2 μm, or less than or equal to 1 μm. For example, with the use of a light exposure apparatus for LSI, the distance can be decreased to less than or equal to 500 nm, less than or equal to 200 nm, less than or equal to 100 nm, or less than or equal to 50 nm. Thus, the area of a light-emitting region (hereinafter, also referred to as a light-emitting area) and the light-receiving area in a pixel can be increased and the aperture ratio can be close to 100%. For example, the aperture ratio higher than or equal to 50%, higher than or equal to 60%, higher than or equal to 70%, higher than or equal to 80%, or higher than or equal to 90% and lower than 100% can be achieved.

Furthermore, patterns of the EL layer and the light-receiving layer themselves can be made extremely smaller than those in the case of using a fine metal mask. For example, in the case of using a fine metal mask for separate formation of EL layers and a light-receiving layer, the thickness varies between the center and the edge of the EL layer, which causes a reduction in an effective area that can be used as a light-emitting region or a light-receiving region with respect to the area of the EL layer. In contrast, in the above formation method, a pattern is formed by processing a film formed to have a uniform thickness, which enables a uniform thickness in the pattern; thus, even in a fine pattern, almost the entire area can be used as a light-emitting region or the light-receiving region. Thus, a display apparatus having both a high resolution and a high aperture ratio can be fabricated.

### <Structure Example 1 of Display Apparatus>

FIG. 20A and FIG. 20B illustrate the display apparatus of one embodiment of the present invention.

FIG. 20A is a top view of the display apparatus 100. The display apparatus 100 includes a display portion in which a plurality of pixels 110 are arranged in a matrix, and a connection portion 140 outside the display portion. The connection portion 140 can be referred to as a cathode contact portion.

The pixel 110 illustrated in FIG. 20A employs stripe arrangement. The pixel 110 illustrated in FIG. 20A is composed of four subpixels: a subpixel 110a, a subpixel 110b, a subpixel 110c, and a subpixel 110d. The subpixel 110a, the subpixel 110b, and the subpixel 110c include light-emitting devices that emit light in different wavelength ranges. Any of the above-described light-emitting devices can be used as the light-emitting device. The subpixel 110a, the subpixel 110b, and the subpixel 110c can be subpixels of three colors of red (R), green (G), and blue (B) or subpixels of three colors of yellow (Y), cyan (C), and magenta (M), for example. The subpixel 110d includes a light-receiving device. Any of the above-described light-receiving devices can be used as the light-receiving device.

FIG. 20A illustrates an example where subpixels are arranged to be aligned in the X direction and subpixels of the same kind are arranged to be aligned in the Y direction. Note that subpixels of different kinds may be arranged to be aligned in the Y direction, and subpixels of the same kind may be arranged to be aligned in the X direction.

Although the top view in FIG. 20A illustrates an example where the connection portion 140 is positioned in the lower side of the display portion, one embodiment of the present invention is not particularly limited thereto. The connection portion 140 is provided in at least one of the upper side, the right side, the left side, and the lower side of the display portion in the top view, or may be provided so as to surround the four sides of the display portion. The number of the connection portions 140 can be one or more.

FIG. 20B is a cross-sectional view along a dashed-dotted line X1-X2 in FIG. 20A.

As illustrated in FIG. 20B, the display apparatus 100 includes a light-emitting device 130a, a light-emitting device 130b, a light-emitting device 130c, and a light-receiving device 130d over a layer 101 including transistors. Furthermore, a protective layer 131 and a protective layer 132 are provided to cover these light-emitting devices and the light-receiving device. A substrate 120 is bonded onto the protective layer 132 with a resin layer 122. In a region between adjacent devices among the light-emitting devices and the light-receiving device, an insulating layer 125 and an insulating layer 127 over the insulating layer 125 are provided.

The display apparatus of one embodiment of the present invention can have any of the following structures: a top-emission structure where light is emitted in a direction opposite to the substrate where the light-emitting device is formed, a bottom-emission structure where light is emitted toward the substrate where the light-emitting device is formed, and a dual-emission structure where light is emitted toward both surfaces.

The layer 101 including transistors can employ a stacked-layer structure where a plurality of transistors are provided over a substrate and an insulating layer is provided to cover these transistors, for example. The layer 101 including transistors may have a depressed portion between adjacent light-emitting devices. For example, an insulating layer positioned on the outermost surface of the layer 101 including transistors may have a depressed portion.

The light-emitting device 130a, the light-emitting device 130b, and the light-emitting device 130c emit light in different wavelength ranges. The light-emitting device 130a, the light-emitting device 130b, and the light-emitting device 130c preferably emit light of three colors, red (R), green (G), and blue (B) as a combination, for example.

The light-emitting device 130a includes a pixel electrode 111a over the layer 101 including transistors, an island-shaped EL layer 113a over the pixel electrode 111a, a layer 114 over the island-shaped EL layer 113a, and a common electrode 115 over the layer 114.

The light-emitting device 130b includes a pixel electrode 111b over the layer 101 including transistors, an island-shaped EL layer 113b over the pixel electrode 111b, the layer 114 over the island-shaped EL layer 113b, and the common electrode 115 over the layer 114.

The light-emitting device 130c includes a pixel electrode 111c over the layer 101 including transistors, an island-shaped EL layer 113c over the pixel electrode 111c, the layer 114 over the island-shaped EL layer 113c, and the common electrode 115 over the layer 114.

The light-receiving device 130d includes a pixel electrode 111d over the layer 101 including transistors, an island-shaped light-receiving layer 113d over the pixel electrode 111d, the layer 114 over the island-shaped light-receiving layer 113d, and the common electrode 115 over the layer 114.

The light-emitting devices of different colors and the light-receiving device share one film as the common electrode. The common electrode is electrically connected to a conductive layer provided in the connection portion 140. Thus, the same potential is supplied to the common electrode included in the light-emitting devices of different colors and the light-receiving device.

For the pair of electrodes (the pixel electrode and the common electrode) of the light-emitting device and the light-receiving device, a metal, an alloy, an electrically conductive compound, a mixture thereof, and the like can be used as appropriate. Specific examples include an indium tin oxide (also referred to as an In—Sn oxide or ITO), an In—Si—Sn oxide (also referred to as ITSO), an indium zinc oxide (In—Zn oxide), an In—W—Zn oxide, an alloy containing aluminum (an aluminum alloy) such as an alloy of aluminum, nickel, and lanthanum (Al—Ni—La), and an alloy containing silver such as an alloy of silver and magnesium and an alloy of silver, palladium, and copper (Ag—Pd—Cu, also referred to as APC). In addition, it is possible to use a metal such as aluminum (Al), magnesium (Mg), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) and an alloy containing an appropriate combination of any of these metals. It is also possible to use an element belonging to Group 1 or Group 2 of the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these, graphene, or the like.

The light-emitting devices preferably employ a microcavity structure. Therefore, one of the pair of electrodes of the light-emitting devices is preferably an electrode having a transmitting property and a reflecting property with respect to visible light (a semi-transmissive and semi-reflective electrode), and the other is preferably an electrode having a reflecting property with respect to visible light (a reflective electrode). When the light-emitting devices have a microcavity structure, light obtained from the light-emitting layers can be resonated between the electrodes, whereby light emitted from the light-emitting devices can be intensified.

Note that the semi-transmissive and semi-reflective electrode can have a stacked-layer structure of an electrode having a reflecting property with respect to visible light and an electrode having a transmitting property with respect to visible light (also referred to as a transparent electrode).

The transparent electrode has a light transmittance higher than or equal to 40%. For example, an electrode having a visible light transmittance higher than or equal to 40% is preferably used in light-emitting elements. The semi-transmissive and semi-reflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes each preferably have a resistivity lower than or equal to 1×10⁻² Ωcm. Note that in the case where any of the light-emitting elements emits infrared light, the infrared light transmittance and reflectance of these electrodes preferably satisfy the above-described numerical ranges of the visible light transmittance and reflectance.

The EL layer 113a, the EL layer 113b, the EL layer 113c, and the light-receiving layer 113d are each provided to have an island-like shape. The EL layer 113a, the EL layer 113b, and the EL layer 113c each include a light-emitting layer. The EL layer 113a, the EL layer 113b, and the EL layer 113c preferably include light-emitting layers that emit light in different wavelength ranges. The light-receiving layer 113d includes an active layer.

The light-emitting layer is a layer containing a light-emitting substance. The light-emitting layer can contain one or more kinds of light-emitting substances. As the light-emitting substance, a substance that exhibits an emission color of blue, violet, bluish violet, green, yellowish green, yellow, orange, red, or the like is appropriately used. As the light-emitting substance, a substance that emits infrared light can also be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably contains, for example, a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting device can be achieved at the same time.

In the combination of materials for forming an exciplex, the HOMO level (highest occupied molecular orbital level) of the hole-transport material is preferably higher than or equal to the HOMO level of the electron-transport material. The LUMO level (lowest unoccupied molecular orbital level) of the hole-transport material is preferably higher than or equal to the LUMO level of the electron-transport material. The LUMO levels and the HOMO levels of the materials can be derived from the electrochemical characteristics (reduction potentials and oxidation potentials) of the materials that are measured by cyclic voltammetry (CV).

Note that the formation of an exciplex can be confirmed by a phenomenon in which the emission spectrum of a mixed film in which the hole-transport material and the electron-transport material are mixed is shifted to the longer wavelength side than the emission spectrum of each of the materials (or has another peak on the longer wavelength side), observed by comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of the transient PL of the hole-transport material, the transient PL of the electron-transport material, and the transient PL of the mixed film of these materials. The transient PL can be rephrased as transient electroluminescence (EL). That is, the formation of an exciplex can also be confirmed by a difference in transient response observed by comparison of the transient EL of the hole-transport material, the transient EL of the electron-transport material, and the transient EL of the mixed film of these materials.

In addition to the light-emitting layer, the EL layer 113a, the EL layer 113b, and the EL layer 113c may further include a layer containing any of a substance with a high hole-injection property, a substance with a high hole-transport property (also referred to as a hole-transport material), a hole-blocking material, a substance with a high electron-transport property (also referred to as an electron-transport material), a substance with a high electron-injection property, an electron-blocking material, a substance with a bipolar property (also referred to as a substance with a high electron-transport property and a high hole-transport property or a bipolar material), and the like.

Either a low molecular compound or a high molecular compound can be used for the light-emitting device, and an inorganic compound may also be included. Each layer included in the light-emitting device can be formed by an evaporation method (including a vacuum evaporation method), a transfer method, a printing method, an inkjet method, a coating method, or the like.

For example, the EL layer 113a, the EL layer 113b, and the EL layer 113c may each include one or more of a hole-injection layer, a hole-transport layer, a hole-blocking layer, an electron-blocking layer, an electron-transport layer, and an electron-injection layer.

In the EL layer, one or more of a hole-injection layer, a hole-transport layer, a hole-blocking layer, an electron-blocking layer, an electron-transport layer, and an electron-injection layer can be formed as a layer common to the light-emitting devices of the respective colors. For example, a carrier-injection layer (a hole-injection layer or an electron-injection layer) may be formed as the layer 114. Note that all the layers in the EL layer may be separately formed for the respective colors. That is, the EL layer does not necessarily include a layer common to the light-emitting devices of the respective colors.

The EL layer 113a, the EL layer 113b, and the EL layer 113c each preferably include a light-emitting layer and a carrier-transport layer over the light-emitting layer. Accordingly, the light-emitting layer is inhibited from being exposed on the outermost surface during the fabrication process of the display apparatus 100, so that damage to the light-emitting layer can be reduced. Thus, the reliability of the light-emitting device can be increased.

The hole-injection layer is a layer injecting holes from an anode to the hole-transport layer, and a layer containing a substance with a high hole-injection property. Examples of the substance with a high hole-injection property include an aromatic amine compound and a composite material containing a hole-transport material and an acceptor material (electron-accepting material).

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, a substance with a high hole-transport property, such as a π-electron rich heteroaromatic compound (e.g., a carbazole derivative, a thiophene derivative, or a furan derivative) or an aromatic amine (a compound having an aromatic amine skeleton), is preferable.

The electron-transport layer is a layer transporting electrons, which are injected from a cathode by the electron-injection layer, to the light-emitting layer. The electron-transport layer is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. For the electron-transport material, it is possible to use a substance having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-injection layer is a layer injecting electrons from the cathode to the electron-transport layer, and a layer containing a substance with a high electron-injection property. As the substance with a high electron-injection property, an alkali metal, an alkaline earth metal, or a compound thereof can be used. As the substance with a high electron-injection property, a composite material containing an electron-transport material and a donor material (electron-donating material) can also be used.

For the electron-injection layer, for example, an alkali metal, an alkaline earth metal, or a compound thereof, such as lithium, cesium, ytterbium, lithium fluoride (LiF), cesium fluoride (CsF), calcium fluoride (CaFₓ, X is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate can be used. The electron-injection layer may have a stacked-layer structure of two or more layers. The stacked-layer structure can be, for example, a structure where lithium fluoride is used for a first layer and ytterbium is provided for a second layer.

Alternatively, for the electron-injection layer, an electron-transport material may be used. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino<2,3-a:2′,3′-c>phenazine (abbreviation: HATNA), 2,4,6-tris<3′-(pyridin-3-yl)biphenyl-3-yl>-1,3,5-tri azine (abbreviation: TmPPPyTz), or the like can be used as the organic compound having an unshared electron pair. Note that NBPhen has a higher glass transition temperature (Tg) than BPhen and thus has high heat resistance.

In the case of fabricating a light-emitting device with a tandem structure, an intermediate layer is provided between two light-emitting units. The intermediate layer has a function of injecting electrons into one of the two light-emitting units and injecting holes to the other when a voltage is applied between the pair of electrodes.

For the intermediate layer, for example, a material that can be used for the electron-injection layer, such as lithium, can be suitably used. For the intermediate layer, for example, a material that can be used for the hole-injection layer can be suitably used. For the intermediate layer, a layer containing a hole-transport material and an acceptor material (electron-accepting material) can be used. For the intermediate layer, a layer containing an electron-transport material and a donor material can be used. Forming the intermediate layer including such a layer can inhibit an increase in the driving voltage that would be caused by stacking light-emitting units.

The active layer includes a semiconductor. Examples of the semiconductor include an inorganic semiconductor such as silicon and an organic semiconductor including an organic compound. This embodiment shows an example where an organic semiconductor is used as the semiconductor contained in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material contained in the active layer include electron-accepting organic semiconductor materials such as fullerene (e.g., C₆₀ fullerene and C₇₀ fullerene) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). In general, when π-electron conjugation (resonance) spreads in a plane as in benzene, an electron-donating property (donor property) becomes high; however, since fullerene has a spherical shape, fullerene has a high electron-accepting property even when π-electrons widely spread. The high electron-accepting property efficiently causes rapid charge separation and thus is useful for a light-receiving element. Both C₆₀ fullerene and C₇₀ fullerene have a wide absorption band in the visible light region, and C₇₀ fullerene is especially preferable because of having a larger π-electron conjugation system and a wider absorption band in the long wavelength region than C₆₀ fullerene. Other examples of the fullerene derivative include [6,6]-Phenyl-C71-butyric acid methyl ester (abbreviation: PC70BM), [6,6]-Phenyl-C61-butyric acid methyl ester (abbreviation: PC60BM), and 1′,1″,4′,4″-Tetrahydro-di[1,4]methanonaphthaleno[1,2:2′,3′,56,60:2″,3″][5,6]fullerene-C60 (abbreviation: ICBA).

Examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin(II) phthalocyanine (SnPc), and quinacridone.

Examples of a p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can improve the carrier-transport property.

For example, the active layer is preferably formed by co-evaporation of an n-type semiconductor and a p-type semiconductor. Alternatively, the active layer may be formed by stacking an n-type semiconductor and a p-type semiconductor.

Either a low molecular compound or a high molecular compound can be used for the light-emitting element and the light-receiving element, and an inorganic compound may be contained. Each layer included in the light-emitting element and the light-receiving element can be formed by an evaporation method (including a vacuum evaporation method), a transfer method, a printing method, an inkjet method, a coating method, or the like.

As the hole-transport material, a high molecular compound such as poly(3,4-ethylenedioxythiophene)/poly(styrenesulfonic acid) (PEDOT/PSS), or an inorganic compound such as a molybdenum oxide or copper iodide (CuI) can be used, for example. As the electron-transport material, an inorganic compound such as zinc oxide (ZnO) can be used.

For the active layer, a high molecular compound such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

The active layer may contain a mixture of three or more kinds of materials. For example, a third material may be mixed with an n-type semiconductor material and a p-type semiconductor material in order to extend the wavelength range. In this case, the third material may be a low molecular compound or a high molecular compound.

The side surfaces of the pixel electrode 111a, the pixel electrode 111b, the pixel electrode 111c, the pixel electrode 111d, the EL layer 113a, the EL layer 113b, the EL layer 113c, and the light-receiving layer 113d are covered with the insulating layer 125 and the insulating layer 127. This can inhibit contact between the layer 114 (or the common electrode 115) and the side surface of any of the pixel electrode 111a, the pixel electrode 111b, the pixel electrode 111c, the pixel electrode 111d, the EL layer 113a, the EL layer 113b, the EL layer 113c, and the light-receiving layer 113d, thereby inhibiting a short circuit of the light-emitting devices and the light-receiving device.

The insulating layer 125 preferably covers at least the side surfaces of the pixel electrode 111a, the pixel electrode 111b, the pixel electrode 111c, and the pixel electrode 111d. It is further preferable that the insulating layer 125 cover the side surfaces of the EL layer 113a, the EL layer 113b, the EL layer 113c, and the light-receiving layer 113d. The insulating layer 125 can be in contact with the side surfaces of the pixel electrode 111a, the pixel electrode 111b, the pixel electrode 111c, the pixel electrode 111d, the EL layer 113a, the EL layer 113b, the EL layer 113c, and the light-receiving layer 113d.

The insulating layer 127 is provided over the insulating layer 125 to fill a depressed portion formed by the insulating layer 125. The insulating layer 127 can overlap with the side surfaces of the pixel electrode 111a, the pixel electrode 111b, the pixel electrode 111c, the pixel electrode 111d, the EL layer 113a, the EL layer 113b, the EL layer 113c, and the light-receiving layer 113d with the insulating layer 125 therebetween.

Note that one of the insulating layer 125 and the insulating layer 127 is not necessarily provided. For example, in the case where the insulating layer 125 is not provided, the insulating layer 127 can be in contact with the side surfaces of the EL layer 113a, the EL layer 113b, the EL layer 113c, and the light-receiving layer 113d. The insulating layers 127 can be provided over the layer 101 so as to fill spaces between adjacent layers among the EL layers included in the light-emitting devices and the light-receiving layer included in the light-receiving device.

The layer 114 and the common electrode 115 are provided over the EL layer 113a, the EL layer 113b, the EL layer 113c, the light-receiving layer 113d, the insulating layer 125, and the insulating layer 127. Before the insulating layer 125 and the insulating layer 127 are provided, a level difference is generated between a region where the pixel electrode is provided and a region where the pixel electrode is not provided (a region between adjacent devices among the light-emitting devices and the light-receiving device). In the display apparatus of one embodiment of the present invention, the level difference can be eliminated with the insulating layer 125 and the insulating layer 127, and the coverage with the layer 114 and the common electrode 115 can be improved. Consequently, a connection defect due to disconnection of the common electrode 115 can be inhibited. Alternatively, an increase in electric resistance due to local thinning of the common electrode 115 by the level difference can be inhibited. Note that in this specification and the like, disconnection refers to a phenomenon in which a layer, a film, or an electrode is split because of the shape of the formation surface (e.g., a step).

In order to improve the planarity of the formation surfaces of the layer 114 and the common electrode 115, the levels of the top surface of the insulating layer 125 and the top surface of the insulating layer 127 are each preferably equal to or substantially equal to the level of the top surface of at least one of the EL layer 113a, the EL layer 113b, the EL layer 113c, and the light-receiving layer 113d. The top surface of the insulating layer 127 preferably has a flat shape and may have a projected portion or a depressed portion.

The insulating layer 125 includes regions in contact with the side surfaces of the EL layer 113a, the EL layer 113b, the EL layer 113c, and the light-receiving layer 113d, and functions as a protective insulating layer for the EL layer 113a, the EL layer 113b, the EL layer 113c, and the light-receiving layer 113d. With the insulating layer 125, entry of impurities (e.g., oxygen or moisture) through the side surfaces of the EL layer 113a, the EL layer 113b, the EL layer 113c, and the light-receiving layer 113d into their insides can be inhibited, and thus a highly reliable display apparatus can be obtained.

When the width (thickness) of the insulating layer 125 in the regions in contact with the side surfaces of the EL layer 113a, the EL layer 113b, the EL layer 113c, and the light-receiving layer 113d is large in a cross-sectional view, spaces between adjacent layers among the EL layer 113a, the EL layer 113b, the EL layer 113c, and the light-receiving layer 113d each increase, which might result in a lower aperture ratio. In addition, when the width (thickness) of the insulating layer 125 is small, the effect of inhibiting entry of impurities through the side surfaces of the EL layer 113a, the EL layer 113b, the EL layer 113c, and the light-receiving layer 113d into their insides might be weakened.

The width (thickness) of the insulating layer 125 in the regions in contact with the side surfaces of the EL layer 113a, the EL layer 113b, the EL layer 113c, and the light-receiving layer 113d is preferably greater than or equal to 3 nm and less than or equal to 200 nm, further preferably greater than or equal to 3 nm and less than or equal to 150 nm, further preferably greater than or equal to 5 nm and less than or equal to 150 nm, still further preferably greater than or equal to 5 nm and less than or equal to 100 nm, still further preferably greater than or equal to 10 nm and less than or equal to 100 nm, yet further preferably greater than or equal to nm and less than or equal to 50 nm. When the width (thickness) of the insulating layer 125 is within the above-described range, a highly reliable display apparatus with a high aperture ratio can be obtained.

The insulating layer 125 can contain an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure.

The insulating layer 125 can be formed by a sputtering method, a chemical vapor deposition (CVD) method, a vacuum evaporation method, a pulsed laser deposition (PLD) method, an atomic layer deposition (ALD) method, or the like. The insulating layer 125 is preferably formed by an ALD method achieving good coverage. An ALD method causes less deposition damage to a formation surface, and thus can be suitably used.

Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used as the insulating layer 125, the insulating layer 125 including few pinholes and having an excellent function of protecting the EL layer can be formed.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulating layer 127 provided over the insulating layer 125 has a planarization function for the depressed portion of the insulating layer 125, which is formed between adjacent light-emitting devices. In other words, the insulating layer 127 has an effect of improving the planarity of the formation surface of the common electrode 115. An insulating layer containing an organic material can be suitably used as the insulating layer 127. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the insulating layer 127, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used. Moreover, a photosensitive resin can be used for the insulating layer 127. A photoresist may be used for the photosensitive resin. As the photosensitive resin, a positive material or a negative material can be used.

A difference between the top surface level of the insulating layer 127 and the top surface level of one of the EL layer 113a, the EL layer 113b, the EL layer 113c, and the light-receiving layer 113d is preferably less than or equal to 0.5 times, further preferably less than or equal to 0.3 times the thickness of the insulating layer 127, for example. As another example, the insulating layer 127 may be provided such that the top surface level of one of the EL layer 113a, the EL layer 113b, the EL layer 113c, and the light-receiving layer 113d is higher than the top surface level of the insulating layer 127. As another example, the insulating layer 127 may be provided such that the top surface level of the insulating layer 127 is higher than the top surface levels of the light-emitting layers included in the EL layer 113a, the EL layer 113b, and the EL layer 113c, and higher than the top surface level of the active layer included in the light-receiving layer 113d.

The protective layer 131 and the protective layer 132 are preferably provided over the light-emitting device 130a, the light-emitting device 130b, the light-emitting device 130c, and the light-receiving device 130d. Providing the protective layer 131 and the protective layer 132 can improve the reliability of the light-emitting devices and the light-receiving device.

There is no limitation on the conductivity of the protective layer 131 and the protective layer 132. As the protective layer 131 and the protective layer 132, at least one type of insulating films, semiconductor films, and conductive films can be used.

The protective layer 131 and the protective layer 132 each including an inorganic film can inhibit deterioration of the light-emitting devices and the light-receiving device by preventing oxidation of the common electrode 115 and inhibiting entry of impurities (e.g., moisture and oxygen) into the light-emitting device 130a, the light-emitting device 130b, the light-emitting device 130c, and the light-receiving device 130d, for example; thus, the reliability of the display apparatus can be improved.

For each of the protective layer 131 and the protective layer 132, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film.

Each of the protective layers 131 and 132 preferably includes a nitride insulating film or a nitride oxide insulating film, and further preferably includes a nitride insulating film.

For each of the protective layer 131 and the protective layer 132, an inorganic film containing an In—Sn oxide (also referred to as ITO), an In—Zn oxide, a Ga—Zn oxide, an Al—Zn oxide, an indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When extraction of light emitted from the light-emitting device and incidence of light on the light-receiving device are performed through the protective layer 131 and the protective layer 132, the protective layer 131 and the protective layer 132 each preferably have a high transmitting property with respect to visible light. For example, ITO, IGZO, and aluminum oxide are preferable because they are each an inorganic material having a high property of transmitting visible light.

The protective layer 131 and the protective layer 132 can each have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 131 and the protective layer 132 may each include an organic film. For example, the protective layer 132 may include both an organic film and an inorganic film.

The protective layer 131 and the protective layer 132 may be formed by different deposition methods. Specifically, the protective layer 131 may be formed by an ALD method, and the protective layer 132 may be formed by a sputtering method.

The end portions of the top surfaces of the pixel electrode 111a, the pixel electrode 111b, the pixel electrode 111c, and the pixel electrode 111d are not covered with an insulating layer. This allows the distance between adjacent devices among the light-emitting devices and the light-emitting device to be extremely short. Accordingly, the display apparatus can have a high resolution or a high definition.

In this specification and the like, a device fabricated using a metal mask or an FMM (fine metal mask or a high-resolution mask) may be referred to as a device having an MM (metal mask) structure. In this specification and the like, a device fabricated without using a metal mask or an FMM may be referred to as a device having an MML (metal maskless) structure.

In this specification and the like, a structure where light-emitting layers in light-emitting devices of different colors (here, blue (B), green (G), and red (R)) are separately formed or separately patterned is sometimes referred to as an SBS (Side By Side) structure. The SBS structure can optimize materials and structures of light-emitting devices and thus can extend freedom of choice of materials and structures, whereby the luminance and the reliability can be easily improved.

In this specification and the like, a light-emitting device capable of emitting white light is sometimes referred to as a white-light-emitting device. Note that a combination of white-light-emitting devices with coloring layers (e.g., color filters) enables a full-color display apparatus.

Note that structures of light-emitting devices can be classified roughly into a single structure and a tandem structure. A device having a single structure includes one light-emitting unit between a pair of electrodes, and the light-emitting unit preferably includes one or more light-emitting layers. To obtain white light emission, two or more of light-emitting layers are selected such that their emission colors are complementary. For example, when an emission color of a first light-emitting layer and an emission color of a second light-emitting layer are complementary, the light-emitting device can be configured to emit white light as a whole. In the case of a light-emitting device including three or more light-emitting layers, white light emission can be obtained by mixing emission colors of the light-emitting layers.

A device having a tandem structure includes two or more light-emitting units between a pair of electrodes, and each light-emitting unit preferably includes one or more light-emitting layers. To obtain white light emission, the structure is made so that light from light-emitting layers of the plurality of light-emitting units can be combined to be white light. Note that a structure for obtaining white light emission is similar to that in the case of a single structure. In the device having a tandem structure, an intermediate layer such as a charge generation layer is suitably provided between the plurality of light-emitting units.

When the white-light-emitting device (having a single structure or a tandem structure) and a light-emitting device having an SBS structure are compared to each other, the light-emitting device having an SBS structure can have lower power consumption than the white-light-emitting device. To reduce power consumption, a light-emitting device having an SBS structure is suitably used. Meanwhile, the white-light-emitting device is suitable in terms of lower manufacturing cost or higher manufacturing yield because the manufacturing process of the white-light-emitting device is simpler than that of the light-emitting device having an SBS structure.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to nm. In other words, the display apparatus includes a region where the distance between the side surface of the EL layer 113a and the side surface of the EL layer 113b or the distance between the side surface of the EL layer 113b and the side surface of the EL layer 113c is less than or equal to 1 μm, preferably less than or equal to 0.5 μm (500 nm), further preferably less than or equal to 100 nm.

Similarly, in the display apparatus of this embodiment, the distance between the light-receiving devices can be short. Specifically, the distance between the light-receiving devices, the distance between the light-receiving layers, or the distance between the pixel electrodes can be less than 10 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus includes a region where a distance between a side surface of a light-receiving layer and a side surface of a light-receiving layer that are adjacent to each other is less than or equal to 0.5 μm (500 nm), preferably less than or equal to 100 nm.

In the display apparatus of this embodiment, the distance between the light-emitting device and the light-receiving device can be short. Specifically, the distance between the light-emitting device and the light-receiving device, the distance between the EL layer and the light-receiving layer, or the distance between the pixel electrodes can be less than 20 μm, less than or equal to 10 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus includes a region where the distance between the side surface of the EL layer 113a and the side surface of the light-receiving layer 113d, the distance between the side surface of the EL layer 113b and the side surface of the light-receiving layer 113d, or the distance between the side surface of the EL layer 113c and the light-receiving layer 113d is less than or equal to 1 μm, preferably less than or equal to 0.5 μm (500 nm), further preferably less than or equal to 100 nm.

A light-blocking layer may be provided on the surface of the substrate 120 on the resin layer 122 side. A variety of optical members can be arranged on the outer surface of the substrate 120. Examples of the optical members include a polarizing plate, a retardation plate, a light diffusion layer (a diffusion film or the like), an anti-reflective layer, and a light-condensing film. Furthermore, an antistatic film inhibiting the attachment of dust, a water repellent film suppressing the attachment of stain, a hard coat film inhibiting generation of a scratch caused by the use, an impact-absorbing layer, or the like may be arranged on the outer surface of the substrate 120.

For the substrate 120, glass, quartz, ceramics, sapphire, a resin, a metal, an alloy, a semiconductor, or the like can be used. The substrate on the side from which light from the light-emitting device is extracted is formed using a material that transmits the light. When the substrate 120 is formed using a flexible material, the flexibility of the display apparatus can be increased and a flexible display can be achieved. Furthermore, a polarizing plate may be used as the substrate 120.

For the substrate 120, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 120.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display panel might be changed, e.g., creases are generated. Thus, for the substrate, a film with a low water absorption rate is preferably used. For example, the water absorption rate of the film is preferably lower than or equal to 1%, further preferably lower than or equal to 0.1%, still further preferably lower than or equal to 0.01%.

For the resin layer 122, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-component resin may be used. An adhesive sheet or the like may be used.

As materials that can be used for a gate, a source, and a drain of a transistor and conductive layers such as a variety of wirings and electrodes included in a display apparatus, metals such as aluminum, titanium, chromium, nickel, copper, yttrium, zirconium, molybdenum, silver, tantalum, or tungsten, an alloy containing any of these metals as its main component, and the like can be given. A single layer or a stacked-layer structure including a film containing any of these materials can be used.

As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Further alternatively, a nitride of the metal material (e.g., titanium nitride) or the like may be used. Note that in the case of using the metal material or the alloy material (or the nitride thereof), the thickness is preferably set small enough to have a light-transmitting property. A stacked film of any of the above materials can be used as a conductive layer. For example, a stacked film of indium tin oxide and an alloy of silver and magnesium, or the like is preferably used for increased conductivity. They can also be used for conductive layers such as wirings and electrodes included in the display apparatus, and conductive layers (e.g., a conductive layer functioning as a pixel electrode or a common electrode) included in a light-emitting device.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

### <Pixel Layout>

Pixel layouts will be described below. There is no particular limitation on the arrangement of subpixels, and a variety of methods can be employed. Examples of the arrangement of subpixels include stripe arrangement, S stripe arrangement, matrix arrangement, delta arrangement, Bayer arrangement, and PenTile arrangement.

Examples of a top surface shape of the subpixel include polygons such as a triangle, a quadrangle (including a rectangle and a square), and a pentagon; polygons with rounded corners; an ellipse; and a circle. Here, the top surface shape of the subpixel corresponds to the top surface shape of a light-emitting region of a light-emitting device or a light-receiving region of a light-receiving device.

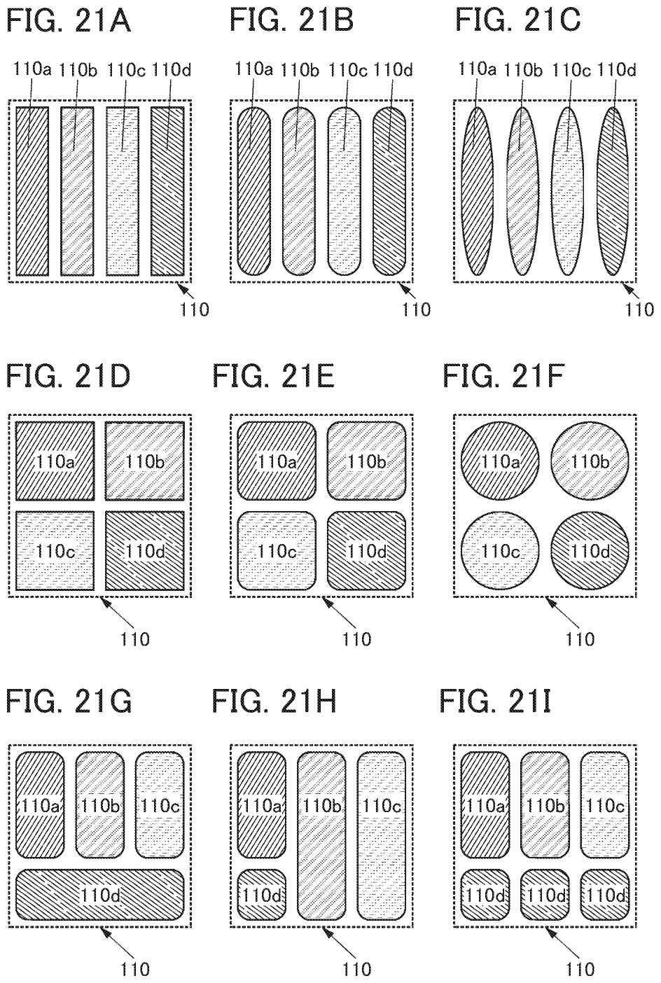

The pixels 110 illustrated in FIG. 21A to FIG. 21C employ stripe arrangement.

The display portion of the display apparatus of one embodiment of the present invention includes a plurality of pixels, and the pixels are arranged in the row direction and the column direction in a matrix. A display portion employing the pixel layout illustrated in FIG. 21A to FIG. 21C includes a first arrangement where the subpixel 110a, the subpixel 110b, the subpixel 110c, and the subpixel 110d are repeatedly arranged in this order in the row direction. Furthermore, the first arrangement is repeated in the column direction.

The display portion includes a second arrangement where the subpixel 110a is repeatedly arranged in the column direction, a third arrangement where the subpixel 110b is repeatedly arranged in the column direction, a fourth arrangement where the subpixel 110c is repeatedly arranged in the column direction, and a fifth arrangement where the subpixel 110d is repeatedly arranged in the column direction. Furthermore, the second arrangement, the third arrangement, the fourth arrangement, and the fifth arrangement are repeated in this order in the row direction.

In this embodiment and the like, for clear explanation of the pixel layout, the horizontal direction in the drawing is the row direction and the vertical direction is the column direction; however, one embodiment of the present invention is not limited thereto and the row direction and the column direction can be replaced with each other. Thus, in this specification and the like, one of the row direction and the column direction is referred to as a first direction and the other of the row direction and the column direction is referred to as a second direction, in some cases. The second direction is orthogonal to the first direction. Note that in the case where the top surface shape of the display portion is a rectangular shape, each of the first direction and the second direction is not necessarily parallel to a straight line portion of the outline of the display portion. The top surface shape is not limited to a rectangular shape, and may be a polygonal shape or a shape with curve (e.g., circle or ellipse). The first direction and the second direction may be a given direction with respect to the display portion.

In this specification and the like, for clear explanation of pixel layout, the subpixels are illustrated in the order from the left of a diagram; however, without limitation thereto, the order can be changed into the order from the right. Similarly, the subpixels are illustrated in the order from the top of a diagram; however, without limitation thereto, the order can be changed into the order from the bottom.

In this specification and the like, “repeatedly arranged” means that the smallest unit of ordered subpixels is arranged twice or more.

FIG. 21A illustrates an example where each subpixel has a rectangular top surface shape, FIG. 21B illustrates an example where each subpixel has a top surface shape formed by combining two half circles and a rectangle, and FIG. 21C illustrates an example where each subpixel has an elliptical top surface shape.

In a photolithography method, as a pattern to be processed becomes finer, the influence of light diffraction becomes more difficult to ignore; thus, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface shape of a subpixel becomes a polygon with rounded corners, an ellipse, a circle, or the like, in some cases.

Furthermore, in the fabrication method of the display apparatus of one embodiment of the present invention, the EL layer or the light-receiving layer is processed into an island-like shape with the use of a resist mask. A resist film formed over the EL layer or the light-receiving layer needs to be cured at a temperature lower than the upper temperature limit of the EL layer or the light-receiving layer. Thus, the resist film is insufficiently cured in some cases depending on the upper temperature limit of the material of the EL layer, the upper temperature limit of the material of the light-receiving layer, or the curing temperature of the resist material. An insufficiently cured resist film may have a shape different from a desired shape at the time of processing. As a result, the top surface shapes of the EL layer and the light-receiving layer each become a polygon with rounded corners, an ellipse, a circle, or the like, in some cases. For example, when a resist mask with a square top surface shape is intended to be formed, a resist mask with a circular top surface shape may be formed, and the EL layer and the light-receiving layer each have a circular top surface shape in some cases.

To obtain a desired top surface shapes of the EL layer and the light-receiving layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The pixels 110 illustrated in FIG. 21D to FIG. 21F employ matrix arrangement.

A display portion of a display apparatus employing the pixel layout illustrated in FIG. 21D to FIG. 21F includes a first arrangement where the subpixel 110a and the subpixel 110b are alternately arranged repeatedly in the row direction and a second arrangement where the subpixel 110c and the subpixel 110d are alternately arranged repeatedly in the row direction. Furthermore, the first arrangement and the second arrangement are repeated in this order in the column direction.

The display portion includes a third arrangement where the subpixel 110a and the subpixel 110c are alternately arranged repeatedly in the column direction and a fourth arrangement where the subpixel 110b and the subpixel 110d are alternately arranged repeatedly in the column direction. Furthermore, the third arrangement and the fourth arrangement are alternately repeated in the column direction.

FIG. 21D illustrates an example where each subpixel has a square top surface shape, FIG. 21E illustrates an example where each subpixel has a substantially square top surface shape with rounded corners, and FIG. 21F illustrates an example where each subpixel has a circular top surface shape.

FIG. 21G illustrates an example where one the pixel 110 is composed of two rows and three columns. The pixel 110 includes three subpixels (the subpixel 110a, the subpixel 110b, and the subpixel 110c) in the upper row (first row) and one subpixel (the subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

As illustrated in FIG. 21G, the subpixels may have different sizes. FIG. 21G illustrates a structure where the subpixel 110d is larger than the subpixel 110a to the subpixel 110c. FIG. 21H illustrates a structure where the subpixel 110b and the subpixel 110c are larger than the subpixel 110a, and the subpixel 110a is larger than the subpixel 110d. The pixel 110 illustrated in FIG. 21H includes two subpixels (the subpixels 110a and 110d) in the left column (first column), the subpixel 110b in the center column (second column), and the subpixel 110c in the right column (third column).

A display portion of a display apparatus employing the pixel layout illustrated in FIG. 21G includes a first arrangement where the subpixel 110a, the subpixel 110b, and the subpixel 110c are repeatedly arranged in this order in the row direction and a second arrangement where the subpixel 110d is repeatedly arranged in the row direction. Furthermore, the first arrangement and the second arrangement are alternately repeated in the column direction.

The display portion includes a third arrangement where the subpixel 110a and the subpixel 110d are alternately arranged repeatedly in the column direction, a fourth arrangement where the subpixel 110b and the subpixel 110d are alternately arranged repeatedly in the column direction, and a fifth arrangement where the subpixel 110c and the subpixel 110d are alternately arranged repeatedly in the column direction. Furthermore, the third arrangement, the fourth arrangement, and the fifth arrangement are repeated in this order in the row direction.

A display portion of a display apparatus employing the pixel layout illustrated in FIG. 21H includes a first arrangement where the subpixel 110a, the subpixel 110b, and the subpixel 110c are repeatedly arranged in this order in the row direction and a second arrangement where the subpixel 110d, the subpixel 110b, and the subpixel 110c are repeatedly arranged in this order in the row direction. Furthermore, the first arrangement and the second arrangement are alternately repeated in the column direction.

The display portion includes a third arrangement where the subpixel 110a and the subpixel 110d are alternately arranged repeatedly in the column direction, a fourth arrangement where the subpixel 110b is repeatedly arranged in the column direction, and a fifth arrangement where the subpixel 110c is repeatedly arranged in the column direction. Furthermore, the third arrangement, the fourth arrangement, and the fifth arrangement are repeated in this order in the row direction.

FIG. 21I illustrates an example where one pixel 110 is composed of two rows and three columns. The pixel 110 includes the subpixel 110a, the subpixel 110b, the subpixel 110c, and three subpixels 110d. The pixel 110 includes three subpixels (the subpixels 110a, 110b, and 110c) in the upper row (first row) and three subpixels (the three subpixels 110d) in the lower row (second row). In other words, the pixel 110 includes two subpixels (the subpixels 110a and 110d) in the left column (first column), two subpixels (the subpixels 110b and 110d) in the center column (second column), and two subpixels (the subpixels 110c and 110d) in the right column (third column).

A display portion of a display apparatus employing the pixel layout illustrated in FIG. 211 includes a first arrangement where the subpixel 110a, the subpixel 110b, and the subpixel 110c are repeatedly arranged in this order in the row direction and a second arrangement where the subpixel 110d is repeatedly arranged in the row direction. Furthermore, the first arrangement and the second arrangement are alternately repeated in the column direction.

The display portion includes a third arrangement where the subpixel 110a and the subpixel 110d are alternately arranged repeatedly in the column direction, a fourth arrangement where the subpixel 110b and the subpixel 110d are alternately arranged repeatedly in the column direction, and a fifth arrangement where the subpixel 110c and the subpixel 110d are alternately arranged repeatedly in the column direction. Furthermore, the third arrangement, the fourth arrangement, and the fifth arrangement are repeated in this order in the row direction.

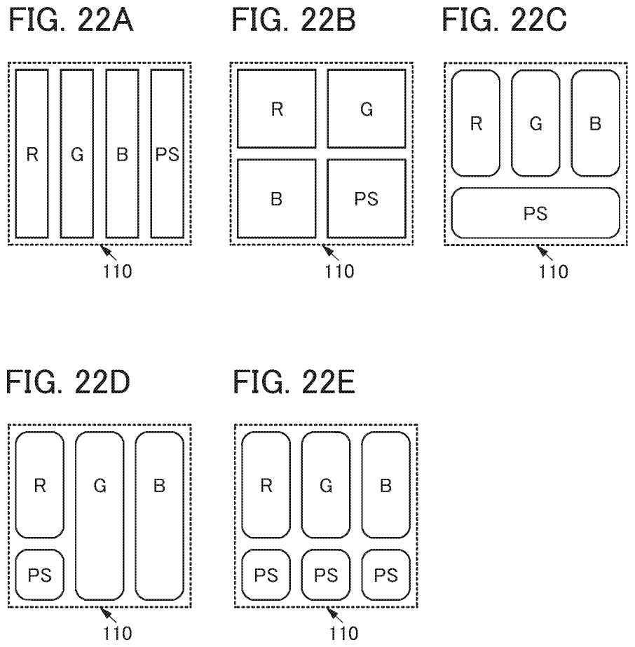

The pixels 110 illustrated in FIG. 21A to 21I are each composed of four subpixels: the subpixel 110a, the subpixel 110b, the subpixel 110c, and the subpixel 110d. The subpixels 110a, 110b, 110c, and 110d each include a light-emitting device emitting light in a different wavelength range or a light-receiving device. For example, as illustrated in FIG. 22A to FIG. 22E, the subpixel 110a can be a subpixel R having a function of emitting red light, the subpixel 110b can be a subpixel G having a function of emitting green light, the subpixel 110c can be a subpixel B having a function of emitting blue light, and the subpixel 110d can be a subpixel PS having a light-receiving function.

A pixel portion employing the pixel layout illustrated in FIG. 22A includes a first arrangement where the subpixel R, the subpixel G, the subpixel B, and the subpixel PS are repeatedly arranged in this order in the row direction. Furthermore, the first arrangement is repeated in the column direction.

The display portion includes a second arrangement where the subpixel R is repeatedly arranged in the column direction, a third arrangement where the subpixel G is repeatedly arranged in the column direction, a fourth arrangement where the subpixel B is repeatedly arranged in the column direction, and a fifth arrangement where the subpixel PS is repeatedly arranged in the column direction. Furthermore, the second arrangement, the third arrangement, the fourth arrangement, and the fifth arrangement are repeated in this order in the row direction.

A display portion of a display apparatus employing the pixel layout illustrated in FIG. 22B includes a first arrangement where the subpixel R and the subpixel G are alternately arranged repeatedly in the row direction and a second arrangement where the subpixel B and the subpixel PS are alternately arranged repeatedly in the row direction. Furthermore, the first arrangement and the second arrangement are repeated in this order in the column direction.

The display portion includes a third arrangement where the subpixel R and the subpixel B are alternately arranged repeatedly in the column direction and a fourth arrangement where the subpixel G and the subpixel PS are alternately arranged repeatedly in the column direction. Furthermore, the third arrangement and the fourth arrangement are alternately repeated in the row direction.

A display portion of a display apparatus employing the pixel layout illustrated in FIG. 22C includes a first arrangement where the subpixel R, the subpixel G, and the subpixel B are repeatedly arranged in this order in the row direction and a second arrangement where the subpixel PS is repeatedly arranged in the row direction. Furthermore, the first arrangement and the second arrangement are alternately repeated in the column direction.

The display portion includes a third arrangement where the subpixel R and the subpixel PS are alternately arranged repeatedly in the column direction, a fourth arrangement where the subpixel G and the subpixel PS are alternately arranged repeatedly in the column direction, and a fifth arrangement where the subpixel B and the subpixel PS are alternately arranged repeatedly in the column direction. Furthermore, the third arrangement, the fourth arrangement, and the fifth arrangement are repeated in this order in the row direction.

A display portion of a display apparatus employing the pixel layout illustrated in FIG. 22D includes a first arrangement where the subpixel R, the subpixel G, and the subpixel B are repeatedly arranged in this order in the row direction, and a second arrangement where the subpixel PS, the subpixel G, and the subpixel B are repeatedly arranged in this order in the row direction. Furthermore, the first arrangement and the second arrangement are alternately repeated in the column direction.

The display portion includes a third arrangement where the subpixel R and the subpixel PS are alternately arranged repeatedly in the column direction, a fourth arrangement where the subpixel G is repeatedly arranged in the column direction, and a fifth arrangement where the subpixel B is repeatedly arranged in the column direction. Furthermore, the third arrangement, the fourth arrangement, and the fifth arrangement are repeated in this order in the row direction.

A display portion of a display apparatus employing the pixel layout illustrated in FIG. 22E includes a first arrangement where the subpixel R, the subpixel G, and the subpixel B are repeatedly arranged in this order in the row direction, and a second arrangement where the subpixel PS is repeatedly arranged in the row direction. Furthermore, the first arrangement and the second arrangement are alternately repeated in the column direction.

The display portion includes a third arrangement where the subpixel R and the subpixel PS are alternately arranged repeatedly in the column direction, a fourth arrangement where the subpixel G and the subpixel PS are alternately arranged repeatedly in the column direction, and a fifth arrangement where the subpixel B and the subpixel PS are alternately arranged repeatedly in the column direction. Furthermore, the third arrangement, the fourth arrangement, and the fifth arrangement are repeated in this order in the row direction.

The light-emitting areas of the subpixel R, the subpixel G, and the subpixel B including the light-emitting devices may be the same or different from each other. For example, the light-emitting area of the subpixel including the light-emitting device can be determined depending on the lifetime of the light-emitting device. The light-emitting area of the light-emitting device with a short lifetime is preferably made larger than the light-emitting areas of the other subpixels.

FIG. 22D illustrates an example where the light-emitting areas of the subpixel G and the subpixel B are larger than the light-emitting area of the subpixel R. This structure can be suitably used in the case where the lifetimes of the light-emitting device emitting green light and the light-emitting device emitting blue light are shorter than the lifetime of the light-emitting device emitting red light. In the subpixel G and the subpixel B each having a large light-emitting area, the current densities of the light-emitting device emitting green light and the light-emitting device emitting blue light included in the subpixels are low, enabling longer lifetimes of the light-emitting devices. That is, the display apparatus can have high reliability.

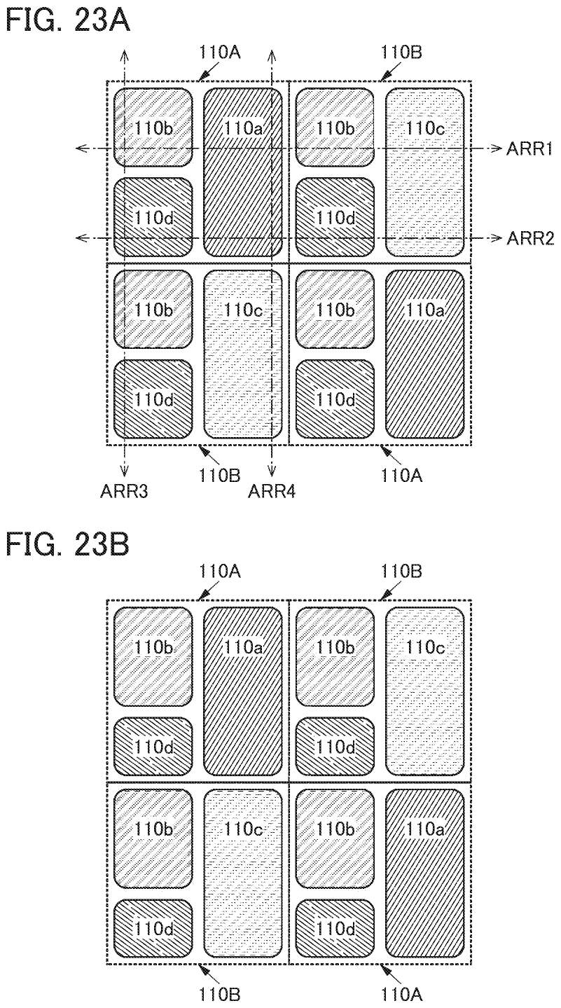

FIG. 23A and FIG. 23B illustrate pixel layout examples different from those in FIG. 21A to FIG. 21I and FIG. 22A to FIG. 22E.

FIG. 23A illustrates four pixels; in the illustrated structure, a pixel 110A and a pixel 110B that are adjacent to each other include different subpixels. The pixel 110A includes three subpixels of the subpixel 110a, the subpixel 110b, and the subpixel 110d, and the pixel 110B adjacent to the pixel 110A includes the subpixel 110b, the subpixel 110c, and the subpixel 110d. That is, the pixel 110A including the subpixel 110a and the pixel 110B not including the subpixel 110a are alternately arranged repeatedly in the column direction and the row direction. Similarly, the pixel 110A not including the subpixel 110c and the pixel 110B including the subpixel 110c are alternately arranged repeatedly in the column direction and the row direction.

The pixel 110A is composed of two rows and two columns, and includes two subpixels (the subpixels 110b and 110d) in the left column (first column) and one subpixel (the subpixel 110a) in the right column (second column). In other words, the pixel 110A includes two subpixels (the subpixels 110a and 110b) in the upper row (first row), two subpixels (the subpixels 110a and 110d) in the lower row (second row), and the subpixel 110a across these two rows.

The pixel 110B is composed of two rows and two columns, and includes two subpixels (the subpixels 110b and 110d) in the left column (first column) and one subpixel (the subpixel 110c) in the right column (second column). In other words, the pixel 110A includes two subpixels (the subpixels 110b and 110c) in the upper row (first row), two subpixels (the subpixels 110c and 110d) in the lower row (second row), and the subpixel 110c across these two rows.

The pixels illustrated in FIG. 23A have a structure where two pixels of the pixel 110A and the pixel 110B include four kinds of subpixels of the subpixel 110a, the subpixel 110b, the subpixel 110c, and the subpixel 110d. The two pixels of the pixel 110A and the pixel 110B include one subpixel 110a, two subpixels 110b, one subpixel 110c, and two subpixels 110d. Such a structure can increase the areas of the subpixels while maintaining a pseudo-high resolution, thereby lowering the required processing accuracy. That is, when comparison is made with the same processing accuracy, a display apparatus having a higher resolution can be fabricated. In addition, the number of transistors per area can be reduced, whereby the productivity can be increased. Accordingly, a display apparatus having a pseudo-high resolution can be fabricated with high productivity.

A display portion of a display apparatus employing the pixel layout illustrated in FIG. 23A includes a first arrangement ARR1 where the subpixel 110b, the subpixel 110a, the subpixel 110b, and the subpixel 110c are repeatedly arranged in this order in the row direction, and a second arrangement ARR2 where the subpixel 110d, the subpixel 110a, the subpixel 110d, and the subpixel 110c are repeatedly arranged in this order in the row direction. Furthermore, the first arrangement ARR1 and the second arrangement ARR2 are alternately repeated in the column direction.

The display portion includes a third arrangement ARR3 where the subpixel 110b and the subpixel 110d are alternately arranged repeatedly in the column direction, and a fourth arrangement ARR4 where the subpixel 110a and the subpixel 110c are alternately arranged repeatedly in the column direction. Furthermore, the third arrangement ARR3 and the fourth arrangement ARR4 are alternately repeated in the row direction.

It is preferable that the subpixel 110a have a larger area than both the subpixel 110b and the subpixel 110d in the pixel 110A, and the subpixel 110c have a larger area than both the subpixel 110b and the subpixel 110d in the pixel 110B. Furthermore, the subpixel having the largest area in the pixel 110A (here, the subpixel 110a) is preferably different from the subpixel having the largest area in the pixel 110B (here, the subpixel 110c).

Note that in this specification and the like, the light-emitting area in a subpixel including a light-emitting device is sometimes referred to as an area of the subpixel. Similarly, the light-receiving area in a subpixel including a light-receiving device is sometimes referred to as an area of the subpixel.

Although FIG. 23A illustrates the subpixel 110a and the subpixel 110c having the same area and the subpixel 110b and the subpixel 110d having the same area, one embodiment of the present invention is not limited thereto. The subpixel 110a and the subpixel 110c may have different areas. The subpixel 110b and the subpixel 110d may have different areas. FIG. 23B illustrates an example where the area of the subpixel 110b is larger than the area of the subpixel 110d. Note that between the pixel 110A and the pixel 110B, the area of the subpixel 110b may be different or the area of the subpixel 110d may be different.

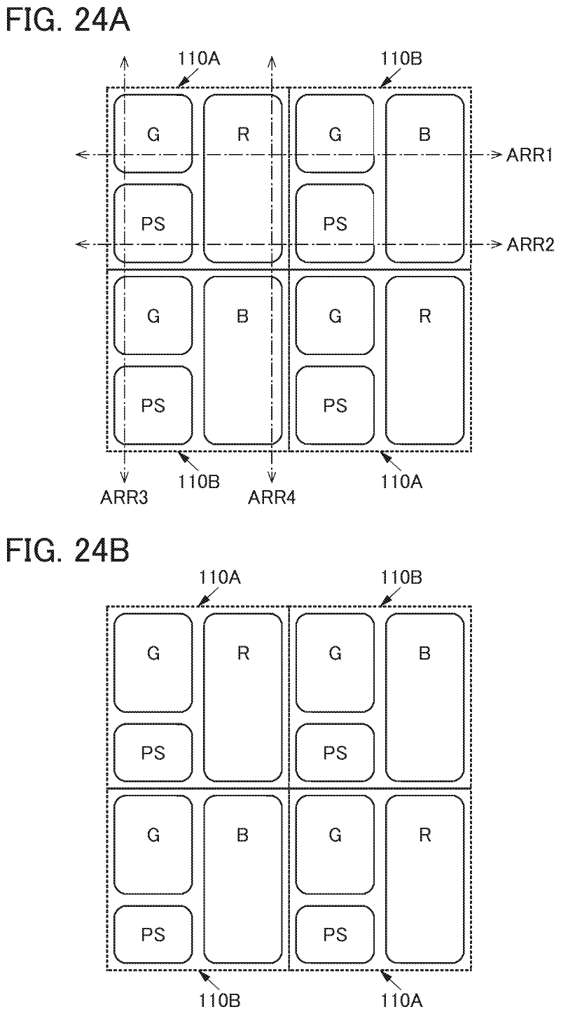

It is preferable that the subpixel 110a, the subpixel 110b, and the subpixel 110c include light-emitting devices emitting light in different wavelength ranges, and the subpixel 110d include a light-receiving device. For example, as illustrated in FIG. 24A and FIG. 24B, the subpixel 110a can be the subpixel R having a function of emitting red light, the subpixel 110b can be the subpixel G having a function of emitting green light, the subpixel 110c can be the subpixel B having a function of emitting blue light, and the subpixel 110d can be the subpixel PS having a light-receiving function.

Among the light-emitting devices of three color of red (R), green (G), and blue (B), light-emitting devices of two colors can form one pixel. The light-receiving device can be provided in any of the pixels. FIG. 24A and FIG. 24B each illustrate a structure where the pixel 110A includes the subpixel R having a function of emitting red light, the subpixel G having a function of emitting green light, and the subpixel PS having a light-receiving function, and the pixel 110B includes the subpixel B having a function of emitting blue light, the subpixel G having a function of emitting green light, and the subpixel PS having a light-receiving function.

A display portion of a display apparatus employing the pixel layout illustrated in FIG. 24A and FIG. 24B includes the first arrangement ARR1 where the subpixel G, the subpixel R, the subpixel G, and the subpixel B are repeatedly arranged in this order in the row direction, and the second arrangement ARR2 where the subpixel PS, the subpixel R, the subpixel PS, and the subpixel B are repeatedly arranged in this order in the row direction. Furthermore, the first arrangement ARR1 and the second arrangement ARR2 are alternately repeated in the column direction.

The display portion includes the third arrangement ARR3 where the subpixel G and the subpixel PS are alternately arranged repeatedly in the column direction, and the fourth arrangement ARR4 where the subpixel R and the subpixel B are alternately arranged repeatedly in the column direction. Furthermore, the third arrangement ARR3 and the fourth arrangement ARR4 are alternately repeated in the row direction.

Although FIG. 24A and FIG. 24B each illustrate an example where both the pixel 110A and the pixel 110B are provided with the subpixel PS including the light-receiving device, one embodiment of the present invention is not limited thereto. In the case where the light-receiving function does not need high accuracy, a pixel not including the subpixel PS may be provided. That is, a structure may be employed where a pixel including the subpixel PS and a pixel not including the subpixel PS are provided.

As illustrated in FIG. 24A and FIG. 24B, the area of the subpixel G having a function of emitting green light is preferably smaller than the areas of both the subpixel R having a function of emitting red light and the subpixel B having a function of emitting blue light. The luminous efficiency function of human with respect to green is higher than that with respect to red and blue; thus, when the area of the subpixel G is smaller than the areas of the subpixel R and the subpixel B, a display apparatus with high visibility and a good balance of red (R), green (G), and blue (B) can be obtained.

Although FIG. 24A and FIG. 24B each illustrate a structure where the area of the subpixel G is smaller than the areas of the subpixel R and the subpixel B, one embodiment of the present invention is not limited thereto. For example, a structure may be employed where the area of the subpixel R is smaller than the areas of the subpixel G and the subpixel B. Note that as described above, the areas of the subpixels including the light-emitting devices may be determined depending on the lifetimes of the light-emitting devices of different colors.

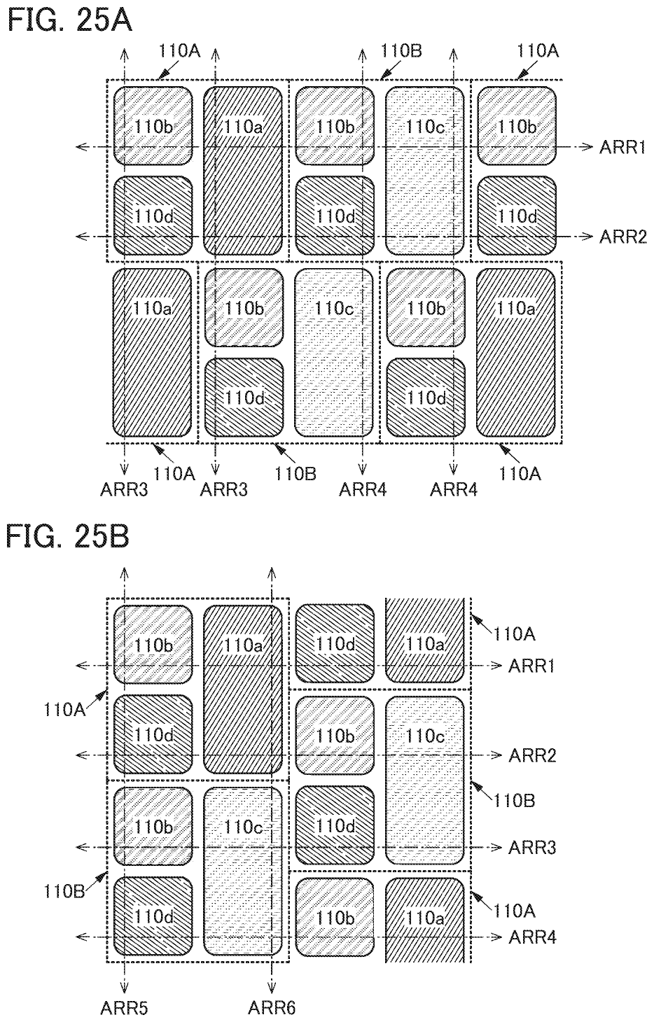

FIG. 25A and FIG. 25B illustrate modification examples of FIG. 23A.

A display portion of a display apparatus employing the pixel layout illustrated in FIG. 25A includes the first arrangement ARR1 where the subpixel 110b, the subpixel 110a, the subpixel 110b, and the subpixel 110c are repeatedly arranged in this order in the row direction, and the second arrangement ARR2 where the subpixel 110d, the subpixel 110a, the subpixel 110d, and the subpixel 110c are repeatedly arranged in this order in the row direction. Furthermore, the first arrangement ARR1 and the second arrangement ARR2 are alternately repeated in the column direction.

The display portion includes the third arrangement ARR3 where the subpixel 110b, the subpixel 110d, and the subpixel 110a are repeatedly arranged in this order in the column direction, and the fourth arrangement ARR4 where the subpixel 110b, the subpixel 110d, and the subpixel 110c are repeatedly arranged in this order in the column direction. Furthermore, the third arrangement ARR3, the third arrangement ARR3, the fourth arrangement ARR4, and the fourth arrangement ARR4 are repeated in this order in the row direction.

A display portion of a display apparatus employing the pixel layout illustrated in FIG. 25B includes the first arrangement ARR1 where the subpixel 110b, the subpixel 110a, the subpixel 110d, and the subpixel 110a are repeatedly arranged in this order in the row direction, the second arrangement ARR2 where the subpixel 110d, the subpixel 110a, the subpixel 110b, and the subpixel 110c are repeatedly arranged in this order in the row direction, the third arrangement ARR3 where the subpixel 110b, the subpixel 110c, the subpixel 110d, and the subpixel 110c are repeatedly arranged in this order in the row direction, and the fourth arrangement ARR4 where the subpixel 110d, the subpixel 110c, the subpixel 110b, and the subpixel 110a are repeatedly arranged in this order in the row direction. Furthermore, the first arrangement ARR1, the second arrangement ARR2, the third arrangement ARR3, and the fourth arrangement ARR4 are repeated in this order in the column direction.

The display portion includes a fifth arrangement ARR5 where the subpixel 110b and the subpixel 110d are alternately arranged repeatedly in the column direction, and a sixth arrangement ARR6 where the subpixel 110a and the subpixel 110c are alternately arranged repeatedly in the column direction. Furthermore, the fifth arrangement ARR5 and the sixth arrangement ARR6 are alternately repeated in the row direction.

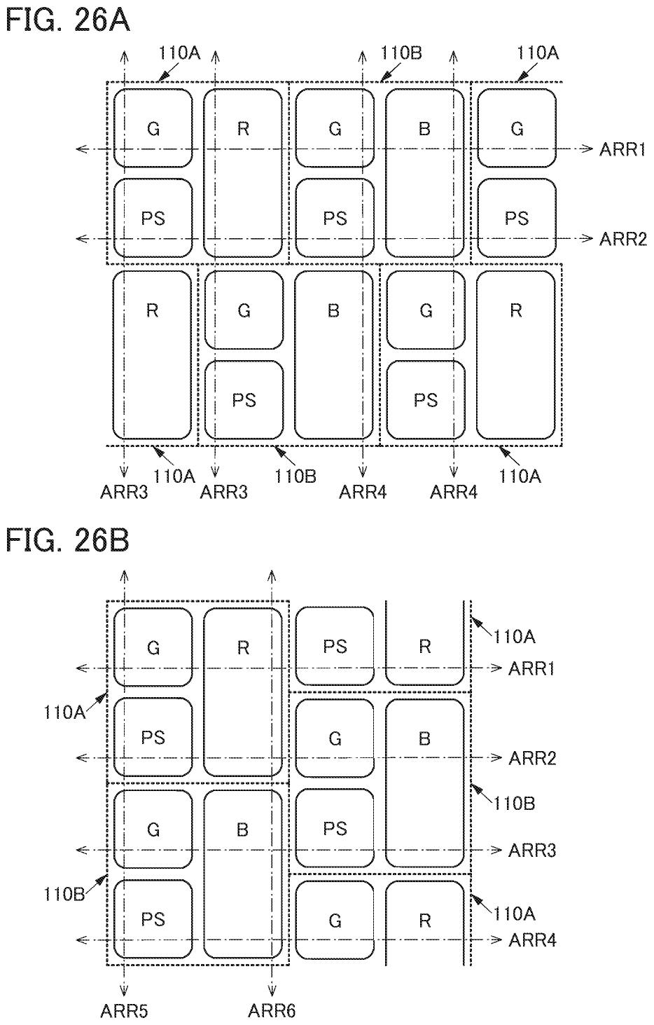

FIG. 26A and FIG. 26B illustrate structure examples where the subpixel R having a function of emitting red light is used as the subpixel 110a, the subpixel G having a function of emitting green light is used as the subpixel 110b, the subpixel B having a function of emitting blue light is used as the subpixel 110c, and the subpixel PS having a light-receiving function is used as the subpixel 110d in FIG. 25A and FIG. 25B.

A display portion of a display apparatus employing the pixel layout illustrated in FIG. 26A includes the first arrangement ARR1 where the subpixel G, the subpixel R, the subpixel G, and the subpixel B are repeatedly arranged in this order in the row direction, and the second arrangement ARR2 where the subpixel PS, the subpixel R, the subpixel PS, and the subpixel B are repeatedly arranged in this order in the row direction. Furthermore, the first arrangement ARR1 and the second arrangement ARR2 are alternately repeated.

The display portion includes the third arrangement ARR3 where the subpixel G, the subpixel PS, and the subpixel R are repeatedly arranged in this order in the column direction, and the fourth arrangement ARR4 where the subpixel G, the subpixel PS, and the subpixel B are repeatedly arranged in this order in the column direction. Furthermore, the third arrangement ARR3, the third arrangement ARR3, the fourth arrangement ARR4, and the fourth arrangement ARR4 are repeated in this order in the row direction.

A display portion of a display apparatus employing the pixel layout illustrated in FIG. 26B includes the first arrangement ARR1 where the subpixel G, the subpixel R, the subpixel PS, and the subpixel R are repeatedly arranged in this order in the row direction, the second arrangement ARR2 where the subpixel PS, the subpixel R, the subpixel G, and the subpixel B are repeatedly arranged in this order in the row direction, the third arrangement ARR3 where the subpixel G, the subpixel B, the subpixel PS, and the subpixel B are repeatedly arranged in this order in the row direction, and the fourth arrangement ARR4 where the subpixel PS, the subpixel B, the subpixel G, and the subpixel R are repeatedly arranged in this order in the row direction. Furthermore, the first arrangement ARR1, the second arrangement ARR2, the third arrangement ARR3, and the fourth arrangement ARR4 are repeated in this order.

The display portion includes the fifth arrangement ARR5 where the subpixel G and the subpixel PS are alternately arranged repeatedly in the column direction, and the sixth arrangement ARR6 where the subpixel R and the subpixel B are alternately arranged repeatedly in the column direction. Furthermore, the fifth arrangement ARR5 and the sixth arrangement ARR6 are alternately repeated in the row direction.

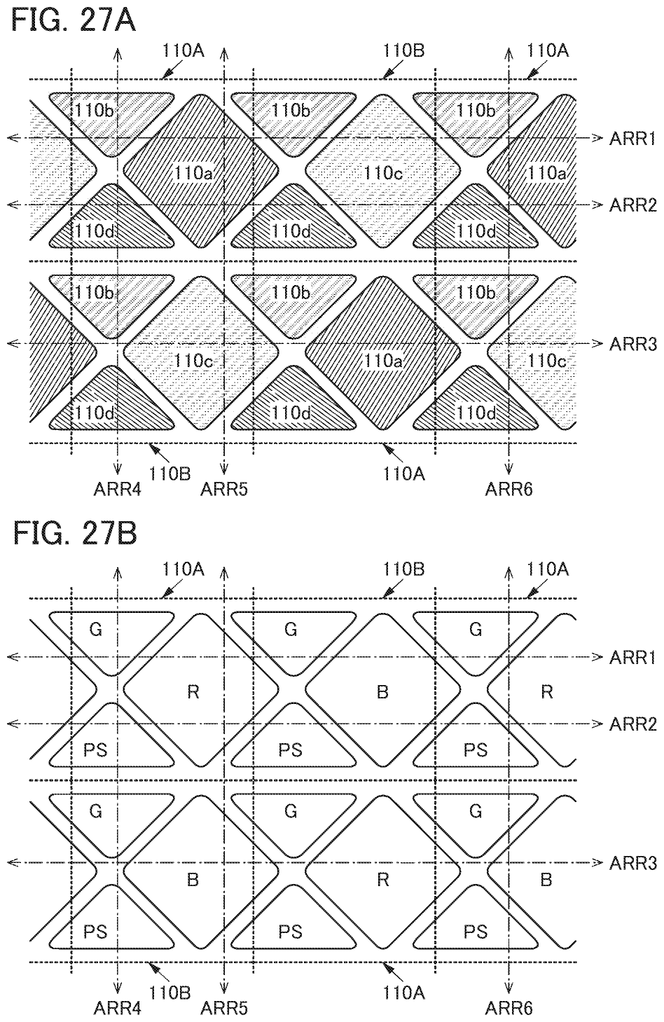

FIG. 27A illustrates a variation example of FIG. 26A. The structure illustrated in FIG. 27A is different from the structure illustrated in FIG. 26A mainly in the top surface shapes of the subpixels.

A display portion of a display apparatus employing the pixel layout illustrated in FIG. 27A includes the first arrangement ARR1 where the subpixel 110b, the subpixel 110a, the subpixel 110b, and the subpixel 110c are repeatedly arranged in this order in the row direction, and the second arrangement ARR2 where the subpixel 110d, the subpixel 110a, the subpixel 110d, and the subpixel 110c are repeatedly arranged in this order in the row direction. Furthermore, the first arrangement ARR1 and the second arrangement ARR2 are alternately repeated in the column direction. The display portion may further include the third arrangement ARR3 where the subpixel 110a and the subpixel 110c are alternately arranged repeatedly in the row direction.

The display portion includes the fourth arrangement ARR4 where the subpixel 110b and the subpixel 110d are alternately arranged repeatedly in the column direction, and the fifth arrangement ARR5 where the subpixel 110a and the subpixel 110c are alternately arranged repeatedly in the column direction. Furthermore, the fourth arrangement ARR4 and the fifth arrangement ARR5 are alternately repeated in the row direction. The display portion may further include the sixth arrangement ARR6 where the subpixel 110b, the subpixel 110a, the subpixel 110d, the subpixel 110b, the subpixel 110c, and the subpixel 110d are repeatedly arranged in this order in the column direction.

Although FIG. 27A illustrates a structure where the top surface shapes of the subpixel 110a and the subpixel 110c are quadrangles with rounded corners and the top surface shapes of the subpixel 110b and the subpixel 110d are triangles with rounded corners, there is no particular limitation on the top surface shapes of the subpixels. For example, the top surface shapes of the subpixel 110b and the subpixel 110d may be quadrangles with rounded corners or may be circles. In addition, the top surface shape may differ among the subpixels.

FIG. 27B illustrates a structure example where the subpixel R having a function of emitting red light is used as the subpixel 110a, the subpixel G having a function of emitting green light is used as the subpixel 110b, the subpixel B having a function of emitting blue light is used as the subpixel 110c, and the subpixel PS having a light-receiving function is used as the subpixel 110d in FIG. 27A.

A display portion of a display apparatus employing the pixel layout illustrated in FIG. 27B includes the first arrangement ARR1 where the subpixel G, the subpixel R, the subpixel G, and the subpixel B are repeatedly arranged in this order in the row direction, and the second arrangement ARR2 where the subpixel PS, the subpixel R, the subpixel PS, and the subpixel B are repeatedly arranged in this order in the row direction. The display portion may include the third arrangement ARR3 where the subpixel R and the subpixel B are alternately arranged repeatedly in the row direction.

The display portion includes the fourth arrangement ARR4 where the subpixel G, the subpixel R, the subpixel PS, the subpixel G, the subpixel B, and the subpixel PS are repeatedly arranged in this order in the column direction. The display portion may include the fifth arrangement ARR5 where the subpixel R and the subpixel B are alternately arranged repeatedly in the column direction, and may include the sixth arrangement ARR6 where the subpixel G and the subpixel PS are alternately arranged repeatedly in the column direction.

### <Structure Example 2 of Display Apparatus>

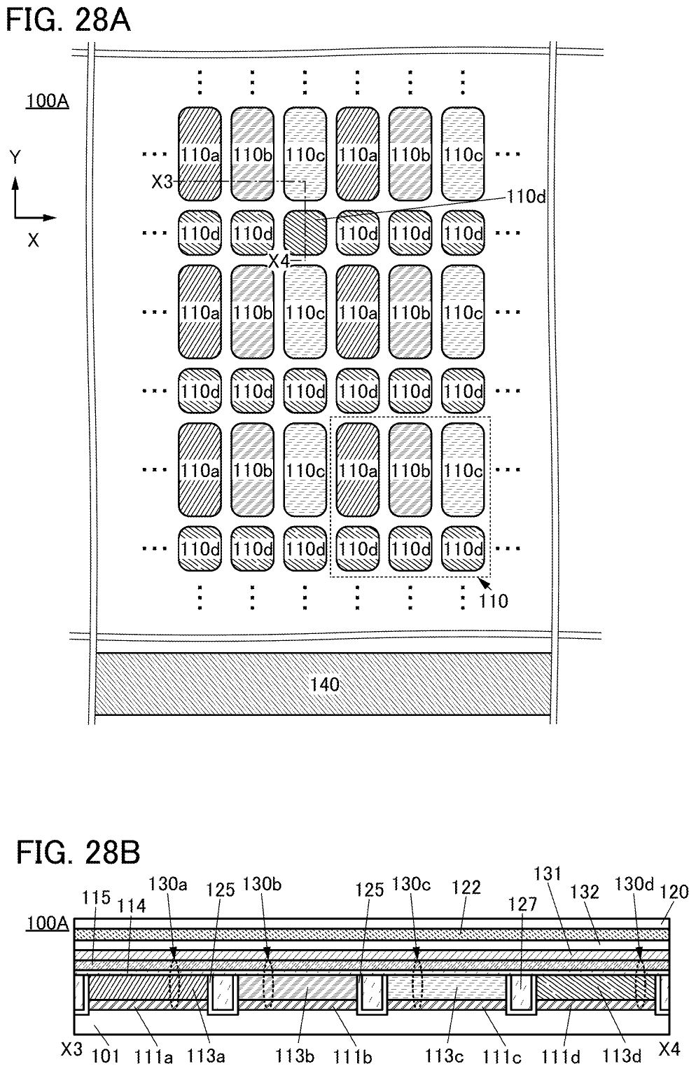

FIG. 28A and FIG. 28B illustrate a structure example different from that of the display apparatus 100.

FIG. 28A is a top view of a display apparatus 100A. FIG. 28B illustrates a cross-sectional view along a dashed-dotted line X3-X4 in FIG. 28A. The display apparatus 100A is an example where the arrangement of the pixel 110 illustrated in FIG. 21I is employed.

### <Fabrication Method Example of Display Apparatus>

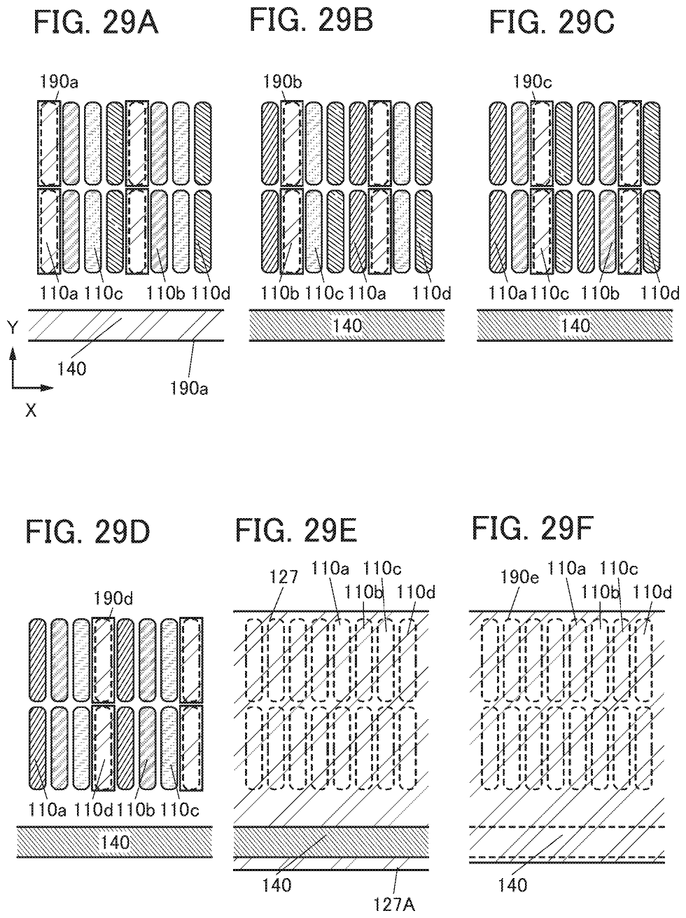

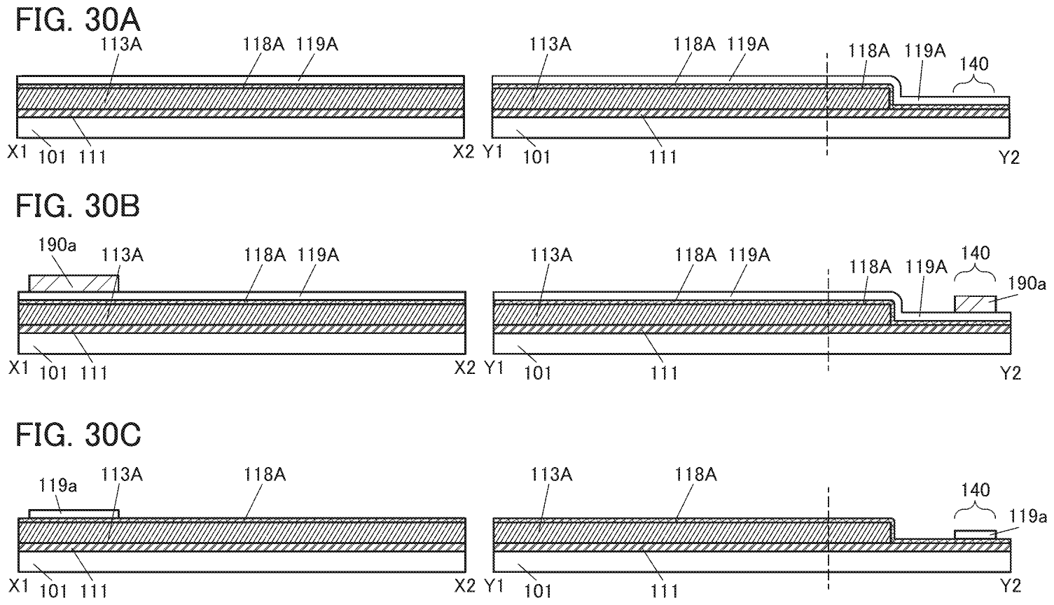

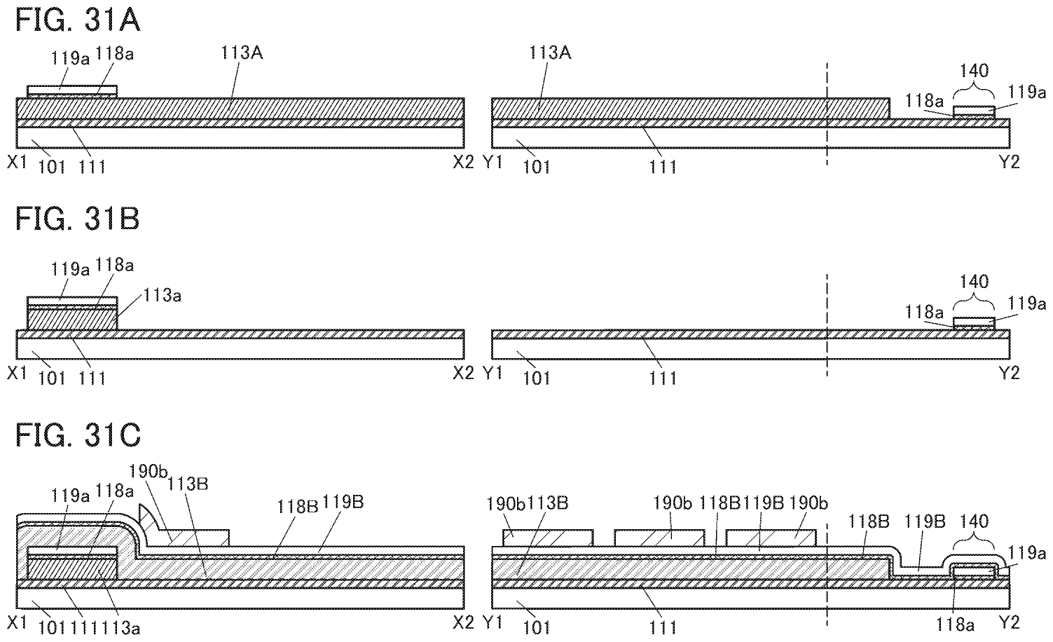

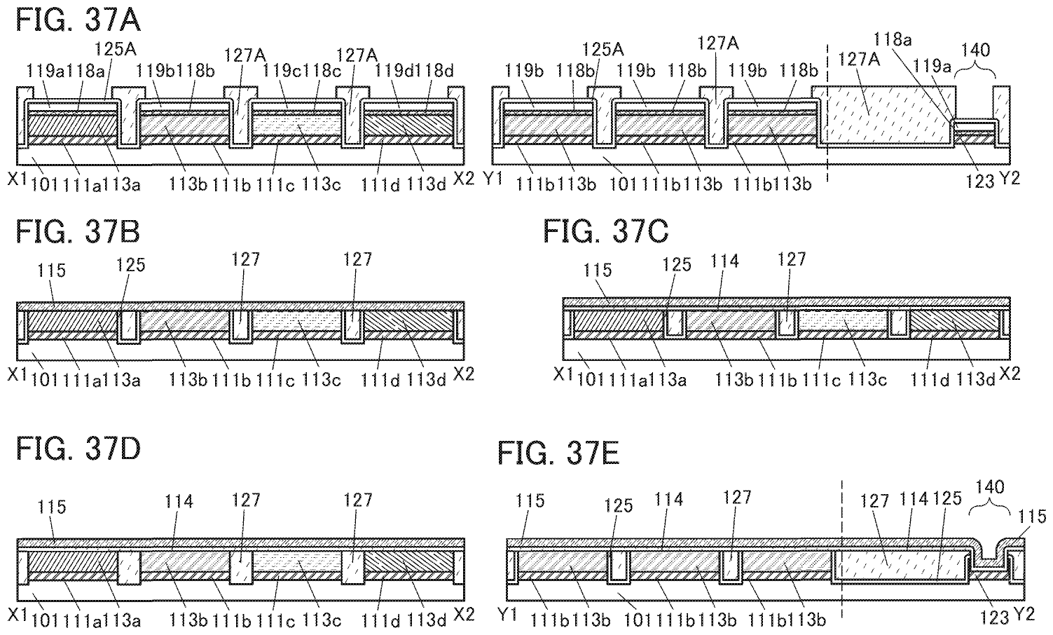

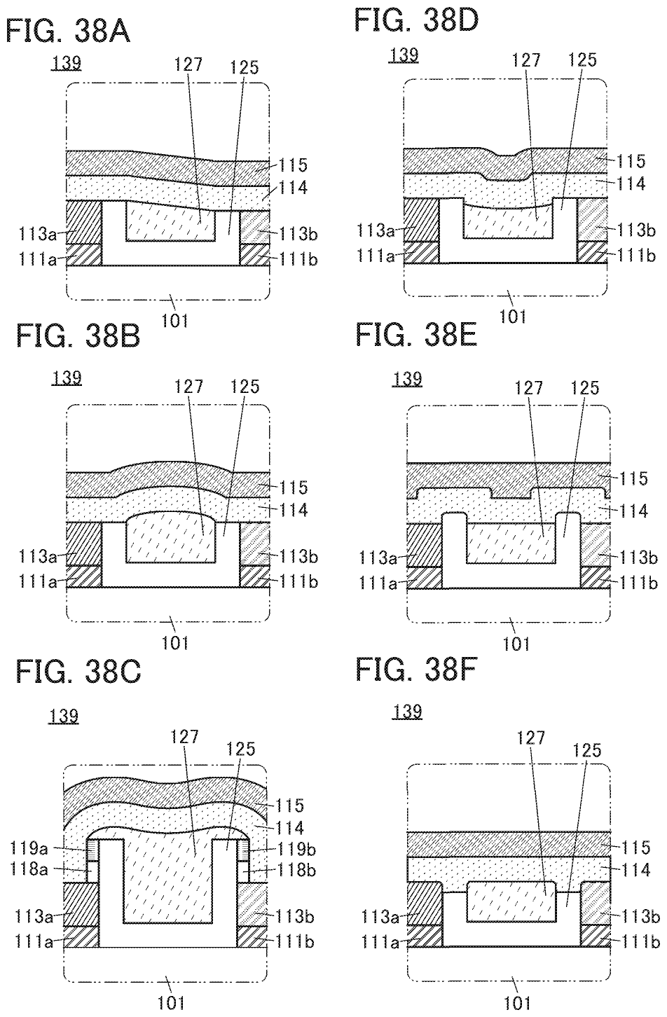

Next, a fabrication method example of a display apparatus is described with reference to FIG. 29 to FIG. 38. FIG. 29A to FIG. 29F are top views illustrating the fabrication method of the display apparatus 100 illustrated in FIG. 20A and FIG. 20B. FIG. 30A to FIG. 30C each illustrate a cross section along the dashed-dotted line X1-X2 and a cross section along the dashed-dotted line Y1-Y2 in FIG. 20A side by side. FIG. 31 to FIG. 36 and FIG. 37A are similar to FIG. 30. FIG. 37B to FIG. 37D are cross-sectional views taken along the dashed-dotted line X1-X2 in FIG. 20A. FIG. 37E is a cross-sectional view taken along the dashed-dotted line Y1-Y2 in FIG. 20A. FIG. 38A to FIG. 38F are enlarged views each illustrating a cross-sectional structure of and around the insulating layer 127.

Thin films included in the display apparatus (insulating films, semiconductor films, conductive films, and the like) can be formed by a sputtering method, a chemical vapor deposition (CVD) method, a vacuum evaporation method, a pulsed laser deposition (PLD) method, an ALD method, or the like. Examples of the CVD method include a plasma-enhanced chemical vapor deposition (PECVD: Plasma Enhanced CVD) method and a thermal CVD method. An example of a thermal CVD method is a metal organic chemical vapor deposition (MOCVD: Metal Organic CVD) method.

The thin films included in the display apparatus (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

Specifically, for fabrication of the light-emitting device, a vacuum process such as an evaporation method and a solution process such as a spin coating method or an inkjet method can be used. Examples of an evaporation method include physical vapor deposition methods (PVD method) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a light-emitting layer, an electron-transport layer, and an electron-injection layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an inkjet method, a screen printing (stencil) method, an offset printing (planography) method, a flexography (relief printing) method, a gravure printing method, or a micro-contact printing method), or the like.

The thin films included in the display apparatus can be processed by a photolithography method or the like. Alternatively, the thin films may be processed by a nanoimprinting method, a sandblasting method, a lift-off method, or the like. Alternatively, island-shaped thin films may be directly formed by a deposition method using a shielding mask such as a metal mask.

There are the following two typical examples of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

For light used for light exposure in a photolithography method, for example, it is possible to use light with the i-line (wavelength: 365 nm), light with the g-line (wavelength: 436 nm), light with the h-line (wavelength: 405 nm), or combined light of any of them. Alternatively, ultraviolet light, KrF laser light, ArF laser light, or the like can be used. Light exposure may be performed by liquid immersion exposure technique. As the light for the light exposure, extreme ultraviolet (EUV) light or X-rays may be used. Furthermore, instead of light used for the light exposure, an electron beam can also be used. It is preferable to use extreme ultraviolet light, X-rays, or an electron beam because extremely minute processing can be performed. Note that a photomask is not needed when light exposure is performed by scanning with a beam such as an electron beam.

For etching of the thin film, a dry etching method, a wet etching method, a sandblast method, or the like can be used.

First, as illustrated in FIG. 30A, a conductive film 111 is formed over the layer 101 including transistors.

Then, a first layer 113A is formed over the conductive film 111, a first sacrificial layer 118A is formed over the first layer 113A, and a second sacrificial layer 119A is formed over the first sacrificial layer 118A.

As illustrated in FIG. 30A, an end portion of the first layer 113A on the connection portion 140 side is positioned on the inner side of an end portion of the first sacrificial layer 118A in the cross-sectional view along Y1-Y2. For example, by using a mask for specifying a deposition area (also referred to as an area mask or a rough metal mask to be distinguished from a fine metal mask), the first layer 113A can be formed in a region different from those of the first sacrificial layer 118A and the second sacrificial layer 119A. In one embodiment of the present invention, the light-emitting device is formed using a resist mask; by combining a resist mask and an area mask as described above, the light-emitting device can be fabricated through a relatively simple process.

The conductive film 111 is a layer that is processed later to be the pixel electrodes 111a, 111b, and 111c and a conductive layer 123. Therefore, the conductive film 111 can employ the above-described structure applicable to the pixel electrode. For formation of the conductive film 111, a sputtering method or a vacuum evaporation method can be used, for example.

The first layer 113A is a layer to be the EL layer 113a later. Thus, the above structure applicable to the EL layer 113a can be employed. The first layer 113A can be formed by a method such as an evaporation method (including a vacuum evaporation method), a transfer method, a printing method, an inkjet method, or a coating method. The first layer 113A is preferably formed by an evaporation method. A premix material may be used in the deposition by an evaporation method. Note that in this specification and the like, a premix material is a composite material in which a plurality of materials are combined or mixed in advance.

As each of the first sacrificial layer 118A and the second sacrificial layer 119A, a film that is highly resistant to the process conditions for the first layer 113A, a second layer 113B, a third layer 113C, and the like formed in later steps, specifically, a film that has high etching selectivity with respect to the EL layers, is used.

The first sacrificial layer 118A and the second sacrificial layer 119A can be formed by a sputtering method, an ALD method (including a thermal ALD method and a PEALD method), a CVD method, or a vacuum evaporation method, for example. The first sacrificial layer 118A, which is formed over and in contact with the EL layer, is preferably formed by a formation method that causes less damage to the EL layer than a formation method of the second sacrificial layer 119A. For example, the first sacrificial layer 118A is preferably formed by an ALD method or a vacuum evaporation method rather than a sputtering method. The first sacrificial layer 118A and the second sacrificial layer 119A are formed at a temperature lower than the upper temperature limit of the EL layer (typically at 200° C. or lower, preferably 100° C. or lower, further preferably 80° C. or lower).

As each of the first sacrificial layer 118A and the second sacrificial layer 119A, a film that can be removed by a wet etching method is preferably used. The use of a wet etching method can reduce damage to the first layer 113A in processing of the first sacrificial layer 118A and the second sacrificial layer 119A, as compared with the case of using a dry etching method.

As the first sacrificial layer 118A, it is preferable to use a film having high etching selectivity with respect to the second sacrificial layer 119A.

In the fabrication method of a display apparatus of this embodiment, it is desirable that the layers (e.g., the hole-injection layer, the hole-transport layer, the light-emitting layer, and the electron-transport layer) included in the EL layer be not easily processed in the step of processing the sacrificial layers, and that the sacrificial layers be not easily processed in the steps of processing the layers included in the EL layer. These are preferably taken into consideration to select the materials and a processing method of the sacrificial layers and processing methods of the EL layer.

Although this embodiment shows an example where the sacrificial layer is formed to have a two-layer structure of the first sacrificial layer and the second sacrificial layer, the sacrificial layer may have a single-layer structure or a stacked-layer structure of three or more layers.

The first sacrificial layer 118A and the second sacrificial layer 119A can each be formed using an inorganic film such as a metal film, an alloy film, a metal oxide film, a semiconductor film, or an inorganic insulating film, for example.

For the first sacrificial layer 118A and the second sacrificial layer 119A, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used. It is particularly preferable to use a low-melting-point material such as aluminum or silver. The use of a metal material capable of blocking ultraviolet light for one or both of the first sacrificial layer 118A and the second sacrificial layer 119A is preferable, in which case irradiation of the EL layer with ultraviolet light can be inhibited and deterioration of the EL layer can be inhibited.

For the first sacrificial layer 118A and the second sacrificial layer 119A, a metal oxide such as In—Ga—Zn oxide can be used. As the first sacrificial layer 118A and the second sacrificial layer 119A, an In—Ga—Zn oxide film can be formed by a sputtering method, for example. It is also possible to use indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, indium tin oxide containing silicon or the like can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium. Specifically, M is preferably one or more kinds selected from gallium, aluminum, and yttrium.

As the first sacrificial layer 118A and the second sacrificial layer 119A, a variety of inorganic insulating films that can be used as the protective layers 131 and 132 can be used. In particular, an oxide insulating film is preferable because its adhesion to the EL layer is higher than that of a nitride insulating film. For example, an inorganic insulating material such as aluminum oxide, hafnium oxide, or silicon oxide can be used for the first sacrificial layer 118A and the second sacrificial layer 119A. As the first sacrificial layer 118A or the second sacrificial layer 119A, an aluminum oxide film can be formed by an ALD method, for example. The use of an ALD method is preferable, in which case damage to a base (especially, the EL layer or the like) can be reduced.

For example, an inorganic insulating film (e.g., an aluminum oxide film) formed by an ALD method can be used as the first sacrificial layer 118A, and an In—Ga—Zn oxide film formed by a sputtering method can be used as the second sacrificial layer 119A. Alternatively, an aluminum film or a tungsten film may be used as the second sacrificial layer 119A.

A material that can be dissolved in a solvent that is chemically stable with respect to at least a film positioned in the uppermost portion of the first layer 113A may be used for the first sacrificial layer 118A and the second sacrificial layer 119A. Specifically, a material that will be dissolved in water or alcohol can be suitably used for the first sacrificial layer 118A or the second sacrificial layer 119A. In depositing such a material, it is preferable to perform application of the material dissolved in a solvent such as water or alcohol by a wet process, and then perform heat treatment for evaporating the solvent. At this time, the heat treatment is preferably performed in a reduced-pressure atmosphere, in which case the solvent can be removed at a low temperature in a short time and thermal damage to the EL layer can be reduced accordingly.

The first sacrificial layer 118A and the second sacrificial layer 119A may be formed by a wet process such as spin coating, dipping, spray coating, ink-jetting, dispensing, screen printing, offset printing, a doctor knife method, slit coating, roll coating, curtain coating, or knife coating.

For the first sacrificial layer 118A and the second sacrificial layer 119A, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Next, a resist mask 190a is formed over the second sacrificial layer 119A as illustrated in FIG. 30B. The resist mask can be formed by application of a photosensitive resin (photoresist), light exposure, and development.

The resist mask may be formed using either a positive resist material or a negative resist material.

As illustrated in FIG. 29A, the resist mask 190a is provided at a position overlapping with a region to be the subpixel 110a later. One island-shaped pattern is preferably provided for one subpixel 110a as the resist mask 190a. Alternatively, one band-like pattern for a plurality of subpixels 110a aligned in one column (aligned in the Y direction in FIG. 29A) may be formed as the resist mask 190a.

Note that the resist mask 190a is preferably provided also at a position overlapping with a region to be the connection portion 140 later (see FIG. 29A and FIG. 30B). This can inhibit a region of the conductive film 111, which is to be the conductive layer 123 later, from being damaged during the fabrication process of the display apparatus.

Then, as illustrated in FIG. 30C, part of the second sacrificial layer 119A is removed using the resist mask 190a, so that the second sacrificial layer 119a is formed. The second sacrificial layer 119a remains in the region to be the subpixel 110a later and the region to be the connection portion 140 later.

In etching the second sacrificial layer 119A, an etching condition with high selectivity is preferably employed so that the first sacrificial layer 118A is not removed by the etching. Since the EL layer is not exposed in processing the second sacrificial layer 119A, the range of choices of the processing method is wider than that for processing the first sacrificial layer 118A. Specifically, deterioration of the EL layer can be further inhibited even when a gas containing oxygen is used as an etching gas in processing the second sacrificial layer 119A.

After that, the resist mask 190a is removed. The resist mask 190a can be removed by ashing using oxygen plasma, for example. Alternatively, the resist mask 190a may be removed by wet etching. At this time, the first sacrificial layer 118A is positioned on the outermost surface and the first layer 113A is not exposed; thus, the first layer 113A can be inhibited from being damaged in the step of removing the resist mask 190a. In addition, the range of choices of the method for removing the resist mask 190a can be widened.

Next, as illustrated in FIG. 31A, part of the first sacrificial layer 118A is removed using the second sacrificial layer 119a as a hard mask, so that a first sacrificial layer 118a is formed.

The first sacrificial layer 118A and the second sacrificial layer 119A can each be processed by a wet etching method or a dry etching method. The first sacrificial layer 118A and the second sacrificial layer 119A are preferably processed by anisotropic etching.

The use of a wet etching method can reduce damage to the first layer 113A in processing the first sacrificial layer 118A and the second sacrificial layer 119A, as compared with the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, a chemical solution containing a mixed solution thereof, or the like, for example.

In the case of using a dry etching method, deterioration of the first layer 113A can be inhibited by not using a gas containing oxygen as the etching gas. In the case of using a dry etching method, it is preferable to use CF₄, C₄F₈, SF₆, CHF₃, Cl₂, H₂O, BCl₃, or a gas containing a noble gas (also referred to as rare gas) such as He as the etching gas, for example.

For example, when an aluminum oxide film formed by an ALD method is used as the first sacrificial layer 118A, the first sacrificial layer 118A can be processed by a dry etching method using CHF₃ and He. In the case where an In—Ga—Zn oxide film formed by a sputtering method is used as the second sacrificial layer 119A, the second sacrificial layer 119A can be processed by a wet etching method using a diluted phosphoric acid.

Subsequently, as illustrated in FIG. 31B, part of the first layer 113A is removed using the second sacrificial layer 119a and the first sacrificial layer 118a as hard masks, whereby the EL layer 113a is formed.

Thus, as illustrated in FIG. 31B, a stacked-layer structure of the EL layer 113a, the first sacrificial layer 118a, and the second sacrificial layer 119a remains over the conductive film 111 in a region corresponding to the subpixel 110a. In a region corresponding to the connection portion 140, a stacked-layer structure of the first sacrificial layer 118a and the second sacrificial layer 119a remains over the conductive film 111.

Through the above process, regions of the first layer 113A, the first sacrificial layer 118A, and the second sacrificial layer 119A, which do not overlap with the resist mask 190a, can be removed.

Note that part of the first layer 113A may be removed using the resist mask 190a. After that, the resist mask 190a may be removed.

Alternatively, the next step may be performed without removing the resist mask 190a. In this case, not only the sacrificial layers but also the resist mask can be used as a mask in processing the conductive film 111 in a later step. Using the resist masks 190a, 190b, and 190c for processing the conductive film 111 sometimes makes it easier to process the conductive film 111 than the case of using only the sacrificial layers as hard masks. For example, it is possible to expand the range of choices of the processing conditions of the conductive film 111, the materials of the sacrificial layers, the materials of the conductive films, and the like.

The first layer 113A is preferably processed by anisotropic etching. Anisotropic dry etching is particularly preferable. Alternatively, wet etching may be used.

In the case of using a dry etching method, deterioration of the first layer 113A can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Thus, damage to the first layer 113A can be inhibited. Furthermore, a defect such as attachment of a reaction product generated at the etching can be inhibited.

In the case of using a dry etching method, it is preferable to use a gas containing at least one of Hz, CF₄, C₄Fs, SF₆, CHF₃, Cl₂, H₂O, BCl₃, and a noble gas such as He or Ar as the etching gas, for example. Alternatively, a gas containing oxygen and at least one of the above are preferably used as the etching gas. Alternatively, an oxygen gas may be used as the etching gas. Specifically, for example, a gas containing Hz and Ar or a gas containing CF₄ and He can be used as the etching gas. As another example, a gas containing CF₄, He, and oxygen can be used as the etching gas.

Next, as illustrated in FIG. 31C, the second layer 113B is formed over the second sacrificial layer 119a and the conductive film 111, the first sacrificial layer 118B is formed over the second layer 113B, and the second sacrificial layer 119B is formed over the first sacrificial layer 118B.

As illustrated in FIG. 31C, an end portion of the second layer 113B on the connection portion 140 side is positioned on the inner side of an end portion of the first sacrificial layer 118B in the cross-sectional view along Y1-Y2.

The second layer 113B is a layer to be the EL layer 113b later. The EL layer 113b emits light in a wavelength range different from that of light from the EL layer 113a. Structures, materials, and the like that can be used for the EL layer 113b are similar to those of the EL layer 113a. The second layer 113B can be formed by a method similar to that for the first layer 113A.

The first sacrificial layer 118B can be formed using a material that can be used for the first sacrificial layer 118A. The second sacrificial layer 119B can be formed using a material that can be used for the second sacrificial layer 119A.

Next, a resist mask 190b is formed over the second sacrificial layer 119B as illustrated in FIG. 31C.

As illustrated in FIG. 29B, the resist mask 190b is provided at a position overlapping with a region to be the subpixel 110b later. One island-shaped pattern is preferably provided for one subpixel 110b as the resist mask 190b. Alternatively, one band-like pattern for a plurality of subpixels 110b aligned in one column may be formed as the resist mask 190b.

The resist mask 190b may be provided also at a position overlapping with the region to be the connection portion 140 later.

Next, part of the second sacrificial layer 119B is removed using the resist mask 190b, so that a second sacrificial layer 119b is formed. The second sacrificial layer 119b remains in the region to be the subpixel 110b later.

After that, the resist mask 190b is removed. Then, part of the first sacrificial layer 118B is removed using the second sacrificial layer 119b as a hard mask, so that the first sacrificial layer 118b is formed.

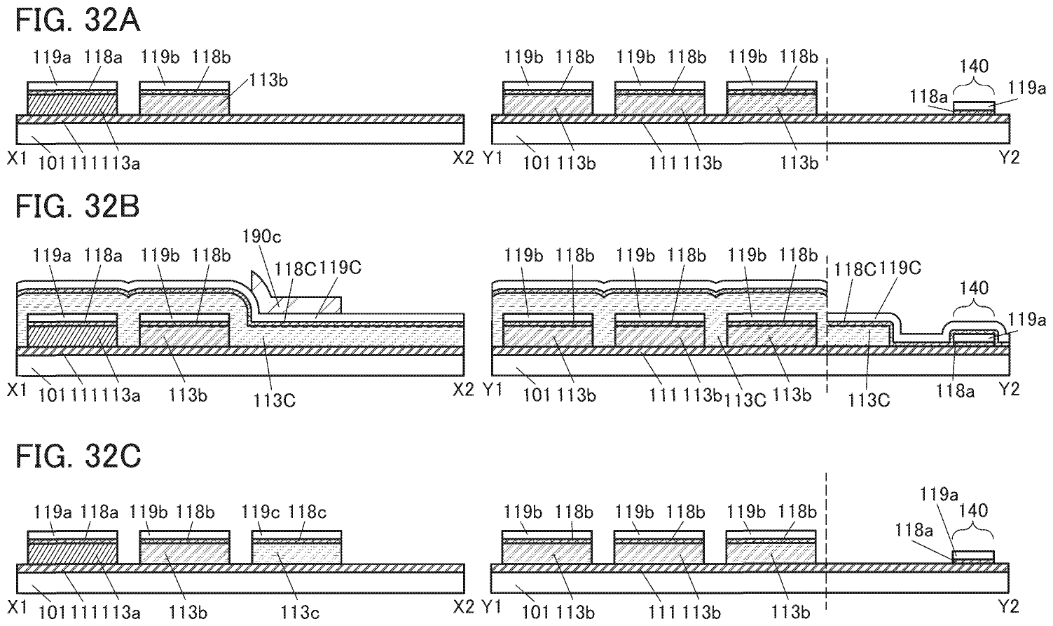

Then, as illustrated in FIG. 32A, part of the second layer 113B is removed using the second sacrificial layer 119b and the first sacrificial layer 118b as hard masks, whereby the EL layer 113b is formed.

Accordingly, as illustrated in FIG. 32A, a stacked-layer structure of the EL layer 113b, the first sacrificial layer 118b, and the second sacrificial layer 119b remains over the conductive film 111 in a region corresponding to the subpixel 110b. In the region corresponding to the connection portion 140, a stacked-layer structure of the first sacrificial layer 118a and the second sacrificial layer 119a remains over the conductive film 111.

Through the above process, regions of the second layer 113B, the first sacrificial layer 118B, and the second sacrificial layer 119B, which do not overlap with the resist mask 190b, can be removed. For processing these layers, a method that can be used for processing the first layer 113A, the first sacrificial layer 118A, and the second sacrificial layer 119A can be used.

Next, as illustrated in FIG. 32B, the third layer 113C is formed over the second sacrificial layer 119a, the second sacrificial layer 119b, and the conductive film 111, a first sacrificial layer 118C is formed over the third layer 113C, and a second sacrificial layer 119C is formed over the first sacrificial layer 118C.

As illustrated in FIG. 32B, an end portion of the third layer 113C on the connection portion 140 side is positioned on the inner side of an end portion of the first sacrificial layer 118C in the cross-sectional view along Y1-Y2.

The third layer 113C is a layer to be the EL layer 113c later. The EL layer 113c emits light in a wavelength range different from that of light from the EL layer 113a and the EL layer 113b. Structures, materials, and the like that can be used for the EL layer 113c are similar to those of the EL layer 113a. The third layer 113C can be formed by a method similar to that for the first layer 113A.

The first sacrificial layer 118C can be formed using a material that can be used for the first sacrificial layer 118A. The second sacrificial layer 119C can be formed using a material that can be used for the second sacrificial layer 119A.

Next, a resist mask 190c is formed over the second sacrificial layer 119C as illustrated in FIG. 32B.

As illustrated in FIG. 29C, the resist mask 190c is provided at a position overlapping with a region to be the subpixel 110c later. One island-shaped pattern is preferably provided for one subpixel 110c as the resist mask 190c. Alternatively, one band-like pattern for a plurality of subpixels 110c aligned in one column may be formed as the resist mask 190c.

The resist mask 190c may be provided also at a position overlapping with the region to be the connection portion 140 later.

Next, part of the second sacrificial layer 119C is removed using the resist mask 190c, so that a second sacrificial layer 119c is formed. The second sacrificial layer 119c remains in the region to be the subpixel 110c later.

After that, the resist mask 190c is removed. Then, part of the first sacrificial layer 118C is removed using the second sacrificial layer 119c as a hard mask, so that the first sacrificial layer 118c is formed.

Then, as illustrated in FIG. 32C, part of the third layer 113C is removed using the second sacrificial layer 119c and the first sacrificial layer 118c as hard masks, whereby the EL layer 113c is formed.

Accordingly, as illustrated in FIG. 32C, in a region corresponding to the subpixel 110c, a stacked-layer structure of the EL layer 113c, the first sacrificial layer 118c, and the second sacrificial layer 119c remains over the conductive film 111. In the region corresponding to the connection portion 140, a stacked-layer structure of the first sacrificial layer 118a and the second sacrificial layer 119a remains over the conductive film 111.

Through the above process, regions of the third layer 113C, the first sacrificial layer 118C, and the second sacrificial layer 119C, which do not overlap with the resist mask 190c, can be removed. For processing these layers, a method that can be used for processing the first layer 113A, the first sacrificial layer 118A, and the second sacrificial layer 119A can be used.

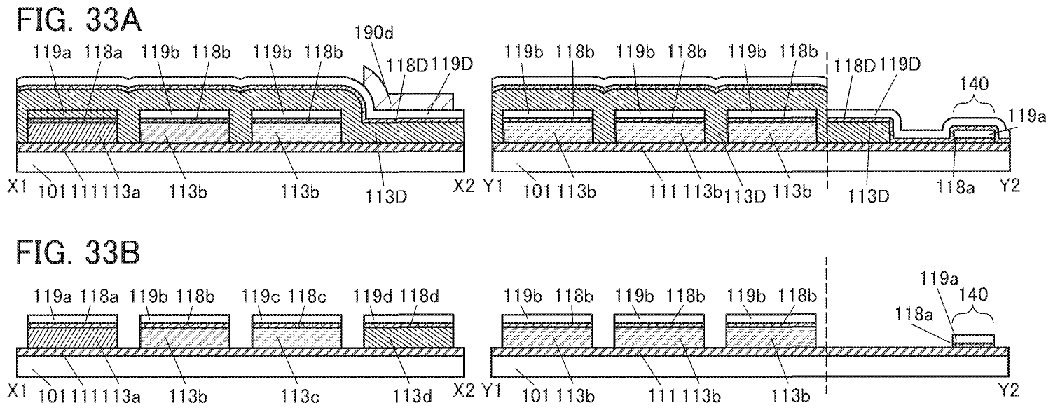

Next, as illustrated in FIG. 33A, a fourth layer 113D is formed over the second sacrificial layer 119a, the second sacrificial layer 119b, the second sacrificial layer 119c, and the conductive film 111, a first sacrificial layer 118D is formed over the fourth layer 113D, and a second sacrificial layer 119D is formed over the first sacrificial layer 118D.

As illustrated in FIG. 33A, an end portion of the fourth layer 113D on the connection portion 140 side is positioned on the inner side of an end portion of the first sacrificial layer 118D in the cross-sectional view along Y1-Y2.

The fourth layer 113D is a layer to be the light-receiving layer 113d later. The light-receiving layer 113d includes an active layer. The fourth layer 113D can be formed by a method similar to that for the first layer 113A.

The first sacrificial layer 118D can be formed using a material that can be used for the first sacrificial layer 118A. The second sacrificial layer 119D can be formed using a material that can be used for the second sacrificial layer 119A.

Next, a resist mask 190d is formed over the second sacrificial layer 119D as illustrated in FIG. 33A.

As illustrated in FIG. 29D, the resist mask 190d is provided at a position overlapping with a region to be the subpixel 110d later. One island-shaped pattern is preferably provided for one subpixel 110d as the resist mask 190d. Alternatively, one band-like pattern for a plurality of subpixels 110d aligned in one column may be formed as the resist mask 190d.

The resist mask 190d may be provided also at a position overlapping with the region to be the connection portion 140 later.

Next, part of the second sacrificial layer 119D is removed using the resist mask 190d, so that a second sacrificial layer 119d is formed. The second sacrificial layer 119d remains in the region to be the subpixel 110d later.

After that, the resist mask 190d is removed. Then, part of the first sacrificial layer 118D is removed using the second sacrificial layer 119d as a hard mask, so that a first sacrificial layer 118d is formed.

Then, as illustrated in FIG. 33B, part of the fourth layer 113D is removed using the second sacrificial layer 119d and the first sacrificial layer 118d as hard masks, whereby the light-receiving layer 113d is formed.

Accordingly, as illustrated in FIG. 33B, a stacked-layer structure of the light-receiving layer 113d, the first sacrificial layer 118d, and the second sacrificial layer 119d remains over the conductive film 111 in a region corresponding to the subpixel 110d. In the region corresponding to the connection portion 140, a stacked-layer structure of the first sacrificial layer 118a and the second sacrificial layer 119a remains over the conductive film 111.

Through the above process, regions of the fourth layer 113D, the first sacrificial layer 118D, and the second sacrificial layer 119D, which do not overlap with the resist mask 190d, can be removed. For processing these layers, a method that can be used for processing the first layer 113A, the first sacrificial layer 118A, and the second sacrificial layer 119A can be used.

Note that the side surfaces of the EL layer 113a, the EL layer 113b, the EL layer 113c, and the light-receiving layer 113d are preferably perpendicular or substantially perpendicular to their formation surfaces. For example, the angle between the formation surface and the side surface is preferably greater than or equal to 60° and less than or equal to 90°.

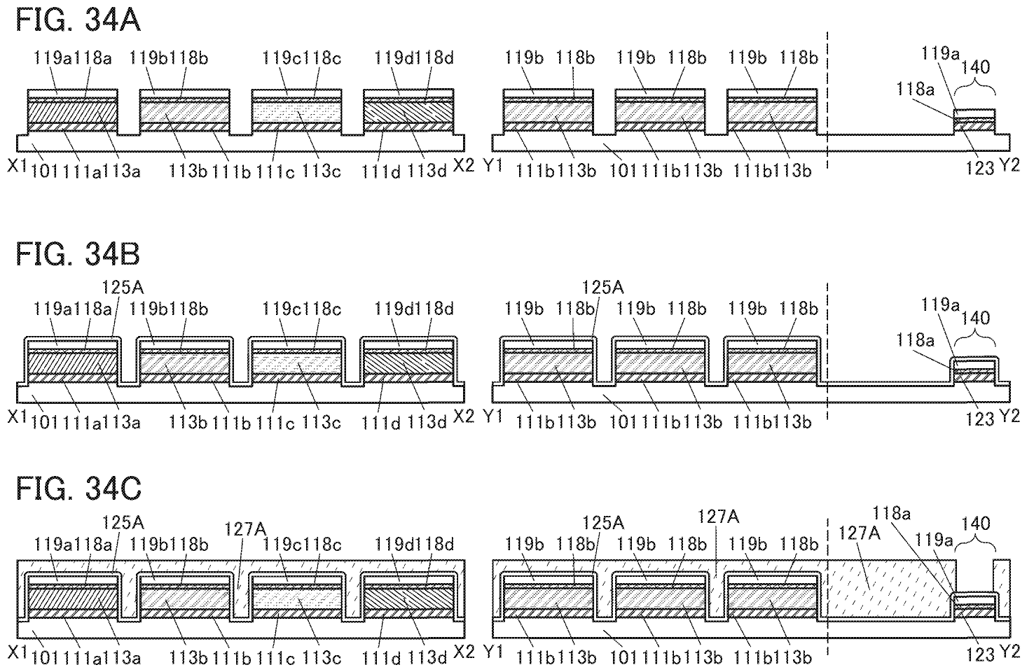

Next, as illustrated in FIG. 34A, the conductive film 111 is processed using the first sacrificial layer 118a, the first sacrificial layer 118b, the first sacrificial layer 118c, the first sacrificial layer 118d, the second sacrificial layer 119a, the second sacrificial layer 119b, the second sacrificial layer 119c, and the second sacrificial layer 119d as hard masks, whereby the pixel electrode 111a, the pixel electrode 111b, the pixel electrode 111c, the pixel electrode 111d, and the conductive layer 123 are formed.

In processing the conductive film 111, part of the layer 101 including transistors (specifically, an insulating layer positioned on the outermost surface) is processed to form a depressed portion in some cases. Although the description below is made using the case where a depressed portion is provided in the layer 101 including transistors as an example, the depressed portion is not necessarily provided.

Here, in order to form the conductive layer 123, any one of the first sacrificial layer 118a, the first sacrificial layer 118b, the first sacrificial layer 118c, and the first sacrificial layer 118d and any one of the second sacrificial layer 119a, the second sacrificial layer 119b, the second sacrificial layer 119c, and the second sacrificial layer 119d are preferably provided in the connection portion 140. Any two or all of the first sacrificial layer 118a, the first sacrificial layer 118b, the first sacrificial layer 118c, and the first sacrificial layer 118d and any two or all of the second sacrificial layer 119a, the second sacrificial layer 119b, the second sacrificial layer 119c, and the second sacrificial layer 119d may be provided in the connection portion 140. Provision of the sacrificial layer in the connection portion 140 can inhibit a region of the conductive film 111, which is to be the conductive layer 123 later, from being damaged during the fabrication process of the display apparatus. Thus, the first sacrificial layer 118a and the second sacrificial layer 119a, which are fabricated the earliest in the process, are preferably formed in the connection portion 140.

For the processing of the conductive film 111, a wet etching method or a dry etching method can be used. The conductive film 111 is preferably processed by anisotropic etching.

Next, as illustrated in FIG. 34B, an insulating film 125A is formed to cover the pixel electrode 111a, the pixel electrode 111b, the pixel electrode 111c, the pixel electrode 111d, the EL layer 113a, the EL layer 113b, the EL layer 113c, the light-receiving layer 113d, the first sacrificial layer 118a, the first sacrificial layer 118b, the first sacrificial layer 118c, the first sacrificial layer 118d, the second sacrificial layer 119a, the second sacrificial layer 119b, the second sacrificial layer 119c, and the second sacrificial layer 119d.

As the insulating film 125A, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. Alternatively, a metal oxide film such as an indium gallium zinc oxide film may be used.

The insulating film 125A preferably has a function of a barrier insulating film against at least one of water and oxygen. Alternatively, the insulating film 125A preferably has a function of inhibiting diffusion of at least one of water and oxygen. Alternatively, the insulating film 125A preferably has a function of capturing or fixing (also referred to as gettering) at least one of water and oxygen.

Note that in this specification and the like, a barrier insulating film refers to an insulating film having a barrier property. In this specification and the like, a barrier property means a function of inhibiting diffusion of a particular substance (also referred to as having low permeability). Alternatively, a barrier property means a function of capturing or fixing (also referred to as gettering) a particular substance.

When the insulating film 125A has a function of the barrier insulating film or a gettering function, entry of impurities (typically, water or oxygen) that would diffuse into the light-emitting devices from the outside can be inhibited. With such a structure, a highly reliable display apparatus can be provided.

Next, as illustrated in FIG. 34C, an insulating film 127A is formed over the insulating film 125A.

As illustrated in FIG. 29E, the insulating film 127A is preferably formed to include an opening at a position overlapping with the conductive layer 123 (the connection portion 140). The insulating film 127A can be formed into a pattern by application of a photosensitive resin, light exposure, and development, for example.

Note that as illustrated in FIG. 37A, the insulating film 127A may be formed to include an opening also at a position overlapping with the pixel electrode 111a, the pixel electrode 111b, the pixel electrode 111c, and the pixel electrode 111d.

For the insulating film 127A, an organic material can be used. Examples of the organic material include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. For the insulating film 127A, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used. Moreover, the insulating film 127A can be formed using a photosensitive resin. A photoresist may be used for the photosensitive resin. As the photosensitive resin, a positive photosensitive material or a negative photosensitive material can be used.

There is no particular limitation on the formation method of the insulating film 127A; for example, the insulating film 127A can be formed by a wet process such as spin coating, dipping, spray coating, ink-jetting, dispensing, screen printing, offset printing, a doctor knife method, slit coating, roll coating, curtain coating, and knife coating. Specifically, the insulating film 127A is preferably formed by spin coating.

The insulating film 125A and the insulating film 127A are preferably formed by a formation method that causes less damage to the EL layer. In particular, the insulating film 125A, which is formed in contact with a side surface of the EL layer, is preferably formed by a formation method that causes less damage to the EL layer than the formation method of the insulating film 127A. The insulating film 125A and the insulating film 127A are each formed at a temperature lower than the upper temperature limit of the EL layer (typically at 200° C. or lower, preferably 100° C. or lower, further preferably 80° C. or lower). For example, an aluminum oxide film can be formed as the insulating film 125A by an ALD method. An ALD method is preferably used, in which case deposition damage is reduced and a film with good coverage can be formed.

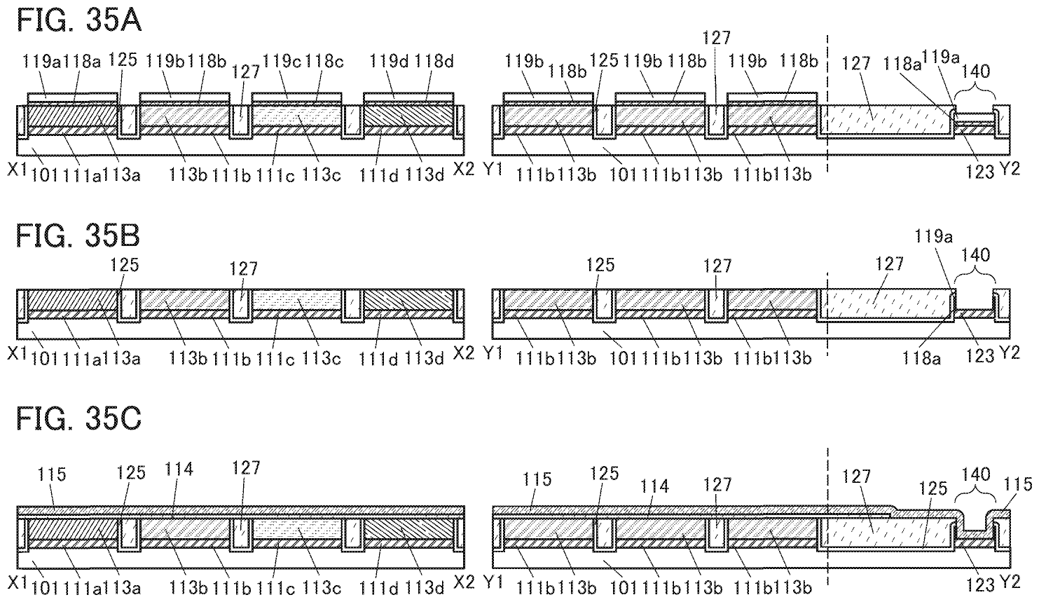

Then, as illustrated in FIG. 35A, the insulating film 125A and the insulating film 127A are processed, whereby the insulating layer 125 and the insulating layer 127 are formed. The insulating layer 127 is formed in contact with the side surface of the insulating layer 125 and the top surface of the depressed portion. The insulating layer 125 (and the insulating layer 127) is (are) provided to cover the side surfaces of the pixel electrode 111a, the pixel electrode 111b, the pixel electrode 111c, and the pixel electrode 111d. This inhibits the pixel electrode 111a, the pixel electrode 111b, the pixel electrode 111c, and the pixel electrode 111d from being in contact with a film to be formed later (a film included in the EL layer, a film included in the light-receiving layer, or a common electrode), thereby inhibiting a short circuit in the light-emitting devices. Furthermore, the insulating layer 125 and the insulating layer 127 are preferably provided to cover the side surfaces of the EL layer 113a, the EL layer 113b, the EL layer 113c, and the light-receiving layer 113d. This inhibits the side surfaces of these layers from being in contact with a film to be formed later, thereby inhibiting a short circuit in the light-emitting devices. In addition, the EL layer 113a, the EL layer 113b, the EL layer 113c, and the light-receiving layer 113d can be inhibited from being damaged in a later step.

In particular, the depressed portion is preferably provided in part of the layer 101 including transistors (specifically, an insulating layer positioned on the outermost surface), in which case the side surfaces of the pixel electrode 111a, the pixel electrode 111b, the pixel electrode 111c, and the pixel electrode 111d can be entirely covered with the insulating layer 125 and the insulating layer 127.

The insulating film 125A is preferably processed by a dry etching method. The insulating film 125A is preferably processed by anisotropic etching. The insulating film 125A can be processed using an etching gas that can be used for processing the first sacrificial layer 118A and the second sacrificial layer 119A.

The insulating film 127A is preferably processed by ashing using oxygen plasma, for example.

Next, as illustrated in FIG. 35B, the first sacrificial layer 118a, the first sacrificial layer 118b, the first sacrificial layer 118c, the first sacrificial layer 118d, the second sacrificial layer 119a, the second sacrificial layer 119b, the second sacrificial layer 119c, and the second sacrificial layer 119d are removed. Accordingly, the EL layer 113a is exposed over the pixel electrode 111a, the EL layer 113b is exposed over the pixel electrode 111b, the EL layer 113c is exposed over the pixel electrode 111c, the light-receiving layer 113d is exposed over the pixel electrode 111d, and the conductive layer 123 is exposed in the connection portion 140. Note that part of the first sacrificial layer 118a, the first sacrificial layer 118b, the first sacrificial layer 118c, the first sacrificial layer 118d, the second sacrificial layer 119a, the second sacrificial layer 119b, the second sacrificial layer 119c, or the second sacrificial layer 119d may remain. For example, in the connection portion 140 or the like, a region of the sacrificial layer overlapping with the insulating layer 125 remains in some cases (see FIG. 35B).

The top surface level of the insulating layer 125 and the top surface level of the insulating layer 127 are each preferably equal to or substantially equal to the top surface level of at least one of the EL layer 113a, the EL layer 113b, the EL layer 113c, and the light-receiving layer 113d. The top surface of the insulating layer 127 preferably has a flat shape and may include a projected portion or a depressed portion.

The step of removing the sacrificial layers can be performed by a method similar to that for the step of processing the sacrificial layers. In particular, the use of a wet etching method can reduce damage to the EL layer 113a, the EL layer 113b, the EL layer 113c, and the light-receiving layer 113d at the time of removing the first sacrificial layer and the second sacrificial layer, as compared to the case of using a dry etching method.

The first sacrificial layer and the second sacrificial layer may be removed in different steps or the same step.

One or both of the first sacrificial layer and the second sacrificial layer may be removed by being dissolved in a solvent such as water or alcohol. Examples of alcohol include ethyl alcohol, methyl alcohol, isopropyl alcohol (IPA), and glycerin.

After the first sacrificial layer and the second sacrificial layer are removed, drying treatment may be performed to remove water included in the EL layer and water adsorbed on the surface of the EL layer. For example, heat treatment can be performed in an inert gas atmosphere or a reduced-pressure atmosphere. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, as illustrated in FIG. 35C, the layer 114 is formed to cover the insulating layers 125 and 127, the EL layer 113a, the EL layer 113b, the EL layer 113c, and the light-receiving layer 113d. As illustrated in FIG. 35C, an end portion of the layer 114 on the connection portion 140 side is positioned on the inner side of the connection portion 140 in the cross-sectional view along Y1-Y2, and the conductive layer 123 is exposed. Note that the layer 114 may be provided in the connection portion 140 depending on the level of the conductivity of the layer 114.

Materials that can be used for the layer 114 are as described above. The layer 114 can be formed by a method such as an evaporation method (including a vacuum evaporation method), a transfer method, a printing method, an inkjet method, or a coating method. The layer 114 may be formed using a premix material.

Here, in the case where the insulating layer 125 and the insulating layer 127 are not provided, any of the pixel electrode 111a, the pixel electrode 111b, the pixel electrode 111c, and the pixel electrode 111d might be in contact with the layer 114. A contact between these layers might cause a short circuit of the light-emitting devices or the light-receiving device when the layer 114 has high conductivity, for example. In the display apparatus of one embodiment of the present invention, however, the insulating layer 125 and the insulating layer 127 cover the side surfaces of the EL layer 113a, the EL layer 113b, the EL layer 113c, the light-receiving layer 113d, the pixel electrode 111a, the pixel electrode 111b, the pixel electrode 111c, and the pixel electrode 111d, which inhibits a contact between the layer 114 having high conductivity and these layers, thereby inhibiting a short circuit of the light-emitting devices. Thus, the reliability of the light-emitting devices can be increased.

Then, the common electrode 115 is formed over the layer 114 and the conductive layer 123 as illustrated in FIG. 35C.

Materials that can be used for the common electrode 115 are as described above. The common electrode 115 can be formed by a sputtering method or a vacuum evaporation method, for example. Alternatively, a film formed by an evaporation method and a film formed by a sputtering method may be stacked.

After that, the protective layer 131 is formed over the common electrode 115, and the protective layer 132 is formed over the protective layer 131. Furthermore, the substrate 120 is bonded onto the protective layer 132 with the resin layer 122, whereby the display apparatus 100 illustrated in FIG. 20B can be fabricated.

Materials and deposition methods that can be used for the protective layers 131 and 132 are as described above. Examples of the deposition method of the protective layers 131 and 132 include a vacuum evaporation method, a sputtering method, a CVD method, and an ALD method. The protective layer 131 and the protective layer 132 may be films formed by different deposition methods. The protective layers 131 and 132 may each have a single-layer structure or a stacked-layer structure.

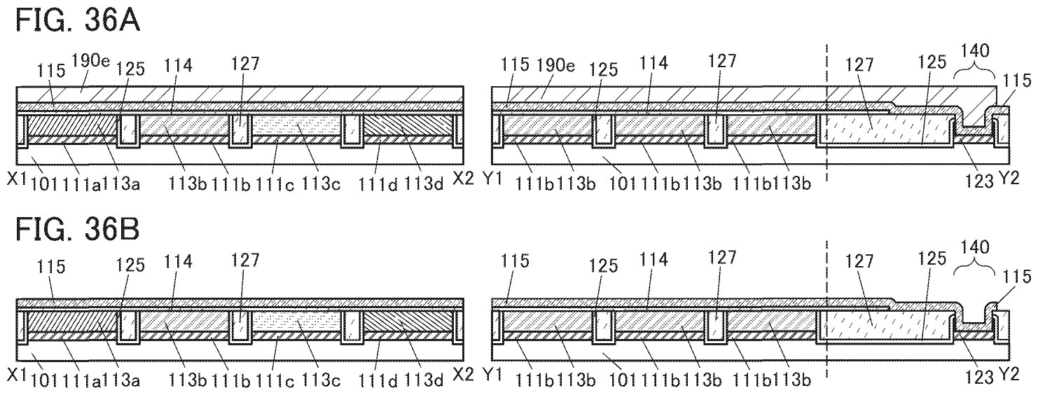

Note that a mask for specifying a deposition area (also referred to as an area mask or a rough metal mask) may be used to form the common electrode 115. Alternatively, the common electrode 115 may be formed without using the mask; the step of processing the common electrode 115 illustrated in FIG. 36A and FIG. 36B may be performed after the step illustrated in FIG. 35C, and then the step of forming the protective layer 131 may be performed.

As illustrated in FIG. 36A and FIG. 29F, a resist mask 190e is formed over the common electrode 115. An end portion on the Y2 side in FIG. 36A includes a portion where the resist mask 190e is not provided. As illustrated in FIG. 29F, the resist mask 190e is provided in a region overlapping with the subpixels and the connection portion 140. That is, the region where the resist mask 190e is not provided is positioned on the outer side of the connection portion 140.

Next, as illustrated in FIG. 36B, part of the common electrode 115 is removed using the resist mask 190e. In the above manner, the common electrode 115 can be processed.

Note that in the case where the resist mask 190e is used, processing steps of the resist mask 190a, the resist mask 190b, the resist mask 190c, the resist mask 190d, the resist mask 190e, and the insulating film 127A are performed; thus, six photomasks are used in the series of fabrication process. In the case where the resist mask 190e is not used, processing steps of the resist mask 190a, the resist mask 190b, the resist mask 190c, the resist mask 190d, and the insulating film 127A are performed; thus, five photomasks are used in the series of fabrication process, and meanwhile, a mask for specifying a deposition area is used for forming the common electrode 115. In the fabrication method of the display apparatus of one embodiment of the present invention, it is not necessary to use a metal mask with a high-resolution pattern for forming an island-shaped EL layer, a mask for forming a pixel electrode into an island-like shape, and a mask for forming an insulating layer covering an end portion of the pixel electrode, whereby the number of masks and the cost can be reduced.

As illustrated in FIG. 37B, without provision of the layer 114, the common electrode 115 may be formed to cover the insulating layers 125 and 127, the EL layer 113a, the EL layer 113b, the EL layer 113c, and the light-receiving layer 113d. That is, all layers included in the EL layers may be formed separately between the light-emitting devices emitting light of different colors. In this case, all the EL layers in the light-emitting devices are formed into island-like shapes.

Here, a short circuit in the light-emitting device might be caused when the common electrode 115 is in contact with any of the pixel electrode 111a, the pixel electrode 111b, the pixel electrode 111c, and the pixel electrode 111d. In the display apparatus of one embodiment of the present invention, however, the insulating layers 125 and 127 cover the side surfaces of the EL layer 113a, the EL layer 113b, the EL layer 113c, the light-receiving layer 113d, the pixel electrode 111a, the pixel electrode 111b, the pixel electrode 111c, and the pixel electrode 111d, which inhibits the common electrode 115 from being in contact with these layers, thereby inhibiting a short circuit in the light-emitting devices or the light-receiving device. Thus, the reliability of the light-emitting devices and the light-receiving device can be increased.

As illustrated in FIG. 37C, in the case where part of the layer 101 including transistors (specifically, an insulating layer positioned on the outermost surface) is not processed in processing the conductive film 111, a depressed portion is not provided in the layer 101 including transistors in some cases.

The insulating layer 125 is not necessarily provided as illustrated in FIG. 37D. In this case, it is preferable to use, for the insulating layer 127, an organic material that causes less damage to the EL layer 113a, the EL layer 113b, the EL layer 113c, and the light-receiving layer 113d. For the insulating layer 127, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin is preferably used, for example.

Note that in the case where the layer 114 is provided in the connection portion 140, the conductive layer 123 and the common electrode 115 are electrically connected to each other with the layer 114 therebetween, as illustrated in FIG. 37E.

FIG. 38A to FIG. 38F each illustrate a cross-sectional structure of a region 139 including the insulating layer 127 and its surroundings.

FIG. 38A illustrates an example where the EL layer 113a and the EL layer 113b have different thicknesses. The top surface level of the insulating layer 125 is equal to or substantially equal to the top surface level of the EL layer 113a on the EL layer 113a side, and equal to or substantially equal to the top surface level of the EL layer 113b on the EL layer 113b side. The top surface of the insulating layer 127 has a gentle slope such that the side closer to the EL layer 113a is higher and the side closer to the EL layer 113b is lower. In this manner, the levels of the insulating layer 125 and the insulating layer 127 are preferably equal to the top surface level of an adjacent EL layer. Alternatively, the levels of the insulating layers may be equal to the top surface level of any of adjacent EL layers so that their top surfaces have a flat portion.

In FIG. 38B, the top surface of the insulating layer 127 includes a region higher in level than the top surface of the EL layer 113a and the top surface of the EL layer 113b. Moreover, the top surface of the insulating layer 127 has a convex shape that is gently bulged toward the center.

In FIG. 38C, the insulating layer 127 includes a region higher in level than the top surface of the EL layer 113a and the top surface of the EL layer 113b. In the region 139, the display apparatus 100 includes at least one of the first sacrificial layer 118a and the second sacrificial layer 119a, and includes a first region where the insulating layer 127 is higher in level than the top surface of the EL layer 113a and the top surface of the EL layer 113b and positioned on the outer side of the insulating layer 125. The first region is positioned over at least one of the first sacrificial layer 118a and the second sacrificial layer 119a. In the region 139, the display apparatus 100 includes at least one of the first sacrificial layer 118b and the second sacrificial layer 119b, and includes a second region where the insulating layer 127 is higher in level than the top surface of the EL layer 113a and the top surface of the EL layer 113b and positioned on the outer side of the insulating layer 125. The second region is positioned over at least one of the first sacrificial layer 118b and the second sacrificial layer 119b.

Note that the top surface of the insulating layer 127 may have a shape corresponding to the shape of the formation surface of the insulating layer 127 (e.g., the top surfaces of the insulating layer 125, the second sacrificial layer 119a, and the second sacrificial layer 119b). FIG. 38C illustrates an example where the top surface of the insulating layer 127 has a recessed shape in a region overlapping with the depressed portion of the insulating layer 125.

In FIG. 38D, the top surface of the insulating layer 127 includes a region lower in level than the top surface of the EL layer 113a and the top surface of the EL layer 113b. Moreover, the top surface of the insulating layer 127 has a concave shape that is gently recessed toward the center.

In FIG. 38E, the top surface of the insulating layer 125 includes a region higher in level than the top surface of the EL layer 113a and the top surface of the EL layer 113b. That is, the insulating layer 125 protrudes from the formation surface of the layer 114, and forms a projected portion.

For example, in the case where the insulating layer 125 is formed to be level with or substantially level with the sacrificial layer, a shape such that the insulating layer 125 protrudes is sometimes formed as illustrated in FIG. 38E.

In FIG. 38F, the top surface of the insulating layer 125 includes a region lower in level than the top surface of the EL layer 113a and the top surface of the EL layer 113b. That is, the insulating layer 125 forms a depressed portion on the formation surface of the layer 114.

As described above, the insulating layer 125 and the insulating layer 127 can have a variety of shapes.

As described above, in the fabrication method of the display apparatus of one embodiment of the present invention, an island-shaped EL layer is formed by processing an EL layer formed over the entire surface, not by using a fine metal mask; thus, the island-shaped EL layer can be formed to have a uniform thickness. Accordingly, a display apparatus with a high resolution or a display apparatus with a high aperture ratio can be achieved.

The first layer, the second layer, and the third layer included in the light-emitting devices of different colors are formed in separate steps. Accordingly, the EL layers can be formed to have structures (a material, thickness, and the like) appropriate for the light-emitting devices of different colors. Thus, the light-emitting devices can have favorable characteristics.

The display apparatus of one embodiment of the present invention includes an insulating layer that covers side surfaces of a pixel electrode, a light-emitting layer, and a carrier-transport layer. In the fabrication process of the display apparatus, the EL layer is processed while the light-emitting layer and the carrier-transport layer are stacked; hence, damage to the light-emitting layer is reduced in the display apparatus. In addition, the insulating layer inhibits the pixel electrode from being in contact with a carrier-injection layer or a common electrode, thereby inhibiting a short circuit in the light-emitting device.

Note that there is no particular limitation on the order of forming the light-emitting device 130a, the light-emitting device 130b, the light-emitting device 130c, and the light-receiving device 130d.

This embodiment can be combined with the other embodiments as appropriate. In the case where a plurality of structure examples are described in one embodiment in this specification, the structure examples can be combined as appropriate.

### Embodiment 3

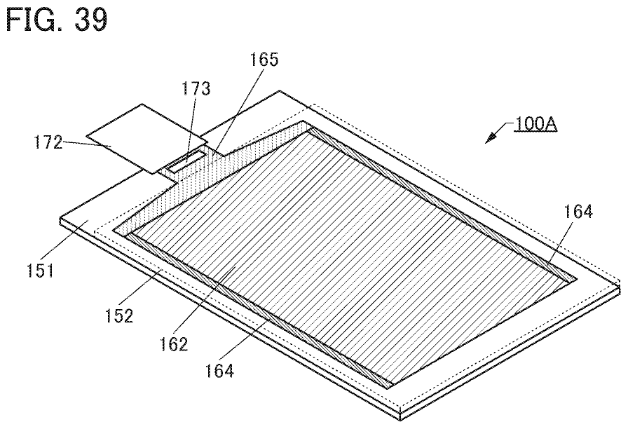

In this embodiment, a display apparatus of one embodiment of the present invention is described with reference to FIG. 39 to FIG. 41.

The display apparatus of this embodiment can be a high-definition display apparatus or large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

In this specification and the like, a display panel that is one embodiment of a display apparatus has a function of displaying (outputting) an image or the like on (to) a display surface. Therefore, the display panel is one embodiment of an output device.

In this specification and the like, a display apparatus to which a connector such as a flexible printed circuit (CPC) or a TCP (Tape Carrier Package) is attached, or a display apparatus on which an integrated circuit (IC) is mounted by a COG (Chip On Glass) method, a COF (Chip On Film) method, or the like is referred to as a display panel module, a display module, or simply a display panel or the like in some cases.

### <Display Apparatus 100A>

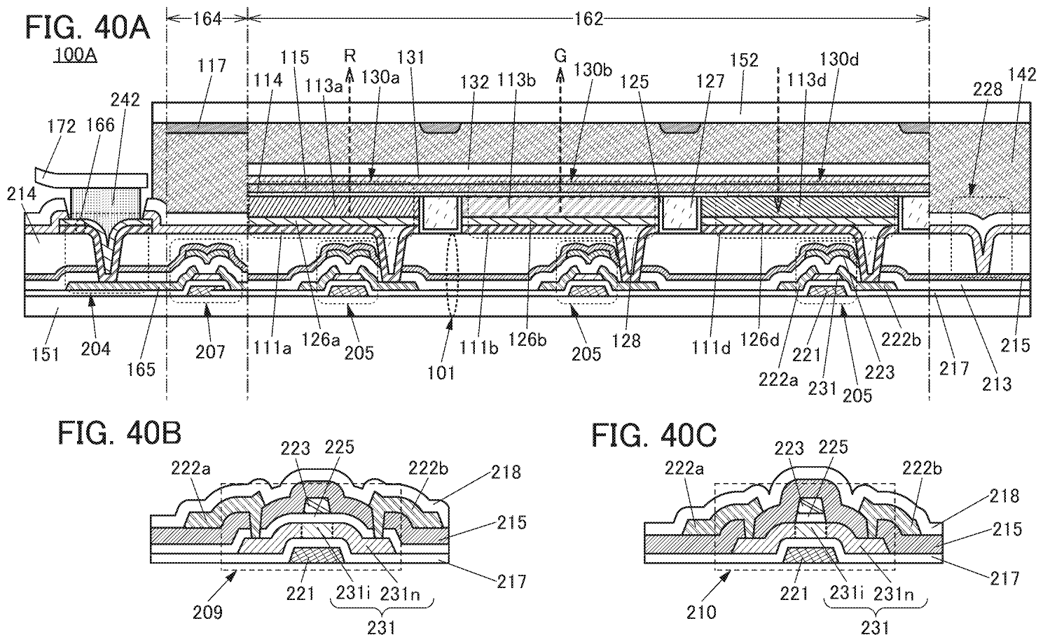

FIG. 39 shows a perspective view of the display apparatus 100A, and FIG. 40A shows a cross-sectional view of the display apparatus 100A.

The display apparatus 100A has a structure where a substrate 152 and a substrate 151 are bonded to each other. In FIG. 39, the substrate 152 is denoted by a dashed line.

The display apparatus 100A includes a display portion 162, a circuit 164, a wiring 165, and the like. FIG. 39 illustrates an example where an IC 173 and an FPC 172 are mounted on the display apparatus 100A. Thus, the structure illustrated in FIG. 39 can be regarded as a display module including the display apparatus 100A, the IC (integrated circuit), and the FPC.

As the circuit 164, for example, a scan line driver circuit can be used.

The wiring 165 has a function of supplying a signal and power to the display portion 162 and the circuit 164. The signal and power are input to the wiring 165 from the outside through the FPC 172 or input to the wiring 165 from the IC 173.

FIG. 39 illustrates an example where the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display apparatus 100A and the display module are not necessarily provided with an IC. The IC may be mounted on the FPC by a COF method or the like.

FIG. 40A illustrates an example of cross sections of part of a region including the FPC 172, part of the circuit 164, part of the display portion 162, and part of a region including an end portion of the display apparatus 100A.

The display apparatus 100A includes light-emitting devices, a light-receiving device, a transistor 207, a transistor 205, and the like between the substrate 151 and the substrate 152. FIG. 40A illustrates, as the light-emitting devices and the light-receiving device, the light-emitting device 130a emitting red light, the light-emitting device 130b emitting green light, and the light-receiving device 130d.

In the case where a pixel of the display apparatus includes three kinds of subpixels including light-emitting devices emitting different colors, the three subpixels can be subpixels of three colors of R, G, and B or subpixels of three colors of yellow (Y), cyan (C), and magenta (M). In the case where four subpixels are included, the four subpixels can be subpixels of four colors of R, G, B, and white (W) or subpixels of four colors of R, G, B, and Y.

The light-emitting device 130a and the light-emitting device 130b each include an optical adjustment layer between a pixel electrode and an EL layer, and the light-receiving device 130d includes an optical adjustment layer between a pixel electrode and a light-receiving layer. As the optical adjustment layer, the light-emitting device 130a includes a conductive layer 126a, the light-emitting device 130b includes a conductive layer 126b, and the light-receiving device 130d includes a conductive layer 126d. Embodiment 1 can be referred to for the details of the light-emitting devices and the light-receiving device. The side surfaces of the pixel electrode 111a, the pixel electrode 111b, the pixel electrode 111d, the conductive layers 126a, 126b, and 126d, the EL layer 113a, the EL layer 113b, and the light-receiving layer 113d are covered with the insulating layers 125 and 127. The layer 114 is provided over the EL layer 113a, the EL layer 113b, the light-receiving layer 113d, and the insulating layers 125 and 127, and the common electrode 115 is provided over the layer 114. The protective layer 131 is provided over the light-emitting device 130a, the light-emitting device 130b, and the light-receiving device 130d. The protective layer 132 is provided over the protective layer 131.

The protective layer 132 and the substrate 152 are bonded to each other with an adhesive layer 142. A solid sealing structure, a hollow sealing structure, or the like can be employed to seal the light-emitting devices. In FIG. 40A, a solid sealing structure is employed in which a space between the substrate 152 and the substrate 151 is filled with the adhesive layer 142. Alternatively, a hollow sealing structure where the space is filled with an inert gas (e.g., nitrogen or argon) may be employed. The adhesive layer 142 may be provided not to overlap with the light-emitting device. The space may be filled with a resin different from that of the frame-like adhesive layer 142.

The pixel electrode 111a, the pixel electrode 111b, and the pixel electrode 111d are each connected to a conductive layer 222b included in the transistor 205 through an opening provided in an insulating layer 214.

Depressed portions are formed in the pixel electrode 111a, the pixel electrode 111b, and the pixel electrode 111d to cover the openings provided in the insulating layer 214. A layer 128 is preferably embedded in the depressed portion. It is preferable that the conductive layer 126a be formed over the pixel electrode 111a and the layer 128, the conductive layer 126b be formed over the pixel electrode 111b and the layer 128, and the conductive layer 126d be formed over the pixel electrode 111d and the layer 128. The conductive layer 126a, the conductive layer 126b, and the conductive layer 126d can also be referred to as pixel electrodes.

The layer 128 has a planarization function for the depressed portions of the pixel electrode 111a, the pixel electrode 111b, and the pixel electrode 111d. Provision of the layer 128 can reduce unevenness of the formation surfaces of the EL layers and the light-receiving layer, and accordingly can improve the coverage. When the conductive layer 126a, the conductive layer 126b, and the conductive layer 126d electrically connected to the pixel electrode 111a, the pixel electrode 111b, and the pixel electrode 111d are provided over the pixel electrode 111a, the pixel electrode 111b, the pixel electrode 111d, and the layer 128, regions overlapping with the depressed portions of the pixel electrode 111a, the pixel electrode 111b, and the pixel electrode 111d can be used as the light-emitting regions in some cases. Thus, the aperture ratio of a pixel can be increased.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. As the layer 128, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 128. As the photosensitive resin, a positive photosensitive material or a negative photosensitive material can be used.

When a photosensitive resin is used, the layer 128 can be formed through only light-exposure and development steps, reducing the influence of dry etching, wet etching, or the like on the surfaces of the pixel electrode 111a, the pixel electrode 111b, and the pixel electrode 111d. When the layer 128 is formed using a negative photosensitive resin, the layer 128 can sometimes be formed using the same photomask (light-exposure mask) as the photomask used for forming the opening in the insulating layer 214.

The conductive layer 126a is provided over the pixel electrode 111a and the layer 128. The conductive layer 126a includes a first region in contact with the top surface of the pixel electrode 111a and a second region in contact with the top surface of the layer 128. The top surface level of the pixel electrode 111a in contact with the first region and the top surface level of the layer 128 in contact with the second region are preferably equal to or substantially equal to each other.

Similarly, the conductive layer 126b is provided over the pixel electrode 111b and the layer 128. The conductive layer 126b includes a first region in contact with the top surface of the pixel electrode 111b and a second region in contact with the top surface of the layer 128. The top surface level of the pixel electrode 111b in contact with the first region and the top surface level of the layer 128 in contact with the second region are preferably equal to or substantially equal to each other.

The conductive layer 126d is provided over the pixel electrode 111d and the layer 128. The conductive layer 126d includes a first region in contact with the top surface of the pixel electrode 111d and a second region in contact with the top surface of the layer 128. The top surface level of the pixel electrode 111d in contact with the first region and the top surface level of the layer 128 in contact with the second region are preferably equal to or substantially equal to each other.

The pixel electrode contains a material reflecting visible light, and a counter electrode contains a material transmitting visible light.

The display apparatus 100A is of a top emission type. Light from the light-emitting device is emitted toward the substrate 152 side. For the substrate 152, a material having a high transmitting property with respect to visible light is preferably used. For the substrate 152, a material having a high transmitting property with respect to visible light and infrared light is further preferably used. Light is incident on the light-receiving device through the substrate 152.

A stacked-layer structure from the substrate 151 to the insulating layer 214 corresponds to the substrate 23 described in Embodiment 1 or the layer 101 including transistors described in Embodiment 2 and the like.

The transistor 207 and the transistor 205 are each formed over the substrate 151. These transistors can be fabricated using the same materials through the same process.

An insulating layer 217, an insulating layer 213, an insulating layer 215, and the insulating layer 214 are provided in this order over the substrate 151. Parts of the insulating layer 217 function as gate insulating layers of the transistors. Parts of the insulating layer 213 function as gate insulating layers of the transistors. The insulating layer 215 is provided to cover the transistors. The insulating layer 214 is provided to cover the transistors and has a function of a planarization layer. Note that there is no limitation on the number of gate insulating layers and the number of insulating layers covering the transistors, and each insulating layer may be a single layer or include two or more layers.

A material through which impurities such as water and hydrogen do not easily diffuse is preferably used for at least one of the insulating layers covering the transistors. Thus, such an insulating layer can function as a barrier insulating film. Such a structure can effectively inhibit diffusion of impurities into the transistors from the outside and increase the reliability of the display apparatus.

An inorganic insulating film is preferably used as each of the insulating layer 217, the insulating layer 213, and the insulating layer 215. As the inorganic insulating film, for example, a silicon nitride film, a silicon oxynitride film, a silicon oxide film, a silicon nitride oxide film, an aluminum oxide film, or an aluminum nitride film, or the like can be used. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 214 ma have a stacked-layer structure of an organic insulating film and an inorganic insulating film. The outermost layer of the insulating layer 214 preferably functions as an etching protective film. Accordingly, a depressed portion can be inhibited from being formed in the insulating layer 214 at the time of processing the pixel electrode 111a, the conductive layer 126a, or the like. Alternatively, a depressed portion may be formed in the insulating layer 214 at the time of processing the pixel electrode 111a, the conductive layer 126a, or the like.

Here, an organic insulating film often has a lower barrier property than an inorganic insulating film. Therefore, the organic insulating film preferably has an opening in the vicinity of an end portion of the display apparatus 100A. This can inhibit entry of impurities from the end portion of the display apparatus 100A through the organic insulating film. Alternatively, the organic insulating film may be formed so that its end portion is positioned on the inner side of the end portion of the display apparatus 100A, to prevent the organic insulating film from being exposed at the end portion of the display apparatus 100A.

In a region 228 illustrated in FIG. 40A, an opening is formed in the insulating layer 214. This can inhibit entry of impurities into the display portion 162 from the outside through the insulating layer 214 even when an organic insulating film is used as the insulating layer 214. Consequently, the reliability of the display apparatus 100A can be increased.

Each of the transistor 207 and the transistors 205 includes a conductive layer 221 functioning as a gate, the insulating layer 217 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate. Here, a plurality of layers obtained by processing the same conductive film are shown with the same hatching pattern. The insulating layer 217 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The structure where the semiconductor layer where a channel is formed is interposed between two gates is used for the transistor 207 and the transistors 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor and a semiconductor having crystallinity (a microcrystalline semiconductor, a polycrystalline semiconductor, a single crystal semiconductor, or a semiconductor partly including crystal regions) may be used. It is preferable to use a semiconductor having crystallinity, in which case degradation of the transistor characteristics can be inhibited.

The semiconductor layer of the transistor preferably includes a metal oxide (also referred to as an oxide semiconductor). That is, a transistor including a metal oxide in its channel formation region (hereinafter, also referred to as an OS transistor) is preferably used for the display apparatus of this embodiment. Alternatively, the semiconductor layer of the transistor may contain silicon. Examples of silicon include amorphous silicon and crystalline silicon (e.g., low-temperature polysilicon or single crystal silicon).

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used as the semiconductor layer.

In the case where the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, in the case where the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. In the case where the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with In being 5. In the case where the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with In being 1.

The transistor included in the circuit 164 and the transistor included in the display portion 162 may have the same structure or different structures. A plurality of transistors included in the circuit 164 may have the same structure or two or more kinds of structures. Similarly, a plurality of transistors included in the display portion 162 may have the same structure or two or more kinds of structures.

FIG. 40B and FIG. 40C illustrate other structure examples of transistors.

Each of a transistor 209 and a transistor 210 includes the conductive layer 221 functioning as a gate, the insulating layer 217 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, the insulating layer 225 functioning as a gate insulating layer, the conductive layer 223 functioning as a gate, and the insulating layer 215 covering the conductive layer 223. The insulating layer 217 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 40B illustrates an example of the transistor 209 where the insulating layer 225 covers the top and side surfaces of the semiconductor layer 231. The conductive layer 222a and the conductive layer 222b are connected to the corresponding low-resistance regions 231n through openings provided in the insulating layer 225 and the insulating layer 215. One of the conductive layer 222a and the conductive layer 222b functions as a source, and the other functions as a drain.

In the transistor 210 illustrated in FIG. 40C, the insulating layer 225 overlaps with the channel formation region 231i of the semiconductor layer 231 and does not overlap with the low-resistance regions 231n. The structure illustrated in FIG. 40C can be fabricated by processing the insulating layer 225 using the conductive layer 223 as a mask, for example. In FIG. 40C, the insulating layer 215 is provided to cover the insulating layer 225 and the conductive layer 223, and the conductive layer 222a and the conductive layer 222b are connected to the corresponding low-resistance regions 231n through the openings in the insulating layer 215.

A connection portion 204 is provided in a region of the substrate 151 which does not overlap with the substrate 152. In the connection portion 204, the wiring 165 is electrically connected to the FPC 172 through a conductive layer 166 and a connection layer 242. An example is illustrated where the conductive layer 166 has a stacked-layer structure of a conductive film obtained by processing the same conductive film as the pixel electrode 111a, the pixel electrode 111b, and the pixel electrode 111d and a conductive film obtained by processing the same conductive film as the conductive layer 126a, the conductive layer 126b, and the conductive layer 126d. On the top surface of the connection portion 204, the conductive layer 166 is exposed. Thus, the connection portion 204 and the FPC 172 can be electrically connected to each other through the connection layer 242.

A light-blocking layer 117 is preferably provided on the surface of the substrate 152 on the substrate 151 side. A variety of optical members can be arranged on the outer surface of the substrate 152. Examples of the optical members include a polarizing plate, a retardation plate, a light diffusion layer (a diffusion film or the like), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 152.

The protective layer 131 and the protective layer 132 provided to cover the light-emitting device inhibit an impurity such as water from entering the light-emitting device. As a result, the reliability of the light-emitting device can be enhanced.

In the region 228 in the vicinity of the end portion of the display apparatus 100A, the insulating layer 215 and the protective layer 131 or the protective layer 132 are preferably in contact with each other through an opening in the insulating layer 214. In particular, the inorganic insulating films are preferably in contact with each other. This can inhibit entry of impurities into the display portion 162 from the outside through the organic insulating film. Consequently, the reliability of the display apparatus 100A can be increased.

For each of the substrate 151 and the substrate 152, glass, quartz, ceramics, sapphire, a resin, a metal, an alloy, a semiconductor, or the like can be used. The substrate on the side where light from the light-emitting device is extracted is formed using a material transmitting the light. When the substrate 151 and the substrate 152 are formed using a flexible material, the flexibility of the display apparatus can be increased. Furthermore, a polarizing plate may be used as the substrate 151 or the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used for one or both of the substrate 151 and the substrate 152.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

In the case where a film is used for the substrate and the film absorbs water, the shape of the display panel might be changed, e.g., creases are generated. Thus, for the substrate, a film with a low water absorption rate is preferably used. For example, the water absorption rate of the film is preferably lower than or equal to 1%, further preferably lower than or equal to 0.1%, still further preferably lower than or equal to 0.01%.

As the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-component resin may be used. An adhesive sheet or the like may be used.

As the connection layer 242, an anisotropic conductive film (ACF), an anisotropic conductive paste (ACP), or the like can be used.

As materials that can be used for a gate, a source, and a drain of a transistor and conductive layers such as a variety of wirings and electrodes included in a display apparatus, metals such as aluminum, titanium, chromium, nickel, copper, yttrium, zirconium, molybdenum, silver, tantalum, or tungsten, an alloy containing any of these metals as its main component, and the like can be given. A film containing any of these materials can be used as a single layer or a stacked-layer structure.

As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Further alternatively, a nitride of the metal material (e.g., titanium nitride) or the like may be used. Note that in the case of using the metal material or the alloy material (or the nitride thereof), the thickness is preferably set small enough to have a light-transmitting property. A stacked film of any of the above materials can be used as a conductive layer. For example, a stacked film of indium tin oxide and an alloy of silver and magnesium, or the like is preferably used because conductivity can be increased. They can also be used for conductive layers such as wirings and electrodes included in the display apparatus, and conductive layers (e.g., a conductive layer functioning as a pixel electrode or a common electrode) included in a light-emitting device.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

### <Display Apparatus 100B>

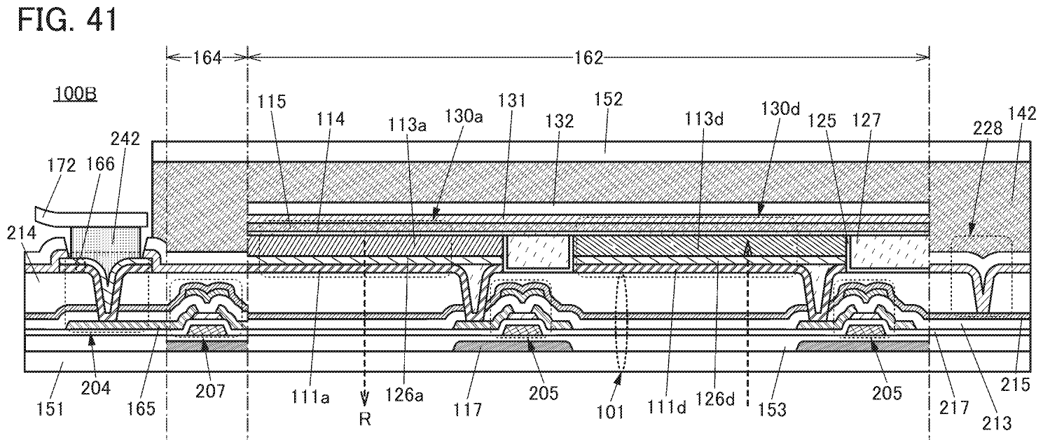

A display apparatus 100B illustrated in FIG. 41 is different from the display apparatus 100A mainly in having a bottom-emission structure. Note that portions similar to those in the display apparatus 100A are not described in some cases.

Light from the light-emitting device is emitted toward the substrate 151 side. For the substrate 151, a material having a high transmitting property with respect to visible light is preferably used. For the substrate 151, a material having a high transmitting property with respect to visible light and infrared light is further preferably used. By contrast, there is no limitation on the light-transmitting property of a material used for the substrate 152. Light is incident on the light-receiving device through the substrate 151.

The light-blocking layer 117 is preferably formed between the substrate 151 and the transistor 207 and between the substrate 151 and the transistor 205. FIG. 41 illustrates an example where the light-blocking layer 117 is provided over the substrate 151, an insulating layer 153 is provided over the light-blocking layer 117, and the transistors 207 and 205 and the like are provided over the insulating layer 153.

This embodiment can be combined with the other embodiments as appropriate.

### Embodiment 4

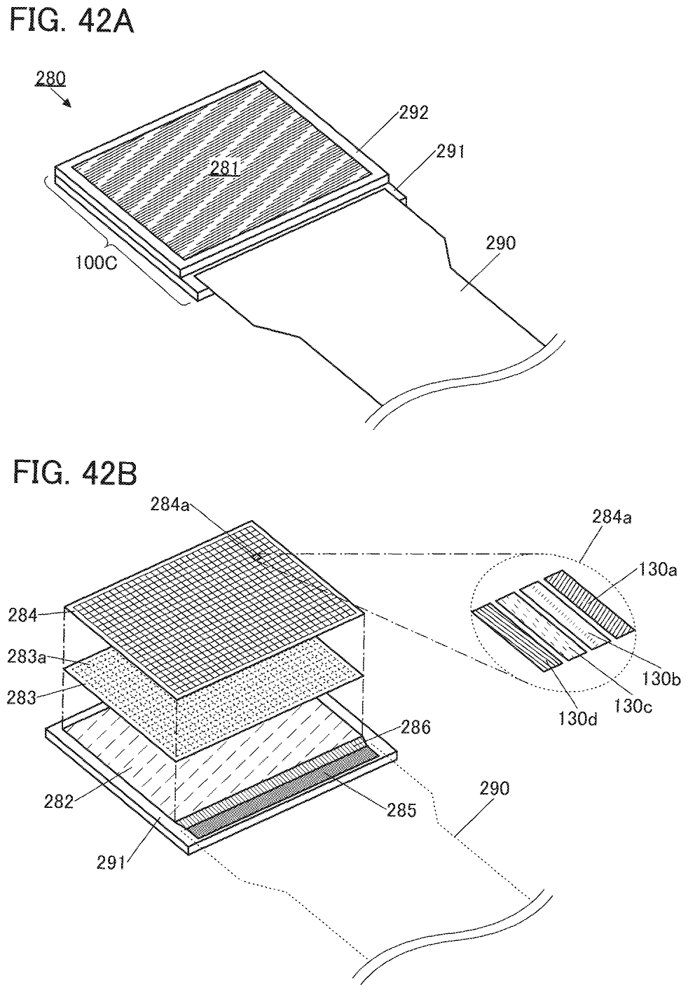

In this embodiment, display apparatuses of one embodiment of the present invention are described with reference to FIG. 42 to FIG. 48.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices capable of being worn on the head, such as a VR (Virtual Reality) device like a head mounted display and a glasses-type AR (Augmented Reality) device.

### <Display Module>

FIG. 42A is a perspective view of a display module 280. The display module 280 includes a display apparatus 100C and an FPC 290. Note that the display apparatus included in the display module 280 is not limited to the display apparatus 100C and may be a display apparatus 100D or a display apparatus 100E described later.

The display module 280 includes a substrate 291 and a substrate 292. The display module 280 includes a display portion 281. The display portion 281 is a region of the display module 280 where an image is displayed, and is a region where light from pixels provided in a pixel portion 284 described later can be seen.

FIG. 42B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 42B. The pixel 284a includes a light-emitting device 130a, a light-emitting device 130b, and a light-emitting device 130c emitting light of different colors and a light-receiving device 130d. The light-emitting devices and the light-receiving device can be arranged in a stripe pattern as illustrated in FIG. 42B. Alternatively, a variety of arrangement methods of light-emitting devices, such as delta arrangement or PenTile arrangement can be employed.

The pixel circuit portion 283 includes a plurality of pixel circuits 283a arranged periodically.

One pixel circuit 283a is a circuit that controls light emission of the light-emitting device and light reception of light-receiving device in one pixel 284a. For example, in the case where one pixel 284a includes three light-emitting devices and one light-receiving device, one pixel circuit 283a is a circuit controlling light emission of the three light-emitting devices and light reception of the one light-receiving device. One pixel circuit 283a may have a structure where three circuits each controlling light emission from one light-emitting device are provided and one circuit controlling light reception of one light-receiving device is provided. For example, the pixel circuit 283a can include at least one selection transistor, one current control transistor (driving transistor), and a capacitor for one light-emitting device. A gate signal is input to a gate of the selection transistor, and a source signal is input to one of a source and a drain of the selection transistor. With such a structure, an active-matrix display apparatus is achieved. As the pixel circuit 283a, the pixel circuit described in Embodiment 1 can be used, for example.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure where one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have an extremely high resolution. For example, the pixels 284a are preferably arranged in the display portion 281 with a resolution higher than or equal to 500 ppi, preferably higher than or equal to 1000 ppi, further preferably higher than or equal to 2000 ppi, still further preferably higher than or equal to 3000 ppi, yet further preferably higher than or equal to 5000 ppi, yet still further preferably higher than or equal to 6000 ppi, and lower than or equal to 20000 ppi or lower than or equal to 30000 ppi.

Such a display module 280 has an extremely high resolution, and thus can be suitably used for a VR device such as a head mounted display or a glasses-type AR device. For example, even with a structure where the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be favorably used for a display portion of a wearable electronic device, such as a wrist watch.

### <Display Apparatus 100C>

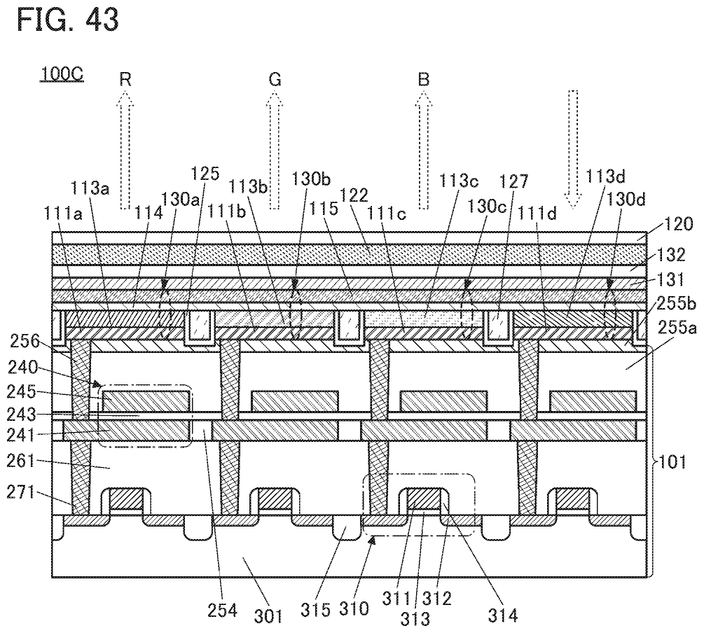

The display apparatus 100C illustrated in FIG. 43 includes a substrate 301, the light-emitting device 130a, the light-remitting device 130b, the light-emitting device 130c, the light-receiving device 130d, a capacitor 240, and a transistor 310.

The substrate 301 corresponds to the substrate 291 in FIG. 42A and FIG. 42B.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover a side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over the insulating layer 255a, and the light-emitting device 130a, the light-emitting device 130b, the light-emitting device 130c, the light-receiving device 130d, and the like are provided over the insulating layer 255b. The side surfaces of the pixel electrode 111a, the pixel electrode 111b, the pixel electrode 111c, the pixel electrode 111d, the EL layer 113a, the EL layer 113b, the EL layer 113c, and the light-receiving layer 113d are each covered with the insulating layers 125 and 127. The layer 114 is provided over the EL layer 113a, the EL layer 113b, the EL layer 113c, the light-receiving layer 113d, the insulating layer 125, and the insulating layer 127, and the common electrode 115 is provided over the layer 114. The protective layer 131 is provided over the light-emitting device 130a, the light-emitting device 130b, the light-emitting device 130c, and the light-receiving device 130d. The protective layer 132 is provided over the protective layer 131, and the substrate 120 is bonded onto the protective layer 132 with the resin layer 122. The above description can be referred to for details of the light-emitting devices and the components thereover up to the substrate 120.

As each of the insulating layers 255a and 255b, a variety of inorganic insulating films such as an oxide insulating film, a nitride insulating film, an oxynitride insulating film, and a nitride oxide insulating film can be suitably used. As the insulating layer 255a, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as the insulating layer 255a and a silicon nitride film be used as the insulating layer 255b. The insulating layer 255b preferably has a function of an etching protective film. Alternatively, a nitride insulating film or a nitride oxide insulating film may be used as the insulating layer 255a, and an oxide insulating film or an oxynitride insulating film may be used as the insulating layer 255b. Although this embodiment shows an example where a depressed portion is provided in the insulating layer 255b, a depressed portion is not necessarily provided in the insulating layer 255b.

The pixel electrode of the light-emitting device is electrically connected to one of the source and the drain of the transistor 310 through a plug 256 embedded in the insulating layers 255a and 255b, the conductive layer 241 embedded in the insulating layer 254, and the plug 271 embedded in the insulating layer 261. The top surface level of the insulating layer 255b and the top surface level of the plug 256 are equal to or substantially equal to each other. Any of a variety of conductive materials can be used for the plugs.

### <Display Apparatus 100D>

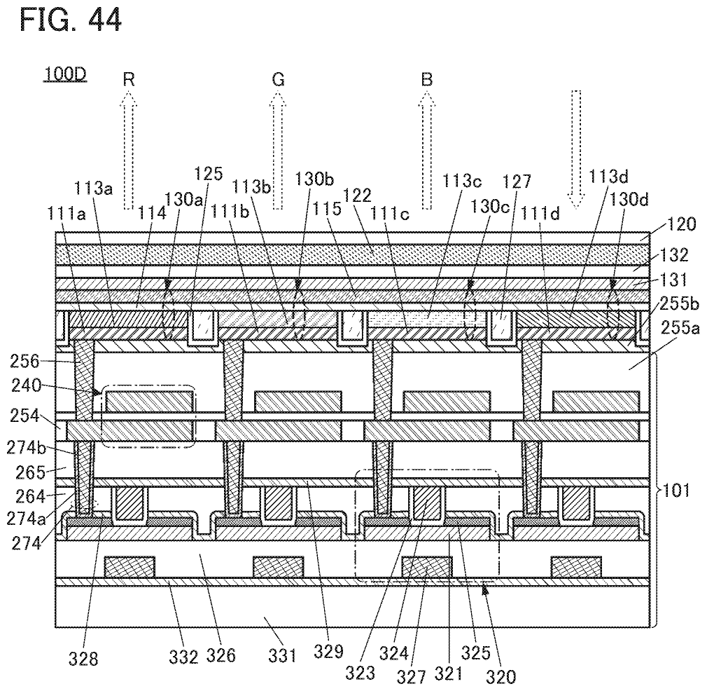

The display apparatus 100D illustrated in FIG. 44 is different from the display apparatus 100C mainly in a structure of a transistor. Note that portions similar to those of the display apparatus 100C are not described in some cases.

A transistor 320 is a transistor including a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 42A and FIG. 42B. A stacked-layer structure including the substrate 331 and the components thereover up to the insulating layer 255b corresponds to the layer 101 including transistors in Embodiment 1. As the substrate 331, an insulating substrate or a semiconductor substrate can be used.

An insulating layer 332 is provided over the substrate 331. The insulating layer 332 functions as a barrier insulating film that prevents diffusion of impurities such as water and hydrogen from the substrate 331 into the transistor 320 and release of oxygen from the semiconductor layer 321 to the insulating layer 332 side. As the insulating layer 332, for example, a film through which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film having semiconductor characteristics. A material that can be suitably used for the semiconductor layer 321 will be described in detail later.

The pair of conductive layers 325 are provided over and in contact with the semiconductor layer 321 and function as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier insulating film that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that their levels are equal to or substantially equal to each other, and an insulating layer 329 and an insulating layer 265 are provided to cover these layers.

The insulating layer 264 and the insulating layer 265 each function as an interlayer insulating layer. The insulating layer 329 functions as a barrier insulating film that prevents diffusion of impurities such as water and hydrogen from the insulating layer 265 or the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers a side surface of an opening of the insulating layer 265, the insulating layer 329, the insulating layer 264, and the insulating layer 328 and part of the top surface of the conductive layer 325, and a conductive layer 274b in contact with the top surface of the conductive layer 274a. In this case, a conductive material in which hydrogen and oxygen are less likely to diffuse is preferably used for the conductive layer 274a.

The structures of the insulating layer 254 and the components thereover up to the substrate 120 in the display apparatus 100D are similar to those in the display apparatus 100C.

### <Display Apparatus 100E>

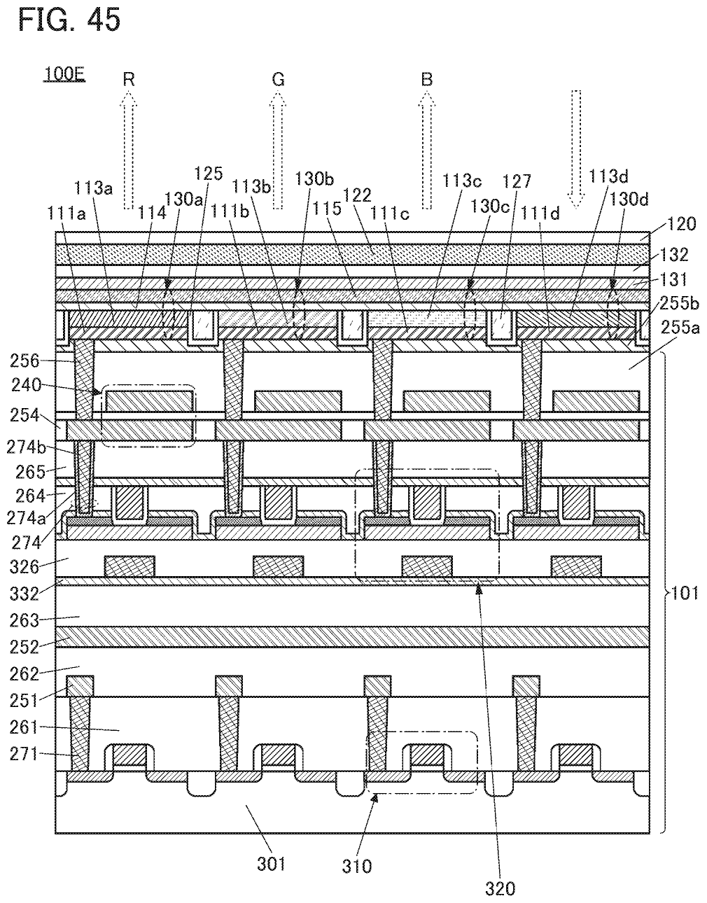

The display apparatus 100E illustrated in FIG. 45 has a structure where the transistor 310 whose channel is formed in the substrate 301 and the transistor 320 including a metal oxide in the semiconductor layer where the channel is formed are stacked. Note that portions similar to those in the display apparatuses 100C and 100D are not described in some cases.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices; thus, the display apparatus can be downsized as compared with the case where a driver circuit is provided around a display region.

### <Display Apparatus 100F>

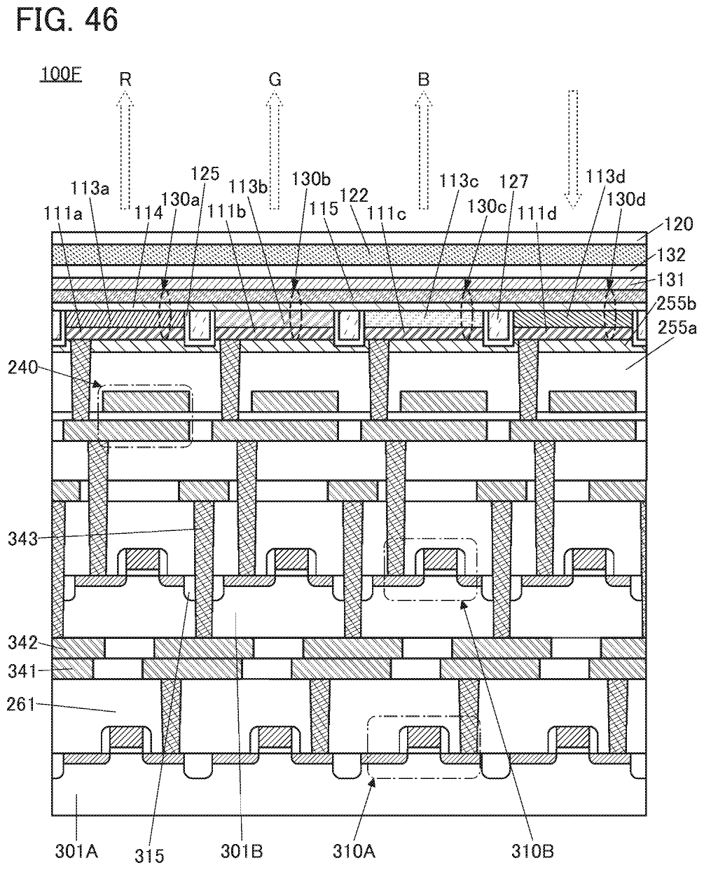

A display apparatus 100F illustrated in FIG. 46 has a structure where a transistor 310A and a transistor 310B in each of which a channel is formed in a semiconductor substrate are stacked.

In the display apparatus 100F, a substrate 301B provided with the transistor 310B, the capacitor 240, and the light-emitting devices is bonded to a substrate 301A provided with the transistor 310A.

The substrate 301B is provided with a plug 343 that penetrates the substrate 301B. The plug 343 is electrically connected to a conductive layer 342 provided on the rear surface of the substrate 301B (a surface opposite to the substrate 120 side). A conductive layer 341 is provided over the insulating layer 261 over the substrate 301A.

The conductive layer 341 and the conductive layer 342 are bonded to each other, whereby the substrate 301A and the substrate 301B are electrically connected to each other.

The conductive layer 341 and the conductive layer 342 are preferably formed using the same conductive material. For example, a metal film containing an element selected from Al, Cr, Cu, Ta, Ti, Mo, and W, a metal nitride film containing the above element as a component (a titanium nitride film, a molybdenum nitride film, or a tungsten nitride film), or the like can be used. Copper is particularly preferably used for the conductive layer 341 and the conductive layer 342. In this case, it is possible to employ Cu—Cu direct bonding (a technique for achieving electrical continuity by connecting Cu (copper) pads). Note that the conductive layer 341 and the conductive layer 342 may be bonded to each other through a bump.

### <Display Apparatus 100G>

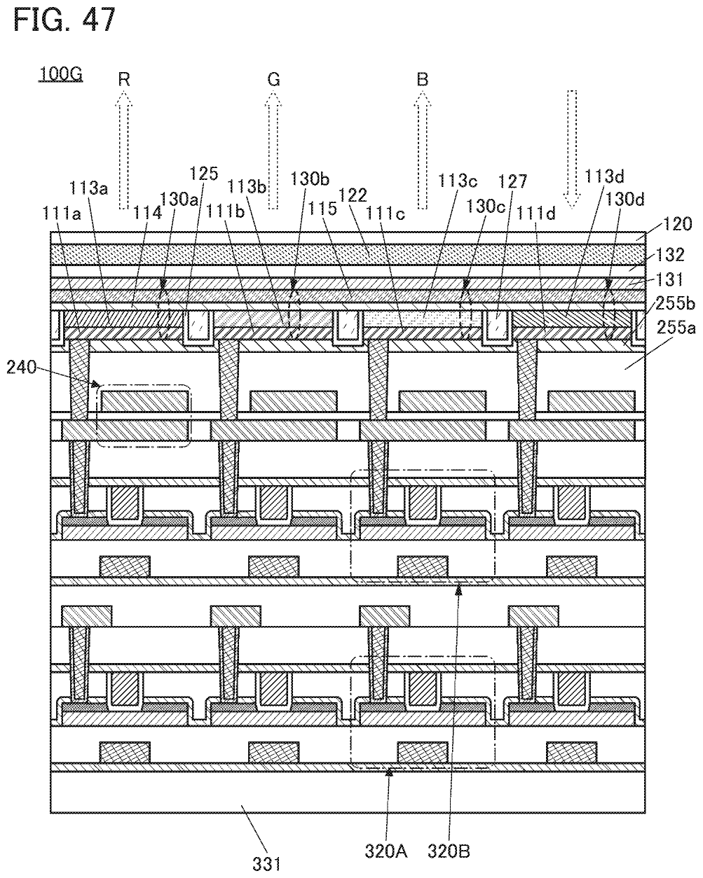

In a display apparatus 100G illustrated in FIG. 47, a transistor 320A and a transistor 320B each including an oxide semiconductor in a semiconductor layer where a channel is formed are stacked.

The description of the display apparatus 100D can be referred to for the transistor 320A, the transistor 320B, and the components around them.

Although the structure where two transistors including an oxide semiconductor are stacked is described, the present invention is not limited thereto. For example, three or more transistors may be stacked.

### <Structure Example of Transistor>

Cross-sectional structure examples of a transistor that can be used for the display apparatuses are described below.

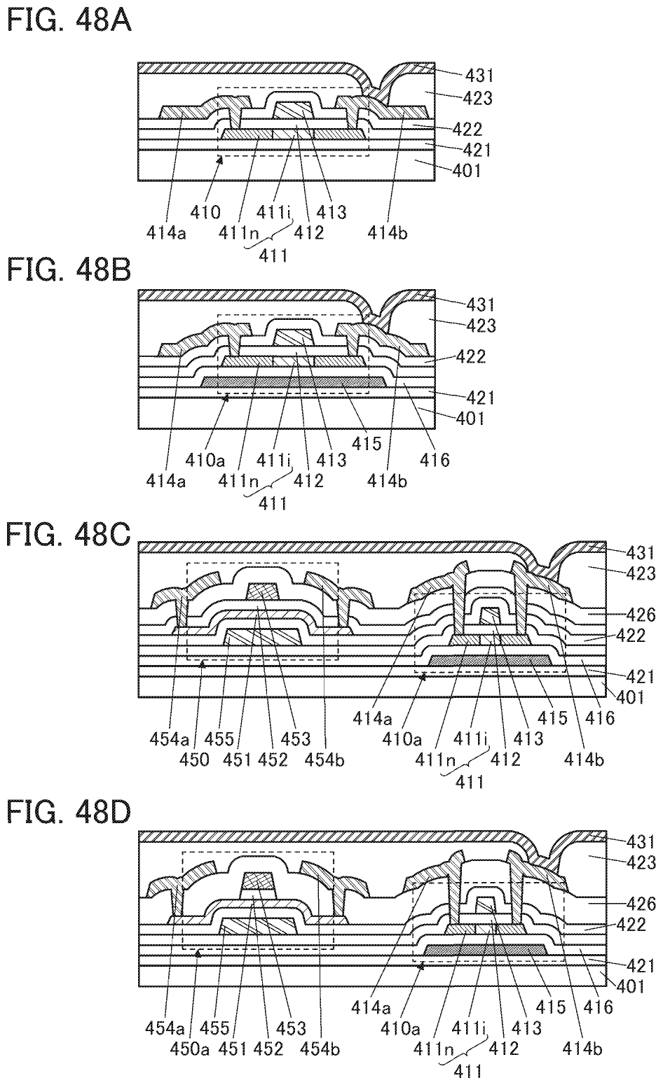

FIG. 48A is a cross-sectional view including a transistor 410.

The transistor 410 is a transistor provided over a substrate 401 and contains polycrystalline silicon in its semiconductor layer. For example, the transistor 410 corresponds to the transistor M12 in the pixel 81 illustrated in FIG. 5B. In other words, FIG. 48A illustrates an example where one of a source and a drain of the transistor 410 is electrically connected to a conductive layer 431 of the light-emitting device.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Alternatively, the semiconductor layer 411 can contain a metal oxide exhibiting semiconductor characteristics (also referred to as an oxide semiconductor). In this case, the transistor 410 can be referred to as an OS transistor.

The low-resistance region 411n is a region containing an impurity element. For example, in the case where the transistor 410 is an n-channel transistor, phosphorus, arsenic, or the like is added to the low-resistance region 411n. Meanwhile, in the case where the transistor 410 is a p-channel transistor, boron, aluminum, or the like is added to the low-resistance region 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are electrically connected to the low-resistance regions 411n in the opening portions provided through the insulating layer 422 and the insulating layer 412. Part of the conductive layer 414a functions as one of a source electrode and a drain electrode and part of the conductive layer 414b functions as the other of the source electrode and the drain electrode. An insulating layer 423 is provided to cover the conductive layer 414a, the conductive layer 414b, and the insulating layer 422.

The conductive layer 431 functioning as a pixel electrode is provided over the insulating layer 423. The conductive layer 431 is provided over the insulating layer 423 and is electrically connected to the conductive layer 414b through an opening provided in the insulating layer 423. Although not illustrated here, an EL layer and a common electrode can be stacked over the conductive layer 431.

FIG. 48B illustrates a transistor 410a including a pair of gate electrodes. The transistor 410a illustrated in FIG. 48B is different from FIG. 48A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 48B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating layer 412 and the insulating layer 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case of using LTPS transistors as all of the transistors included in the pixel 81, the transistor 410 illustrated in FIG. 48A as an example or the transistor 410a illustrated in FIG. 48B as an example can be used. In this case, the transistors 410a may be used as all of the transistors included in the pixel 81, the transistors 410 may be used as all of the transistors, or the transistors 410a and the transistors 410 may be used in combination.

Described below is an example of a structure including both a transistor containing silicon in its semiconductor layer and a transistor containing a metal oxide in its semiconductor layer.

FIG. 48C is a schematic cross-sectional view including the transistor 410a and a transistor 450.

The above description in Structure example 1 can be referred to for the transistor 410a. Although an example using the transistor 410a is illustrated here, a structure including the transistor 410 and the transistor 450 may be employed or a structure including all of the transistor 410, the transistor 410a, and the transistor 450 may be employed.

The transistor 450 is a transistor including a metal oxide in its semiconductor layer. The structure illustrated in FIG. 48C shows an example where the transistor 450 and the transistor 410a correspond to the transistor M11 and the transistor M12, respectively, in the pixel 81. That is, FIG. 48C illustrates an example where one of the source and the drain of the transistor 410a is electrically connected to the conductive layer 431.

FIG. 48C illustrates an example where the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in opening portions provided in the insulating layer 426 and the insulating layer 452. Part of the conductive layer 454a functions as one of a source electrode and a drain electrode and part of the conductive layer 454b functions as the other of the source electrode and the drain electrode. The insulating layer 423 is provided to cover the conductive layer 454a, the conductive layer 454b, and the insulating layer 426.

Here, the conductive layer 414a and the conductive layer 414b electrically connected to the transistor 410a are preferably formed by processing the same conductive film as the conductive layer 454a and the conductive layer 454b. FIG. 48C illustrates a structure where the conductive layer 414a, the conductive layer 414b, the conductive layer 454a, and the conductive layer 454b are formed on the same plane (i.e., in contact with the top surface of the insulating layer 426) and contain the same metal element. In this case, the conductive layer 414a and the conductive layer 414b are electrically connected to the low-resistance regions 411n through openings provided in the insulating layer 426, the insulating layer 452, the insulating layer 422, and the insulating layer 412. This is preferable because the fabrication process can be simplified.

The conductive layer 413 functioning as the first gate electrode of the transistor 410a and the conductive layer 455 functioning as the second gate electrode of the transistor 450 are preferably formed by processing the same conductive film. FIG. 48C illustrates a structure where the conductive layer 413 and the conductive layer 455 are formed on the same plane (i.e., in contact with the top surface of the insulating layer 412) and contain the same metal element. This is preferable because the fabrication process can be simplified.

FIG. 48C illustrates a structure where the insulating layer 452 functioning as the first gate insulating layer of the transistor 450 covers an end portion of the semiconductor layer 451; however, as in a transistor 450a illustrated in FIG. 48D, the insulating layer 452 may be processed to have the same or substantially the same top surface shape as the conductive layer 453.

Note that in this specification and the like, the expression “having substantially the same top surface shapes” means that at least outlines of stacked layers partly overlap with each other. For example, the case of processing an upper layer and a lower layer with the use of the same mask pattern or mask patterns that are partly the same is included. However, in some cases, the outlines do not completely overlap with each other and the upper layer is positioned on an inner side of the lower layer or the upper layer is positioned on an outer side of the lower layer; such a case is also represented by the expression “having substantially the same top surface shapes”.

Although the example where the transistor 410a corresponds to the transistor M12 and is electrically connected to the pixel electrode is shown here, one embodiment of the present invention is not limited thereto. For example, a structure where the transistor 450 or the transistor 450a corresponds to the transistor M12 may be employed. In this case, the transistor 410a corresponds to the transistor M11, the transistor M13, or another transistor.

This embodiment can be combined with the other embodiments as appropriate.

### Embodiment 5

In this embodiment, a metal oxide (also referred to as an oxide semiconductor) that can be used in the OS transistor described in the above embodiment will be described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a chemical vapor deposition (CVD) method such as a metal organic chemical vapor deposition (MOCVD) method, an atomic layer deposition (ALD) method, or the like.

### <Classification of Crystal Structure>

Amorphous (including completely amorphous), CAAC (c-axis-aligned crystalline), nc (nanocrystalline), CAC (cloud-aligned composite), single crystal, and polycrystalline (polycrystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum obtained by GIXD (Grazing-Incidence XRD) measurement. Note that a GIXD method is also referred to as a thin film method or a Seemann-Bohlin method.

For example, the XRD spectrum of the quartz glass substrate shows a peak with a substantially bilaterally symmetrical shape. On the other hand, the peak of the XRD spectrum of the IGZO film having a crystal structure has a bilaterally asymmetrical shape. The asymmetrical peak of the XRD spectrum clearly shows the existence of crystals in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film formed at room temperature. Thus, it is suggested that the IGZO film formed at room temperature is in an intermediate state, which is neither a crystal state nor an amorphous state, and it cannot be concluded that the IGZO film is in an amorphous state.

### <<Structure of Oxide Semiconductor>>

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS will be described in detail.

### <CAAC-OS>

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure where a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

<nc-OS>

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

<a-Like OS>

The a-like OS is an oxide semiconductor having a structure between those of the nc-OS and the amorphous oxide semiconductor. The a-like OS has a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Structure of Oxide Semiconductor>>

Next, the above-described CAC-OS will be described in detail. Note that the CAC-OS relates to the material composition.

### <CAC-OS>

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by <In>, <Ga>, and <Zn>, respectively. For example, the first region in the CAC-OS in the In—Ga—Zn oxide has <In> higher than <In> in the composition of the CAC-OS film. Moreover, the second region has <Ga> higher than <Ga> in the composition of the CAC-OS film. For example, the first region has higher <In> and lower <Ga> than the second region. Moreover, the second region has higher <Ga> and lower <In> than the first region.

Specifically, the first region contains indium oxide, indium zinc oxide, or the like as its main component. The second region contains gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure where metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of an oxygen gas to the total flow rate of the deposition gas at the time of deposition is preferably as low as possible, and for example, the ratio of the flow rate of an oxygen gas to the total flow rate of the deposition gas at the time of deposition is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure where the region containing In as its main component (the first region) and the region containing Ga as its main component (the second region) are unevenly distributed and mixed.

Here, the first region has higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ) and excellent switching operation can be achieved.

A transistor using the CAC-OS has high reliability. Thus, the CAC-OS is most suitable for a variety of semiconductor devices such as display apparatuses.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm³, preferably lower than or equal to 1×10¹⁵ cm³, further preferably lower than or equal to 1×10¹³ cm³, still further preferably lower than or equal to 1×10¹¹ cm³, yet further preferably lower than 1×10¹⁰ cm³, and higher than or equal to 1×10⁻⁹ cm³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Electric charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor will be described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×18 atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10 20 atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given. This embodiment can be combined with the other embodiments as appropriate.

### Embodiment 6

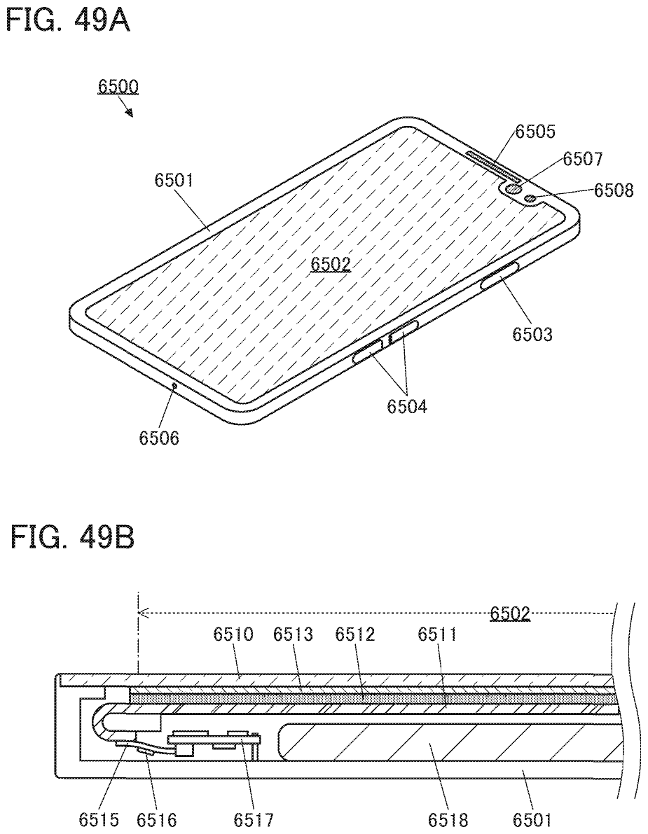

In this embodiment, electronic devices of one embodiment of the present invention will be described with reference to FIG. 49 to FIG. 51.

An electronic device of this embodiment includes the display apparatus of one embodiment of the present invention in a display portion. The display apparatus of one embodiment of the present invention can be easily increased in resolution and definition. Thus, the display apparatus of one embodiment of the present invention can be used for display portions of a variety of electronic devices.

Examples of electronic devices include a digital camera, a digital video camera, a digital photo frame, a mobile phone, a portable game machine, a portable information terminal, and an audio reproducing device in addition to electronic devices with a relatively large screen, such as a television device, a desktop or laptop personal computer, a monitor of a computer or the like, digital signage, and a large game machine such as a pachinko machine.

In particular, a display apparatus of one embodiment of the present invention can have a high resolution, and thus can be suitably used for an electronic device having a relatively small display portion. Examples of such an electronic device include a watch-type or a bracelet-type information terminal device (wearable device), and a wearable device worn on a head, such as a device for VR such as a head-mounted display, a glasses-type device for AR, and a device for MR (Mixed Reality).

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. Furthermore, the pixel density (resolution) of the display apparatus of one embodiment of the present invention is preferably higher than or equal to 100 ppi, higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the use of such a display apparatus having one or both of a high definition and a high resolution, the electronic device can have higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device 6500 illustrated in FIG. 49A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502.

FIG. 49B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while the thickness of the electronic device is reduced. Moreover, part of the display panel 6511 is folded back so that a connection portion with the FPC 6515 is placed on the back side of a pixel portion, whereby an electronic device with a narrow bezel can be achieved.

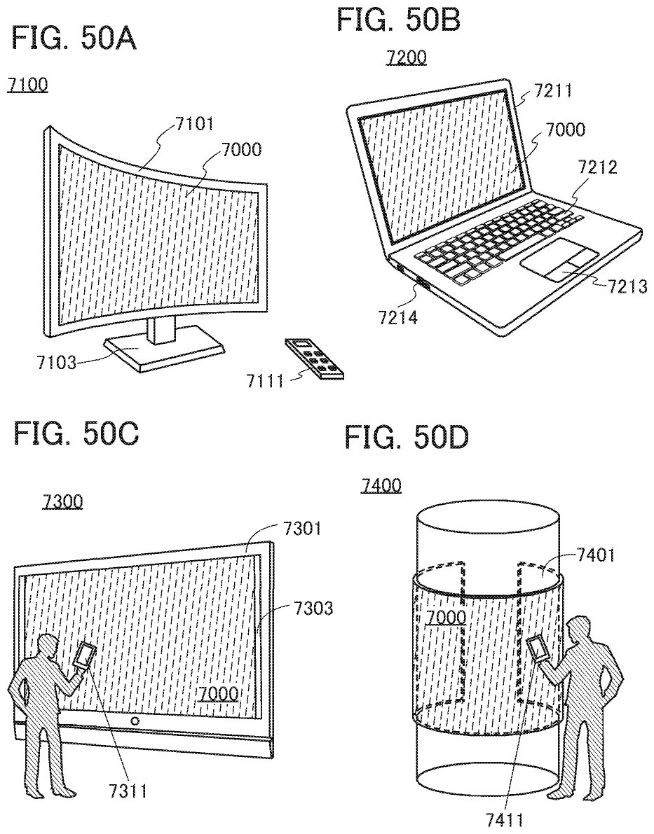

FIG. 50A illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 50A can be performed with an operation switch provided in the housing 7101 and a separate remote controller 7111. Alternatively, the display portion 7000 may be provided with a touch sensor, and the television device 7100 may be operated by touch on the display portion 7000 with a finger or the like. The remote controller 7111 may include a display portion for displaying information output from the remote controller 7111. With operation keys or a touch panel provided in the remote controller 7111, channels and volume can be operated and videos displayed on the display portion 7000 can be operated.

Note that the television device 7100 has a structure where a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 50B illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 50C and FIG. 50D illustrate examples of digital signage.

Digital signage 7300 illustrated in FIG. 50C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 50D is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in FIG. 50C and FIG. 50D.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of an image or a moving image on the display portion 7000, intuitive operation by a user is possible. Moreover, for an application for providing information such as route information or traffic information, usability can be enhanced by intuitive operation.

As illustrated in FIG. 50C and FIG. 50D, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

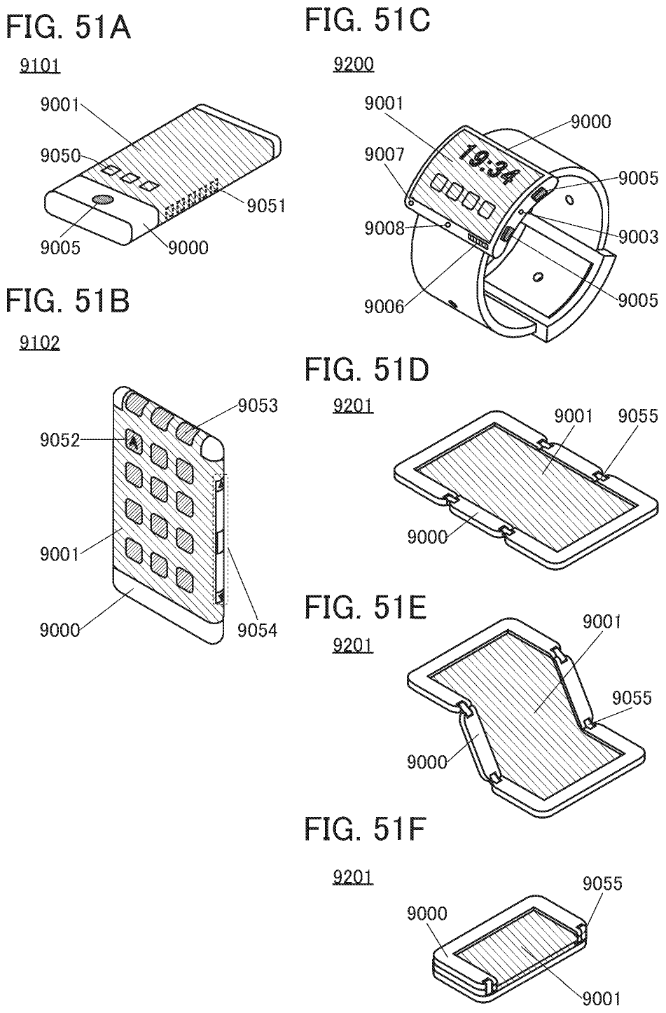

Electronic devices illustrated in FIG. 51A to FIG. 51F each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays), a microphone 9008, and the like. The display apparatus of one embodiment of the present invention can be used for the display portion 9001.

The electronic devices illustrated in FIG. 51A to FIG. 51F have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a recording medium (an external recording medium or a recording medium incorporated in the camera), a function of displaying the taken image on the display portion, or the like.

The electronic devices illustrated in FIG. 51A to FIG. 51F will be described in detail below.

FIG. 51A is a perspective view illustrating a portable information terminal 9101. For example, the portable information terminal 9101 can be used as a smartphone. Note that the portable information terminal 9101 may include the speaker 9003, the connection terminal 9006, the sensor 9007, or the like. The portable information terminal 9101 can display characters and image information on its plurality of surfaces. FIG. 51A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 51B is a perspective view illustrating a portable information terminal 9102. The portable information terminal 9102 has a function of displaying information on three or more surfaces of the display portion 9001. Here, an example is illustrated where information 9052, information 9053, and information 9054 are displayed on different surfaces. For example, a user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 51C is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 51D to FIG. 51F are perspective views illustrating a foldable portable information terminal 9201. FIG. 51D is a perspective view of an opened state of the portable information terminal 9201, FIG. 51F is a perspective view of a folded state thereof, and FIG. 51E is a perspective view of a state in the middle of change from one of FIG. 51D and FIG. 51F to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

The display apparatus and the electronic device of one embodiment of the present invention can be incorporated in an inside wall or an outside wall of a house or a building or the interior or the exterior of a vehicle.

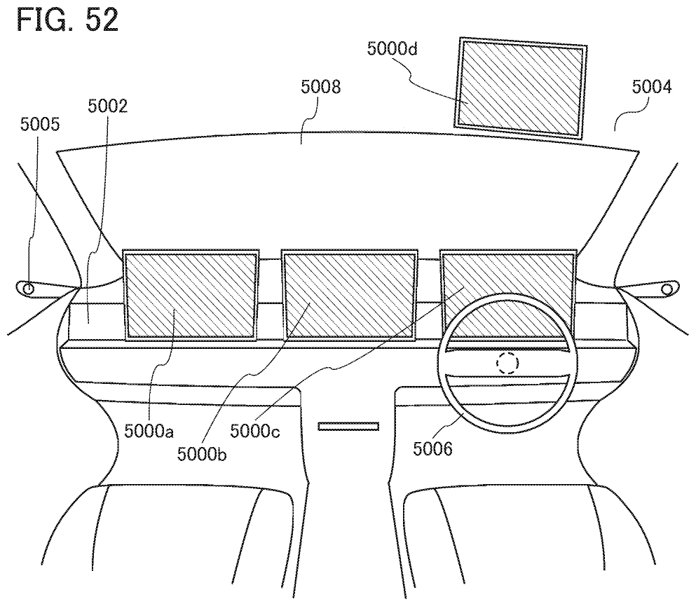

FIG. 52 illustrates an example where the display apparatus of one embodiment of the present invention is installed in a vehicle. In the vehicle illustrated in FIG. 52, a display apparatus 5000a, a display apparatus 5000b, and a display apparatus 5000c are installed on a dashboard 5002. A display apparatus 5000d is installed on a ceiling 5004 on the driver's seat side. Note that in the example illustrated in FIG. 52, the display apparatus 5000d is installed in, but not limited to, a right-hand drive vehicle; installation in a left-hand drive vehicle is also possible. In that case, the left and right of the components arranged in FIG. 52 are reversed. FIG. 52 illustrates a steering wheel 5006, a windshield 5008, and the like that are arranged around a driver's seat and a front passenger seat.

It is preferable that one or more of the display apparatus 5000a to the display apparatus 5000d have a near touch sensor function. With the near touch sensor function, the user can operate the display apparatus without staring at the display apparatus. In particular, a driver can operate the display apparatus without significantly moving the line of sight from the front side, which can enhance the safety while the vehicle is driven and stopped. A display portion of each of the display apparatus 5000a to the display apparatus 5000d has a diagonal preferably greater than or equal to 5 inches, further preferably greater than or equal to 10 inches. A display apparatus in which a display portion has a diagonal of approximately 13 inches can be suitably used as each of the display apparatus 5000a to the display apparatus 5000d, for example.

Note that the display apparatus 5000a to the display apparatus 5000d may be flexible. The flexible display apparatuses can be incorporated along even a curved surface. For example, the display apparatuses can be provided along a curved surface such as the dashboard 5002 or the ceiling 5004.

A plurality of cameras 5005 may be provided outside the vehicle. The cameras 5005 can capture images of the surroundings of the vehicle, e.g., the situations at the rear side. Although the cameras 5005 are provided instead of side mirrors in the example illustrated in FIG. 52, both the side mirrors and the cameras may be provided.

As the cameras 5005, a CCD camera, a CMOS camera, or the like can be used. In addition, an infrared camera may be used in combination with such a camera. The infrared camera, which has a higher output level with a higher temperature of an object, can detect or extract a living body such as a human or an animal.

Images captured with the cameras 5005 can be output to one or more of the display apparatus 5000a to the display apparatus 5000d. The display apparatus 5000a to the display apparatus 5000d are mainly used for supporting driving of the vehicle. Images of the situations at the rear side are captured at a wide angle of view with the cameras 5005, and the images are displayed on one or more of the display apparatus 5000a to the display apparatus 5000d so that the driver can see a blind area for avoiding an accident.

A distance image sensor may be provided, for example, over a roof of the vehicle, and an image obtained by the distance image sensor may be displayed on one or more of the display apparatus 5000a to the display apparatus 5000d. As the distance image sensor, an image sensor, LIDAR (Light Detection and Ranging), or the like can be used. When an image obtained by the image sensor and the image obtained by the distance image sensor are displayed on one or more of the display apparatus 5000a to the display apparatus 5000d, more pieces of information can be provided to the driver to support driving.

One or more of the display apparatus 5000a to the display apparatus 5000d may have a function of displaying map information, traffic information, television images, DVD images, and the like.

A display panel having an image capturing function is preferably used for at least one of the display apparatus 5000a to the display apparatus 5000d. For example, when the driver touches the display panel, the vehicle can perform biometric authentication such as fingerprint authentication or palm print authentication. The vehicle may have a function of setting an environment to meet the driver's preference when the driver is authenticated by biometric authentication. For example, one or more of adjustment of the position of the seat, adjustment of the position of the steering wheel, adjustment of the direction of the cameras 5005, setting of brightness, setting of an air conditioner, setting of the speed (frequency) of wipers, volume setting of audio, and reading of the playlist of the audio are preferably performed after authentication.

A vehicle can be brought into a state where the vehicle can be driven, e.g., a state where an engine is started, after the driver is authenticated by biometric authentication. This is preferable because a key, which is conventionally necessary, is unnecessary.

This embodiment can be combined with the other embodiments as appropriate.

### Example 1

In this example, evaluation results of the characteristics of fabricated light-receiving devices will be described. Note that light-receiving devices fabricated in the following examples can be formed on the same plane as light-emitting devices.

In this example, light-receiving devices (a device 1a to a device 1d) of one embodiment of the present invention were fabricated.

Chemical formulae of materials used in this example are shown below.

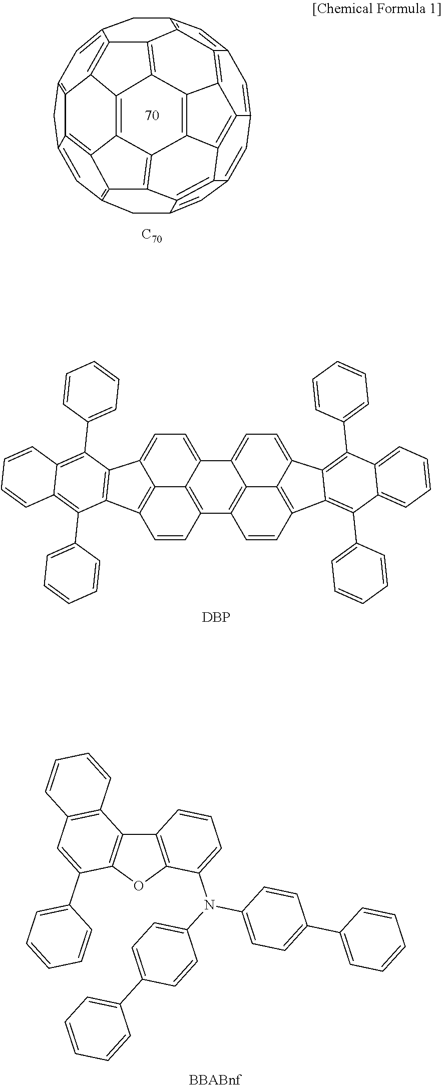

Specific structures of the light-receiving devices fabricated in this example are shown in Table 1 and Table 2. The description of the light-receiving device 12e illustrated in FIG. 3B as an example can be referred to for the structures of the light-receiving devices. In this example, the structure of the layer 35B was made different among the light-receiving devices, and similar structures were employed for layers other than the layer 35B.

TABLE 1

| | Constituent material | Weight ratio | Film thickness | |
|---|---|---|---|---|
| Electrode 15 | Ag:Mg (10:1) | — | 15 | nm |
| Layer 21 | LiF | — | 1 | nm |
| Layer 33B | BBABnf:OCHD-003 | 1:0.1 | 10 | nm |
| Layer 35B | BBABnf | — | * | |
| Active layer 43 | C₇₀:DBP | 9:1 | 60 | nm |
| Layer 37B | C₇₀ | — | 55 | nm |

| | | | |
|---|---|---|---|
| Electrode 13B | APC\ITSO | — | 100 nm\100 nm |

TABLE 2

| Sample name | Layer 35B * |
|---|---|
| Device 1a | 20 nm |
| Device 1b | 40 nm |
| Device 1c | 60 nm |
| Device 1d | 80 nm |

The electrode 13B was formed in such a manner that an alloy film of silver, palladium, and copper (APC: Ag—Pd—Cu) was formed to a thickness of 100 nm by a sputtering method, and a film of indium tin oxide containing silicon oxide (ITSO) was formed to a thickness of 100 nm by a sputtering method. Note that the electrode 13B functions as an anode in each light-receiving device of this example.

Next, a base material over which the electrode 13B was formed was washed with water, baked at 200° C. for an hour, and then subjected to UV ozone treatment for 370 seconds. After that, the substrate was transferred into a vacuum evaporation apparatus where the pressure was reduced to approximately 1×10⁻⁴ Pa, and vacuum baking was performed at 170° C. for 30 minutes in a heating chamber of the vacuum evaporation apparatus. Then, the substrate was cooled down for approximately 30 minutes.

The layer 37B functioning as an electron-transport layer was formed using fullerene (C₇₀) to a thickness of 55 nm.

The active layer 43 was formed by depositing fullerene (C₇₀) and tetraphenyldibenzoperiflanthene (abbreviation: DBP) by co-evaporation in a weight ratio of C₇₀:DBP=9:1. The active layer 43 was formed to a thickness of 60 nm.

The layer 35B functioning as a hole-transport layer was formed using N,N-bis(4-biphenyl)-6-phenylbenzo[b]naphtho[1,2-d]furan-8-amine (abbreviation: BBABnf). Here, the thickness of the layer 35B was made different among the light-receiving devices. In the device 1a, the thickness of the layer 35B was 20 nm. In the device 1b, the thickness of the layer 35B was 40 nm. In the device 1c, the thickness of the layer 35B was 60 nm. In the device 1d, the thickness of the layer 35B was 80 nm.

The layer 33B was formed by depositing N,N-bis(4-biphenyl)-6-phenylbenzo[b]naphtho[1,2-d]furan-8-amine (abbreviation: BBABnf) and an electron acceptor material containing fluorine with a molecular weight of 672 (OCHD-003) by co-evaporation in a weight ratio of BBABnf:OCHD-003=1:0.1. The layer 33B was formed to a thickness of 10 nm. Note that the layer 33B functions as a hole-transport layer in each light-receiving device of this example.

The layer 21 was formed by depositing lithium fluoride (LiF) by evaporation to a thickness of 1 nm.

The electrode 15 was formed by depositing silver (Ag) and magnesium (Mg) by co-evaporation in a volume ratio of 10:1 to a thickness of 15 nm. Note that the electrode 15 functions as a cathode in each light-receiving device of this example.

In the above manner, the light-receiving devices (the device 1a to the device 1d) different in the structure of the layer 35B were fabricated.

### <Current Density-Voltage Characteristics>

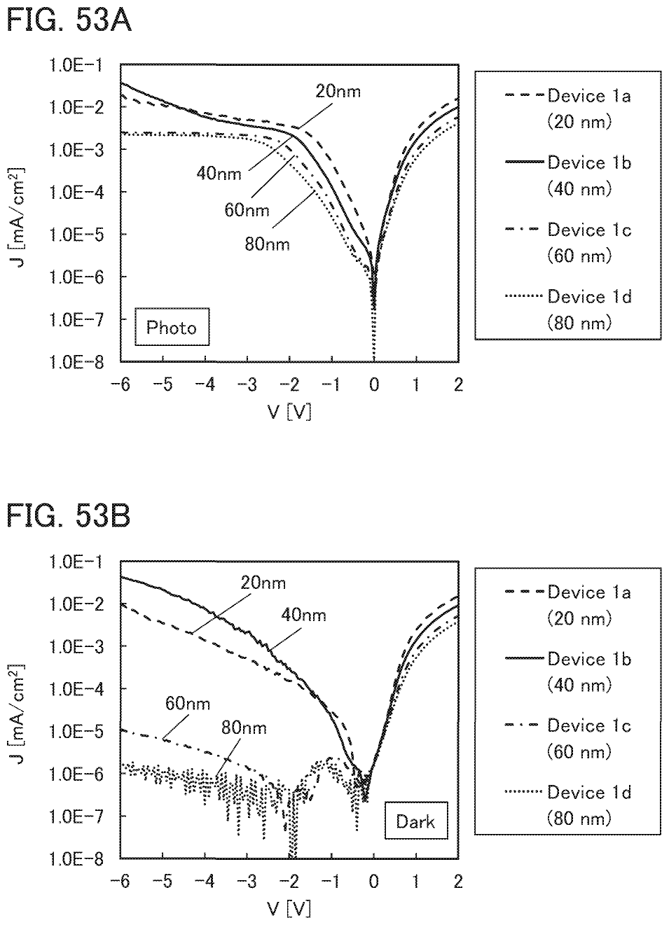

Next, the current density-voltage characteristics of each light-receiving device were measured. The measurement was performed in each of a state with irradiation with monochromatic light having a wavelength λ of 525 nm at an irradiance of 12.5 μW/cm² (denoted by Photo) and a dark state (denoted by Dark). FIG. 53A and FIG. 53B show the current density-voltage characteristics of the device 1a to the device 1d. In each of FIG. 53A to FIG. 53B, the horizontal axis represents voltage V and the vertical axis represents current density J.

As shown in FIG. 53A, it is found that the device 1c and the device 1d show favorable saturation characteristics as compared with the device 1a and the device 1b. As shown in FIG. 53B, it is found that there is a large amount of current in a dark state (dark current) in the device 1a and the device 1b. This is probably because, in the device 1a and the device 1b where the layer 35B has a small thickness, the components of the electrode 15 diffuse to the vicinity of the active layer 43, which facilitates charge transfer between the electrode 15 and the active layer 43 and increases the amount of dark current. Meanwhile, favorable characteristics are obtained in the device 1c and the device 1d probably because diffusion of the components of the electrode is inhibited and thus the amount of dark current is small.

### Example 2

In this example, evaluation results of the characteristics of a fabricated light-receiving device will be described.

In this example, a light-receiving device (a device 2) of one embodiment of the present invention was fabricated.

Chemical formulae of materials used in this example are shown below.

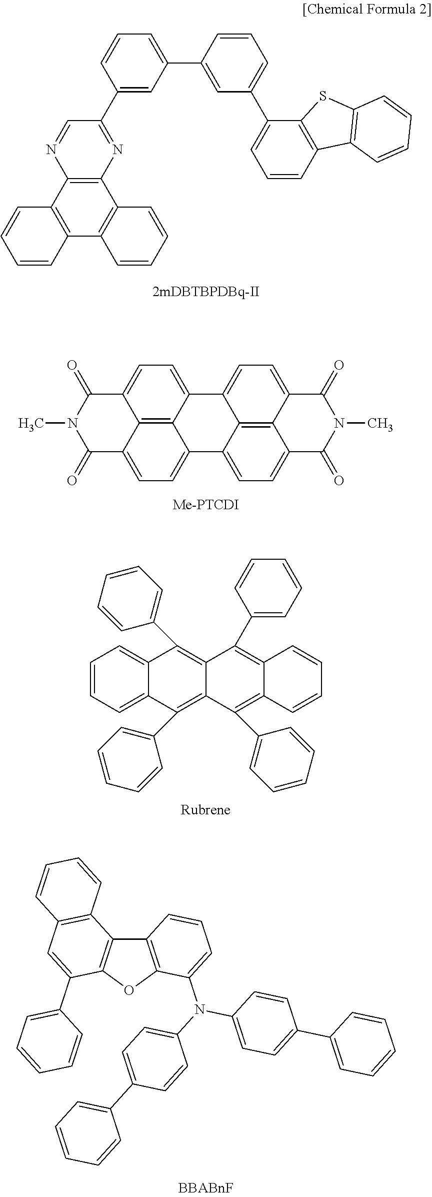

A specific structure of the light-receiving device fabricated in this example is shown in Table 3. The description of the light-receiving device 12e illustrated in FIG. 3B as an example can be referred to for the structure of the light-receiving device.

TABLE 3

| | Constituent material | Weight ratio | Film thickness | |
|---|---|---|---|---|
| Electrode 15 | Ag:Mg (10:1) | — | 15 | nm |
| Layer 21 | LiF | — | 1 | nm |
| Layer 33B | BBABnf:OCHD-003 | 1:0.1 | 10 | nm |
| Layer 35B | BBABnf | — | 80 | nm |
| Active layer 43 | Rubrene | — | 54 | nm |
| | Me-PTCDI | — | 6 | nm |
| Layer 37B | 2mDBTBPDBq-II | — | 10 | nm |

| | | | |
|---|---|---|---|
| Electrode 13B | APC\ITSO | — | 100 nm\100 nm |

The electrode 13B was formed. Since the description in Example 1 can be referred to for the formation of the electrode 13B, the detailed description thereof is omitted.

The layer 37B functioning as an electron-transport layer was formed by depositing 2-[3′-(dibenzothiophen-4-yl)biphenyl-3-yl]dibenzo[f,h]quinoxaline (abbreviation: 2mDBTBPDBq-II) by evaporation to a thickness of 10 nm.

The active layer 43 was formed by depositing N,N-dimethyl-3,4,9,10-perylenetetracarboxylic diimide (abbreviation: Me-PTCDI) by evaporation to a thickness of 6 nm and then depositing Rubrene by evaporation to a thickness of 54 nm.

The layer 35B functioning as a hole-transport layer was formed by depositing N,N-bis(4-biphenyl)-6-phenylbenzo[b]naphtho[1,2-d]furan-8-amine (abbreviation: BBABnf) by evaporation to a thickness of 80 nm.

The layer 33B, the layer 21, and the electrode 15 were formed. Since the description in Example 1 can be referred to for the formation of the layer 33B, the layer 21, and the electrode 15, the detailed description thereof is omitted.

In the above manner, the light-receiving device (the device 2) was fabricated.

### <Current Density-Voltage Characteristics>

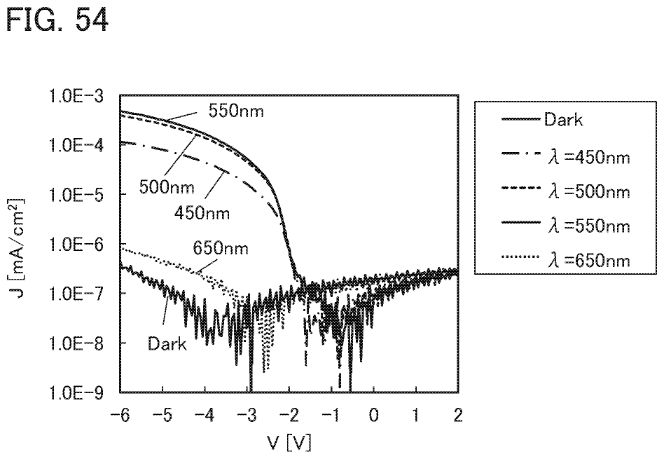

Next, the current density-voltage characteristics of the light-receiving device were measured. The measurement was performed in each of a state with irradiation with monochromatic light at an irradiance of 12.5 μW/cm² and a dark state (denoted by Dark). The wavelengths λ of the monochromatic light were 450 nm, 500 nm, 550 nm, and 650 nm. FIG. 54 shows the current density-voltage characteristics of the device 2. In FIG. 54, the horizontal axis represents voltage V and the vertical axis represents current density J.

As shown in FIG. 54, it is found that the light-receiving device of this example shows favorable characteristics when irradiated with light with the wavelengths λ of 450 nm, 500 nm, and 550 nm. It is also found that the light-receiving device of this example has a small amount of dark current.

### Example 3

In this example, evaluation results of the characteristics of fabricated light-receiving devices will be described.

In this example, light-receiving devices (a device 3 and a device 4) of one embodiment of the present invention were fabricated.

Chemical formulae of materials used in this example are shown below.

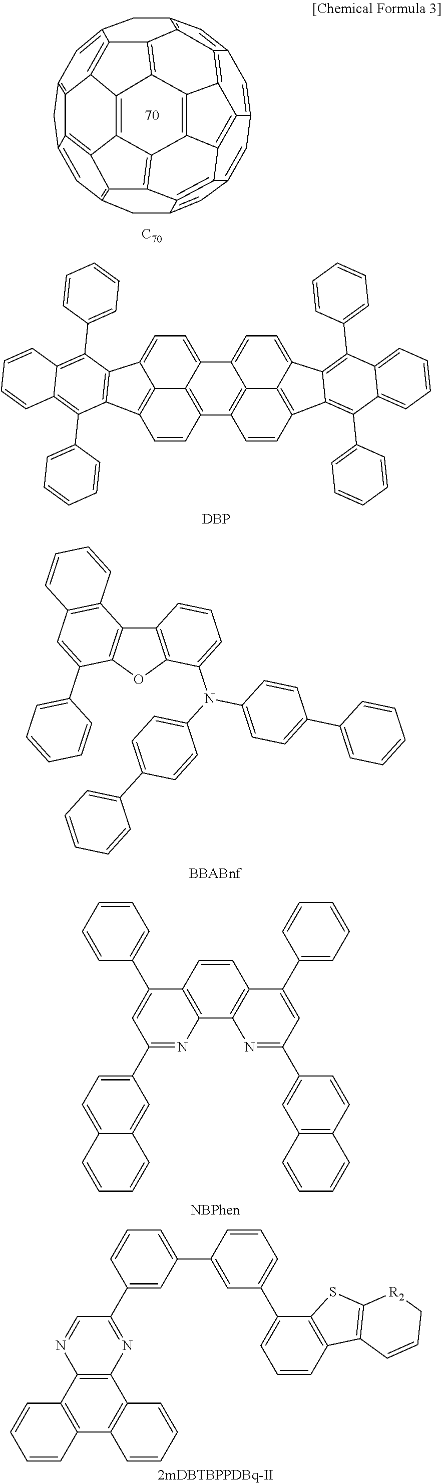

A specific structure of the device 3 fabricated in this example is shown in Table 4. The description of the light-receiving device 12e illustrated in FIG. 3B as an example can be referred to for the structure of the device 3. Note that as illustrated in the light-receiving device 12e in FIG. 3B, the electrode 13B functioning as the pixel electrode is a cathode and the electrode 15 functioning as the common electrode is an anode in the device 3.

TABLE 4

| | | | Weight | | |
|---|---|---|---|---|---|
| | | Constituent material | ratio | Film thickness | |
| Electrode 15 | | Ag:Mg (10:1) | — | 15 | nm |
| Layer 21 | | LiF | — | 1 | nm |
| Layer 31B | Layer 33B | BBABnf:OCHD-003 | 1:0.1 | 10 | nm |
| | Layer 35B | BBABnf | — | 80 | nm |

| | | | | |
|---|---|---|---|---|
| Active layer 43 | C₇₀:DBP | 9:1 | 60 | nm |
| Layer 37B | C₇₀ | — | 55 | nm |

| | | | |
|---|---|---|---|
| Electrode 13B | APC\ITSO | — | 100 nm\100 nm |

Since the description of the device 1d made in Example 1 can be referred to for the fabrication of the device 3, the detailed description thereof is omitted.

A specific structure of the device 4 fabricated in this example is shown in Table 5. The description of the light-receiving device 12c illustrated in FIG. 2D as an example can be referred to for the structure of the device 4. Note that as illustrated in the light-receiving device 12c in FIG. 2D, the electrode 13B functioning as the pixel electrode is an anode and the electrode 15 functioning as the common electrode is a cathode in the device 4.

TABLE 5

| | Constituent material | Weight ratio | Film thickness | |
|---|---|---|---|---|
| Electrode 15 | Ag:Mg (10:1) | — | 10 | nm |
| Layer 21 | LiF | — | 1 | nm |
| Layer 37B | NBPhen | — | 10 | nm |
| | 2mDBTBPDBq-II | — | 10 | nm |
| Active layer 43 | C₇₀:DBP | 9:1 | 60 | nm |
| Layer 31B | BBABnf | — | 40 | nm |
| | BBABnf:OCHD-003 | 1:0.1 | 10 | nm |

| | | | |
|---|---|---|---|
| Electrode 13B | APC\ITSO | — | 100 nm\100 nm |

The electrode 13B was formed. Since the description in Example 1 can be referred to for the formation of the electrode 13B, the detailed description is omitted.

The layer 31B functioning as a hole-transport layer was formed by depositing N,N-bis(4-biphenyl)-6-phenylbenzo[b]naphtho[1,2-d]furan-8-amine (abbreviation: BBABnf) and an electron acceptor material containing fluorine with a molecular weight of 672 (OCHD-003) by co-evaporation in a weight ratio of BBABnf:OCHD-003=1:0.1 to a thickness of 10 nm, and then depositing BBABnf by evaporation to a thickness of 40 nm.

The active layer 43 was formed. Since the description in Example 1 can be referred to for the formation of the active layer 43, the detailed description is omitted.

The layer 37B functioning as an electron-transport layer was formed by depositing 2-[3′-(dibenzothiophen-4-yl)biphenyl-3-yl]dibenzo[f,h]quinoxaline (abbreviation: 2mDBTBPDBq-II) by evaporation to a thickness of 10 nm and then depositing 2,9-bis(naphthalen-2-yl)-4,7-diphenyl-1,10-phenanthroline (abbreviation: NBPhen) by evaporation to a thickness of 10 nm.

The layer 21 functioning as an electron-transport layer was formed. Since the description in Example 1 can be referred to for the formation of the layer 21, the detailed description is omitted.

The electrode 15 was formed by depositing silver (Ag) and magnesium (Mg) by co-evaporation in a volume ratio of 10:1 to a thickness of 10 nm.

In the above manner, the device 3 and the device 4 were fabricated.

### <Current Density-Voltage Characteristics>

Next, the current density-voltage characteristics of each light-receiving device were measured. The measurement was performed in each of a state with irradiation with monochromatic light at an irradiance of 12.5 μW/cm² and a dark state (denoted by Dark). The wavelengths λ of the monochromatic light were 450 nm, 550 nm, and 650 nm.

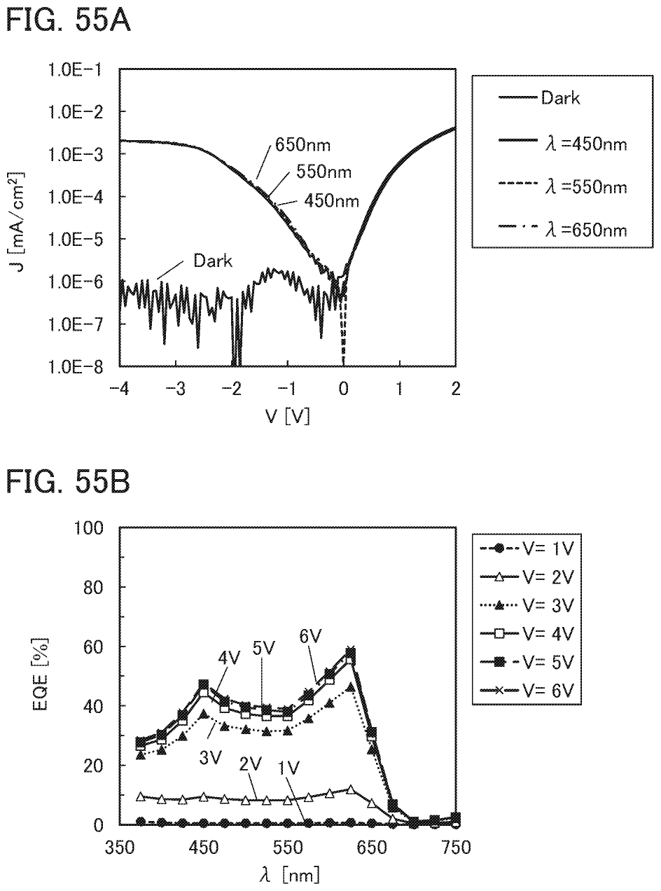

FIG. 55A shows the current density-voltage characteristics of the device 3. In FIG. 55A, the horizontal axis represents voltage V and the vertical axis represents current density J. As shown in FIG. 55A, it is found that the device 3 shows favorable characteristics when irradiated with light with the wavelengths λ of 450 nm, 500 nm, and 550 nm. It is also found that the device 3 has a small amount of dark current.

FIG. 55B shows the wavelength dependence of external quantum efficiency (EQE) of the device 3. The EQE was measured at an irradiance of 12.5 μW/cm² with various voltages and wavelengths. In FIG. 55B, the horizontal axis represents wavelength λ and the vertical axis represents EQE. As shown in FIG. 55B, it is found that the device 3 has light-receiving sensitivity to visible light.

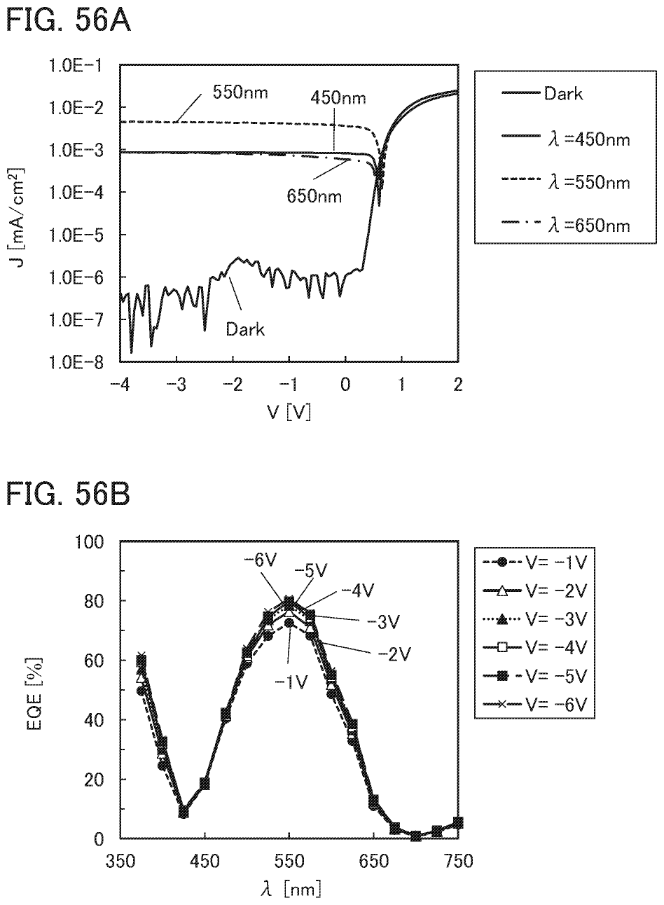

FIG. 56A shows the current density-voltage characteristics of the device 4. In FIG. 56A, the horizontal axis represents voltage V and the vertical axis represents current density J. As shown in FIG. 56A, it is found that the device 4 shows favorable characteristics when irradiated with light with the wavelengths λ of 450 nm, 500 nm, and 550 nm. It is also found that the device 4 has a small amount of dark current.

FIG. 56B shows the wavelength dependence of external quantum efficiency (EQE) of the device 4. The EQE was measured at an irradiance of 12.5 μW/cm² with various voltages and wavelengths. In FIG. 56B, the horizontal axis represents wavelength λ and the vertical axis represents EQE. As shown in FIG. 56B, it is found that the device 4 has light-receiving sensitivity to visible light.

### REFERENCE NUMERALS

ACL: wiring, ARR1: first arrangement, ARR2: second arrangement, ARR3: third arrangement, ARR4: fourth arrangement, ARR5: fifth arrangement, ARR6: sixth arrangement, C11: capacitor, C21: capacitor, DB: data potential, DG: data potential, DR: data potential, DS: data potential, EAL: wiring, EL: light-emitting device, ELB: light-emitting device, ELG: light-emitting device, ELR: light-emitting device, GL: wiring, M11: transistor, M12: transistor, M13: transistor, M15: transistor, M16: transistor, M17: transistor, M18: transistor, PD: light-receiving device, RL: wiring, RS: wiring, SE: wiring, SL: wiring, SLB: wiring, SLG: wiring, SLR: wiring, T11: time, T12: time, T21: time, T22: time, T23: time, T24: time, T25: time, T26: time, TX: wiring, V11: wiring, V12: wiring, V13: wiring, WX: wiring, 10A: display apparatus, 10B: display apparatus, 10C: display apparatus, 10D: display apparatus, 10E: display apparatus, 10F: display apparatus, 10G: display apparatus, 10: display apparatus, 11a: light-emitting device, 11B: light-emitting device, 11b: light-emitting device, 11c: light-emitting device, 11d: light-emitting device, 11e: light-emitting device, 11f: light-emitting device, 11g: light-emitting device, 11G: light-emitting device, 11IR: light-emitting device, 11R: light-emitting device, 11: light-emitting device, 12a: light-receiving device, 12b: light-receiving device, 12c: light-receiving device, 12e: light-receiving device, 12f: light-receiving device, 12IRS: light-receiving device, 12PS: light-receiving device, 12: light-receiving device, 13A: electrode, 13a: electrode, 13B: electrode, 13b: electrode, 13c: electrode, 13d: electrode, 13e: electrode, 13f: electrode, 15: electrode, 17B: EL layer, 17G: EL layer, 17IR: EL layer, 17R: EL layer, 17: EL layer, 19IRS: light-receiving layer, 19PS: light-receiving layer, 19: light-receiving layer, 21: layer, 23: substrate, 31A: layer, 31B: layer, 31: light, 32: light, 33A: layer, 33a: layer, 33B: layer, 33b: layer, 33c: layer, 33d: layer, 33e: layer, 33f: layer, 35A: layer, 35a: layer, 35B: layer, 35b: layer, 35c: layer, 35d: layer, 35e: layer, 35f: layer, 37A: layer, 37a: layer, 37B: layer, 37b: layer, 37c: layer, 37d: layer, 37e: layer, 37f: layer, 39A: optical adjustment layer, 39B: optical adjustment layer, 41a: light-emitting layer, 41B: light-emitting layer, 41b: light-emitting layer, 41c: light-emitting layer, 41G: light-emitting layer, 41IR: light-emitting layer, 41R: light-emitting layer, 41: light-emitting layer, 43IRS: active layer, 43PS: active layer, 43: active layer, 47: EL layer, 50: intermediate layer, 51A: layer, 57A: layer, 61: light-emitting layer, 71: display portion, 72: driver circuit portion, 73: driver circuit portion, 74: driver circuit portion, 75: circuit portion, 80A: pixel, 80B: pixel, 80C: pixel, 80: pixel, 81B: subpixel, 81G: subpixel, 81R: subpixel, 81: pixel, 82: pixel, 82PS: subpixel, 91: blood vessel, 93: biological tissue, 100A: display apparatus, 100B: display apparatus, 100C: display apparatus, 100D: display apparatus, 100E: display apparatus, 100F: display apparatus, 100G: display apparatus, 100: display apparatus, 101: layer, 110a: subpixel, 110A: pixel, 110b: subpixel, 110B: pixel, 110c: subpixel, 110d: subpixel, 110: pixel, 111a: pixel electrode, 111b: pixel electrode, 111c: pixel electrode, 111d: pixel electrode, 111: conductive film, 113a: EL layer, 113A: first layer, 113b: EL layer, 113B: second layer, 113c: EL layer, 113C: third layer, 113d: light-receiving layer, 113D: fourth layer, 114: layer, 115: common electrode, 117: light-blocking layer, 118A: first sacrificial layer, 118a: first sacrificial layer, 118B: first sacrificial layer, 118b: first sacrificial layer, 118C: first sacrificial layer, 118c: first sacrificial layer, 118D: first sacrificial layer, 118d: first sacrificial layer, 119A: second sacrificial layer, 119a: second sacrificial layer, 119B: second sacrificial layer, 119b: second sacrificial layer, 119C: second sacrificial layer, 119c: second sacrificial layer, 119D: second sacrificial layer, 119d: second sacrificial layer, 120: substrate, 122: resin layer, 123: conductive layer, 125A: insulating film, 125: insulating layer, 126a: conductive layer, 126b: conductive layer, 126d: conductive layer, 127A: insulating film, 127: insulating layer, 128: layer, 130a: light-emitting device, 130b: light-emitting device, 130c: light-emitting device, 130d: light-receiving device, 131: protective layer, 132: protective layer, 139: region, 140: connection portion, 142: adhesive layer, 151: substrate, 152: substrate, 153: insulating layer, 162: display portion, 164: circuit, 165: wiring, 166: conductive layer, 172: FPC, 173: IC, 190a: resist mask, 190b: resist mask, 190c: resist mask, 190d: resist mask, 190e: resist mask, 200A: display apparatus, 200B: display apparatus, 200: display apparatus, 201: substrate, 202: substrate, 203: functional layer, 204: connection portion, 205: transistor, 207: transistor, 209: transistor, 210: transistor, 211B: light-emitting device, 211G: light-emitting device, 211IR: light-emitting device, 211R: light-emitting device, 211: light-emitting device, 212IRS: light-receiving device, 212PS: light-receiving device, 212: light-receiving device, 213: insulating layer, 214: insulating layer, 215: insulating layer, 217: insulating layer, 218: insulating layer, 220: finger, 221: conductive layer, 222a: conductive layer, 222b: conductive layer, 222: fingerprint, 223: conductive layer, 224: contact portion, 225: insulating layer, 226: path, 227: imaging range, 228: region, 229: stylus, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301: substrate, 301A: substrate, 301B: substrate, 310: transistor, 310A: transistor, 310B: transistor, 311: conductive layer, 312: low-resistance region, 313: insulating layer, 314: insulating layer, 315: element isolation layer, 320: transistor, 320A: transistor, 320B: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 341: conductive layer, 342: conductive layer, 343: plug, 400: portable information terminal, 401: substrate, 402: housing, 404: display portion, 406: finger, 407: region, 408: region, 409: image, 410a: transistor, 410: transistor, 411i: channel formation region, 411n: low-resistance region, 411: semiconductor layer, 412: insulating layer, 413: conductive layer, 414a: conductive layer, 414b: conductive layer, 415: conductive layer, 416: insulating layer, 421: insulating layer, 422: insulating layer, 423: insulating layer, 426: insulating layer, 431: conductive layer, 450a: transistor, 450: transistor, 451: semiconductor layer, 452: insulating layer, 453: conductive layer, 454a: conductive layer, 454b: conductive layer, 455: conductive layer, 5000a: display apparatus, 5000b: display apparatus, 5000c: display apparatus, 5000d: display apparatus, 5002: dashboard, 5004: ceiling, 5005: camera, 5006: handle, 5008: windshield, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9200: portable information terminal, 9201: portable information terminal

1. A display apparatus comprising a light-emitting device, a light-receiving device, and a substrate,
wherein the light-emitting device comprises a first electrode, a light-emitting layer, a first electron-transport layer, an electron-injection layer, and a second electrode stacked in this order over the substrate, and
wherein the light-receiving device comprises a third electrode, an active layer, a first hole-transport layer, the electron-injection layer, and the second electrode stacked in this order over the substrate.

2. The display apparatus according to claim 1,
wherein the light-emitting device comprises a second hole-transport layer between the first electrode and the light-emitting layer.

3. The display apparatus according to claim 1,
wherein the light-receiving device comprises a second electron-transport layer between the third electrode and the active layer.

4. The display apparatus according to claim 1,
wherein the light-emitting device is configured to emit visible light, and
wherein the light-receiving device is configured to detect visible light.

5. The display apparatus according to claim 1,
wherein the light-emitting device is configured to emit infrared light, and
wherein the light-receiving device is configured to detect infrared light.

6. The display apparatus according to claim 1,
wherein the first electrode is supplied with a first potential,
wherein the second electrode is supplied with a second potential lower than the first potential, and
wherein the third electrode is supplied with a third potential higher than the second potential.

7. The display apparatus according to claim 1, further comprising a pixel portion comprising a plurality of first pixels, a plurality of second pixels, a plurality of third pixels, and a plurality of fourth pixels,
wherein the first pixels, the second pixels, the third pixels, and the fourth pixels each comprise one of the light-emitting device and the light-receiving device,
wherein, in a first direction, the pixel portion comprises a first arrangement where the second pixel, the first pixel, the second pixel, and the third pixel are repeatedly arranged in this order, and a second arrangement where the fourth pixel, the first pixel, the fourth pixel, and the third pixel are repeatedly arranged in this order,
wherein the first arrangement and the second arrangement are alternately repeated in a second direction orthogonal to the first direction,
wherein, in the second direction, the pixel portion comprises a third arrangement where the second pixel and the fourth pixel are alternately arranged repeatedly, and a fourth arrangement where the first pixel and the third pixel are alternately arranged repeatedly, and
wherein the third arrangement and the fourth arrangement are alternately repeated in the first direction.

8. The display apparatus according to claim 7,
wherein the first pixel, the second pixel, and the third pixel comprise the light-emitting devices emitting light in different wavelength ranges, and
wherein the fourth pixel comprises the light-receiving device.

9. The display apparatus according to claim 7,
wherein the third pixel comprises a light-emitting device emitting green light,
wherein an area of the third pixel is smaller than an area of the first pixel, and
wherein the area of the third pixel is smaller than an area of the second pixel.

10. A display module comprising the display apparatus according to claim 1 and at least one of a connector and an integrated circuit.

11. An electronic device comprising the display module according to claim 10 and at least one of a housing, a battery, a camera, a speaker, and a microphone.
